(19) United States
(12) Patent Application Publication
(10) Pub. No.: US 2013/0337387 A1
(43) Pub. Date: Dec. 19, 2013

(54) RESIST COMPOSITION AND METHOD OF FORMING RESIST PATTERN

(71) Applicant: Tokyo Ohta Kogyo Co., Ltd., (US)

(72) Inventors: Masahito Yahagi, Kawasaki-shi (JP); Jun Iwashita, Kawasaki-shi (JP)

(73) Assignee: Tokyo Ohta Kogyo Co., Ltd., Kawasaki-shi (JP)

(21) Appl. No.: 13/868,462

(22) Filed: Apr. 23, 2013

(30) Foreign Application Priority Data
Apr. 25, 2012 (JP) 2012-100250

(51) Int. Cl. G03F 7/004

(52) U.S. Cl. CPC G03F 7/004
USPC 430/325; 526/243

(57) ABSTRACT

A resist composition including a base component (A) which generates acid upon exposure and exhibits changed solubility in a developing solution by the action of acid, (A) including (A1) including (a0) and (a2), and the resist composition having a Tf temperature of lower than 170° C. (└La⁰¹ represents —COO—, —CON(R′)— or a divalent aromatic group, R′ represents a hydrogen atom or a methyl group, Va⁰¹ represents a linear alkylene group of at least 3 carbon atoms, A⁻ represents an anion-containing group, M^{m+} represents an organic cation, Ya²¹ represents a single bond or divalent linking group, La²¹ represents —O—, —COO—, —CON(R′)— or —OCO—, R′ represents a hydrogen atom or a methyl group, and Ra²¹ represents a lactone-containing group, a carbonate containing group or an —SO₂— containing group.

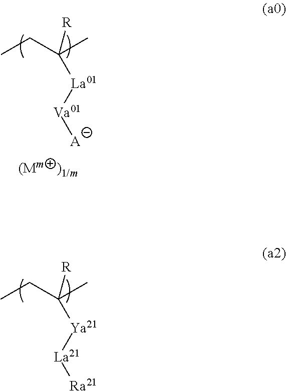

### TECHNICAL FIELD

The present invention relates to a resist composition which exhibits excellent lithography properties, and a method of forming a resist pattern using the resist composition. Priority is claimed on Japanese Patent Application No. 2012-100250, filed Apr. 25, 2012, the content of which is incorporated herein by reference.

### BACKGROUND ART

In lithography techniques, for example, a resist film composed of a resist material is formed on a substrate, and the resist film is subjected to selective exposure, followed by development, thereby forming a resist pattern having a predetermined shape on the resist film. A resist material in which the exposed portions of the resist film become soluble in a developing solution is called a positive-type, and a resist material in which the exposed portions of the resist film become insoluble in a developing solution is called a negative-type.

In recent years, in the production of semiconductor elements and liquid crystal display elements, advances in lithography techniques have lead to rapid progress in the field of pattern miniaturization.

Typically, these miniaturization techniques involve shortening the wavelength (increasing the energy) of the exposure light source. Conventionally, ultraviolet radiation typified by g-line and i-line radiation has been used, but nowadays KrF excimer lasers and ArF excimer lasers are starting to be introduced in mass production. Furthermore, research is also being conducted into lithography techniques that use an exposure light source having a wavelength shorter (energy higher) than these excimer lasers, such as electron beam (EB), extreme ultraviolet radiation (EUV), and X ray.

Resist materials for use with these types of exposure light sources require lithography properties such as a high resolution capable of reproducing patterns of minute dimensions, and a high level of sensitivity to these types of exposure light sources.

Conventionally, as a resist material that satisfies these conditions, a chemically amplified composition is used, which includes an acid-generator component that generates acid upon exposure and a base material component that exhibits a changed solubility in a developing solution under the action of acid.

In recent years, a base resin which has an acid generating group that generates acid upon exposure has been proposed for a chemically amplified resist composition. For example, a resin component which has in the structure thereof an acid generating group which generates acid upon exposure and an acid decomposable group which exhibits changed polarity by the action of acid has been proposed (see, for example, Patent Documents 1 to 3). Such a resin component has both the function as an acid generator and the function as a base component, and hence, can compose a chemically amplified resist composition by just one component. That is, when such a resin component is subjected to exposure, acid is generated from the acid-generator group in the structure thereof, and the acid decomposable group is decomposed by the generated acid, thereby forming a polar group such as a carboxy group so as to exhibit increased polarity. When a resin film (resist film) formed using such a resin component is subjected to selective exposure, the polarity of the exposed portions is increased. Thus, by conducting developing by using an alkali developing solution, the exposed portions are dissolved and removed, thereby forming a positive resist pattern.

### DOCUMENTS OF RELATED ART

### Patent Document

[Patent Document 1] Japanese Unexamined Patent Application, First Publication No. Hei 10-221852

[Patent Document 2] Japanese Unexamined Patent Application, First Publication No. 2006-045311

[Patent Document 3] Japanese Unexamined Patent Application, First Publication No. 2010-095643

### SUMMARY OF THE INVENTION

As miniaturization of resists progress, there is still room for improvement in the lithography properties of the conventional resist materials.

In a resist composition having a resin component that possesses both of a function as an acid generator and a function as a base component, since an acid generator in the form of a low molecular weight compound is not present, a formed resist film tends to exhibit a high glass transition temperature. Therefore, it becomes necessary to raise the bake temperature after exposure (PEB temperature). However, when the baking (PEB) is conducted at a high temperature, it becomes difficult to control the diffusion length of acid, thereby resulting in deterioration of the lithography properties.

The present invention takes the above circumstances into consideration, with an object of providing a resist composition which contains a resin component that possesses both of a function as an acid generator and a function as a base component, and which exhibits excellent lithography properties and resolution; and a method of forming a resist pattern using the resist composition.

For solving the above-mentioned problems, the present invention employs the following aspects.

Specifically, a first aspect of the present invention is a resist composition including a base component (A) which generates acid upon exposure and exhibits changed solubility in a developing solution by the action of acid,

the base component (A) including a resin component (A1) including a structural unit (a0) represented by general formula (a0) shown below and a structural unit (a2) represented by general formula (a2) shown below,

provided that, when the resist composition is used to form a film on a substrate, and the film is subjected to selective exposure and developing to form a hole pattern, followed by a bake treatment, a bake treatment temperature (Tf) at which a size of the hole pattern is started to be reduced 10% as compared to the size before the bake treatment is lower than 170° C.

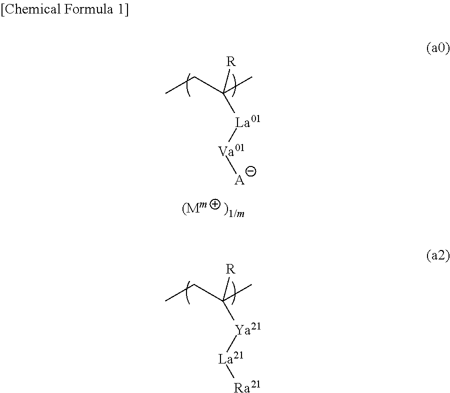

In the formulae, R represents a hydrogen atom, an alkyl group of 1 to 5 carbon atoms or a halogenated alkyl group of 1 to 5 carbon atoms; La⁰¹ represents —COO—, —CON(R′)— or a divalent aromatic group; R′ represents a hydrogen atom or a methyl group; Va⁰¹ represents a linear alkylene group of at least 3 carbon atoms, provided that part or all of the hydrogen atoms constituting the alkylene group may be substituted with a halogen atom, a linear or branched alkyl group or a linear or branched halogenated alkyl group, and part of —CH₂— constituting the alkylene group may be replaced by a divalent cyclic group, an oxygen atom (—O—), a carbonyl group (—C(═O)—) or —NH—; A⁻ represents an anion-containing group; Mm⁺represents an organic cation having a valency of m; m represents an integer of 1 to 3; Ya²¹ represents a single bond or divalent linking group, La²¹ represents —O—, —COO—, —CON(R′)— or —OCO—, and R′ represents a hydrogen atom or a methyl group, provided that, when La²¹ represents —O—, Ya²¹ does not represent —CO—; and Ra²¹ represents a lactone-containing group, a carbonate containing group or an —SO₂— containing group.

A second aspect of the present invention is a method of forming a resist pattern, including: using a resist composition of the first aspect to form a resist film on a substrate; conducting exposure of the resist film; and developing the resist film to form a resist pattern.

In the present description and claims, the term “aliphatic” is a relative concept used in relation to the term “aromatic”, and defines a group or compound that has no aromaticity.

The term “alkyl group” includes linear, branched or cyclic, monovalent saturated hydrocarbon, unless otherwise specified.

The term “alkylene group” includes linear, branched or cyclic, divalent saturated hydrocarbon, unless otherwise specified. The same applies for the alkyl group within an alkoxy group.

A “halogenated alkyl group” is a group in which part or all of the hydrogen atoms of an alkyl group is substituted with a halogen atom. Examples of the halogen atom include a fluorine atom, a chlorine atom, a bromine atom and an iodine atom.

A “fluorinated alkyl group” or a “fluorinated alkylene group” is a group in which part or all of the hydrogen atoms of an alkyl group or an alkylene group have been substituted with fluorine atom(s).

The term “structural unit” refers to a monomer unit that contributes to the formation of a polymeric compound (resin, polymer, copolymer).

A “structural unit derived from an acrylate ester” refers to a structural unit that is formed by the cleavage of the ethylenic double bond of an acrylate ester.

An “acrylate ester” refers to a compound in which the terminal hydrogen atom of the carboxy group of acrylic acid (CH₂=CH—COOH) has been substituted with an organic group.

The acrylate ester may have the hydrogen atom bonded to the carbon atom on the α-position substituted with a substituent. The substituent that substitutes the hydrogen atom bonded to the carbon atom on the α-position is atom other than hydrogen or a group, and examples thereof include an alkyl group of 1 to 5 carbon atoms, a halogenated alkyl group of 1 to 5 carbon atoms and a hydroxyalkyl group. A carbon atom on the α-position of an acrylate ester refers to the carbon atom bonded to the carbonyl group, unless specified otherwise.

Hereafter, an acrylate ester having the hydrogen atom bonded to the carbon atom on the α-position substituted with a substituent is sometimes referred to as “α-substituted acrylate ester”. Further, acrylate esters and α-substituted acrylate esters are collectively referred to as “(α-substituted) acrylate ester”.

A “structural unit derived from hydroxystyrene or a hydroxystyrene derivative” refers to a structural unit that is formed by the cleavage of the ethylenic double bond of hydroxystyrene or a hydroxystyrene derivative.

The term “hydroxystyrene derivative” includes compounds in which the hydrogen atom at the α-position of hydroxystyrene has been substituted with another substituent such as an alkyl group or a halogenated alkyl group; and derivatives thereof. Examples of the derivatives thereof include hydroxystyrene in which the hydrogen atom of the hydroxy group has been substituted with an organic group and may have the hydrogen atom on the α-position substituted with a substituent; and hydroxystyrene which has a substituent other than a hydroxy group bonded to the benzene ring and may have the hydrogen atom on the α-position substituted with a substituent. Here, the α-position (carbon atom on the α-position) refers to the carbon atom having the benzene ring bonded thereto, unless specified otherwise.

As the substituent which substitutes the hydrogen atom on the α-position of hydroxystyrene, the same substituents as those described above for the substituent on the α-position of the aforementioned α-substituted acrylate ester can be mentioned.

A “structural unit derived from vinylbenzoic acid or a vinylbenzoic acid derivative” refers to a structural unit that is formed by the cleavage of the ethylenic double bond of vinylbenzoic acid or a vinylbenzoic acid derivative.

The term “vinylbenzoic acid derivative” includes compounds in which the hydrogen atom at the α-position of vinylbenzoic acid has been substituted with another substituent such as an alkyl group or a halogenated alkyl group; and derivatives thereof Examples of the derivatives thereof include benzoic acid in which the hydrogen atom of the carboxy group has been substituted with an organic group and may have the hydrogen atom on the α-position substituted with a substituent; and benzoic acid which has a substituent other than a hydroxy group and a carboxy group bonded to the benzene ring and may have the hydrogen atom on the α-position substituted with a substituent. Here, the α-position (carbon atom on the α-position) refers to the carbon atom having the benzene ring bonded thereto, unless specified otherwise.

The term “styrene” is a concept including styrene and compounds in which the hydrogen atom at the α-position of styrene is substituted with other substituent such as an alkyl group and a halogenated alkyl group. A “structural unit derived from styrene” or “structural unit derived from a styrene derivative” refers to a structural unit that is formed by the cleavage of the ethylenic double bond of styrene or a styrene derivative.

As the alkyl group as a substituent on the α-position, a linear or branched alkyl group is preferable, and specific examples include a methyl group, an ethyl group, a propyl group, an isopropyl group, an n-butyl group, an isobutyl group, a tert-butyl group, a pentyl group, an isopentyl group and a neopentyl group.

Specific examples of the halogenated alkyl group as the substituent on the α-position include groups in which part or all of the hydrogen atoms of the aforementioned “alkyl group as the substituent on the α-position” are substituted with halogen atoms. Examples of the halogen atom include a fluorine atom, a chlorine atom, a bromine atom and an iodine atom, and a fluorine atom is particularly desirable.

Specific examples of the hydroxyalkyl group of 1 to 5 carbon atoms as the substituent on the α-position include groups in which part or all of the hydrogen atoms of the aforementioned “alkyl group as the substituent on the α-position” are substituted with a hydroxy group. The number of hydroxy groups within the hydroxyalkyl group is preferably 1 to 5, and most preferably 1.

The term “exposure” is used as a general concept that includes irradiation with any form of radiation.

An “organic group” refers to a group containing a carbon atom, and may include atoms other than carbon atoms (e.g., a hydrogen atom, an oxygen atom, a nitrogen atom, a sulfur atom, a halogen atom (such as a fluorine atom and a chlorine atom) and the like).

According to the present invention, there are provided a resist composition which can be used to form a fine resist pattern with excellent lithography properties; and a method of forming a resist pattern using the resist composition.

### MODE FOR CARRYING OUT THE INVENTION

<<Resist Composition>>

The resist composition according to a first aspect of the present invention includes a base component (A) which generates acid upon exposure and exhibits changed solubility in a developing solution under action of acid (hereafter, sometimes referred to as “component (A)”).

By virtue of containing the base component (A), the resist composition of the present invention has a characteristic of exhibiting changed solubility in a developing solution upon exposure. When a resist film is formed using the resist composition, and the resist film is subjected to a selective exposure, acid is generated from the base component (A) at exposed portions, and the generated acid acts on the base component (A) to change the solubility of the component (A) in a developing solution. As a result, the solubility of the exposed portions in a developing solution is changed, whereas the solubility of the unexposed portions in a developing solution remain unchanged. Therefore, by subjecting the resist film to development, the exposed portions are dissolved and removed to form a positive-tone resist pattern in the case of a positive resist, whereas the unexposed portions are dissolved and removed to form a negative-tone resist pattern in the case of a negative resist.

In the present specification, a resist composition which forms a positive resist pattern by dissolving and removing the exposed portions is called a positive resist composition, and a resist composition which forms a negative resist pattern by dissolving and removing the unexposed portions is called a negative resist composition.

The resist composition of the present invention may be either a positive resist composition or a negative resist composition. Further, in the formation of a resist pattern, the resist composition of the present invention can be applied to an alkali developing process using an alkali developing solution in the developing treatment, or a solvent developing process using a developing solution containing an organic solvent (organic developing solution) in the developing treatment. The resist composition of the present invention is preferably used in the formation of a positive-tone resist pattern by an alkali developing process and a negative-tone resist pattern by a solvent developing process. In such a case, as the component (A), a base component that exhibits increased solubility in an alkali developing solution (decreased solubility in an organic developing solution) under the action of acid is used.

When the resist composition is used to form a film on a substrate, and the film is subjected to selective exposure and developing to form a hole pattern, followed by a bake treatment, a bake treatment temperature (Tf) at which a size of the hole pattern is started to be reduced 10% as compared to the size before the bake treatment is lower than 170° C.

Specifically, with respect to a formed hole pattern, post bake treatment is conducted at temperatures from 120° C. to 190° C. (intervals of 5° C.), and the hole diameter after the post bake treatment at each temperature is measured. From the measurement results, with respect to each resist composition, a graph is plotted by taking the post bake temperature (° C.) on the horizontal axis and the hole diameter after the post bake on the vertical axis. From the graph, the temperature at which the hole diameter has shrunk by 10% from the target size is determined as the Tf temperature (° C.). By virtue of the resist composition having a Tf temperature of lower than 170° C., it is presumed that diffusion of acid can be controlled, thereby improving the lithography properties.

The film thickness of the resist film on which the hole pattern is formed is 100 nm. The diameter and pitch of the hole pattern can be appropriately selected so as to obtain uniform diameter and pitch. For example, the diameter may be 170 nm, and the pitch may be 1,200 nm. Further, the formation method of the hole pattern can also be appropriately selected. For example, the following method can be mentioned. An organic anti-reflection film is formed on a silicon wafer, and then a resist composition is applied to the organic anti-reflection film, followed by a prebake treatment (PAB) and drying, thereby forming a resist film having a film thickness of 100 nm. Subsequently, a KrF excimer laser (248 nm) is selectively irradiated on the resist film through a mask pattern. Thereafter, a PEB treatment is conducted, followed by an alkali developing treatment at 23° C. using a 2.38wt % aqueous TMAH solution, thereby obtaining an isolated hole pattern having a diameter of 170 nm and a pitch of 1,200 nm.

The resist composition of the present invention preferably has a Tf temperature of 140° C. to 165° C., and more preferably 150° C. to 160° C.

<Base Component (A)>

The component (A) used in the resist composition of the present invention is a base component which generates acid upon exposure and exhibits changed solubility in a developing solution under action of acid, and contains a resin component (A1) (hereafter, sometimes referred to as “component (A1)”) which includes a structural unit (a0) and a structural unit (a2) described later). Further, the resin component (A) may include a structural unit (a1) containing an acid decomposable group that exhibits increased polarity by the action of acid (hereafter, referred to as “structural unit (a1)”), or a structural unit (a9) containing a fluoroalkylsulfonylamino group, an aminosulfonyl group, a —C(═O)—NH—C(═O)— group or a phenolic hydroxy group (hereafter, referred to as “structural unit (a9)”).

Here, the term “base component” refers to an organic compound capable of forming a film, and is preferably an organic compound having a molecular weight of 500 or more. When the organic compound has a molecular weight of 500 or more, the film-forming ability is improved, and a resist pattern of nano level can be easily formed. The “organic compound having a molecular weight of 500 or more” which can be used as a base component is broadly classified into non-polymers and polymers.

In general, as a non-polymer, any of those which have a molecular weight in the range of 500 to less than 4,000 is used. Hereafter, a non-polymer having a molecular weight in the range of 500 to less than 4,000 is referred to as a low molecular weight compound.

As a polymer, any of those which have a molecular weight of 1,000 or more is generally used. Hereafter, a polymer having a molecular weight of 1,000 or more is referred to as a polymeric compound. With respect to a polymeric compound, the “molecular weight” is the weight average molecular weight in terms of the polystyrene equivalent value determined by gel permeation chromatography (GPC). Hereafter, a polymeric compound is frequently referred to simply as a “resin”.

[Resin Component (A1)]

The base component (A) includes a resin component (A1) including a structural unit (a0) represented by general formula (a0) shown below (hereafter, referred to as “structural unit (a0)”) and a structural unit (a2) represented by general formula (a2) shown below (hereafter, referred to as “structural unit (a2)”). By virtue of including the resin component (A1), it is presumed that the Tf temperature of the resist composition can be controlled to lower than 170° C.

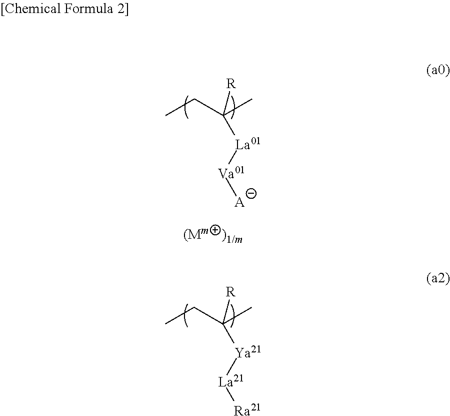

In the formulae, R represents a hydrogen atom, an alkyl group of 1 to 5 carbon atoms or a halogenated alkyl group of 1 to 5 carbon atoms; La⁰¹ represents —COO—, —CON(R′)— or a divalent aromatic group; R′ represents a hydrogen atom or a methyl group; Va⁰¹ represents a linear alkylene group of at least 3 carbon atoms, provided that part or all of the hydrogen atoms constituting the alkylene group may be substituted with a halogen atom, a linear or branched alkyl group or a linear or branched halogenated alkyl group, and part of —CH₂— constituting the alkylene group may be replaced by a divalent cyclic group, an oxygen atom (—O—), a carbonyl group (—C(═O)—) or —NH—; A represents an anion-containing group; M^{m+} represents an organic cation having a valency of m; m represents an integer of 1 to 3; Ya²¹ represents a single bond or divalent linking group, La²¹ represents —O—, —COO—, —CON(R′)— or —OCO—, and R′ represents a hydrogen atom or a methyl group, provided that, when La²¹ represents —O—, Ya²¹ does not represent —CO—; and Ra²¹ represents a lactone-containing group, a carbonate containing group or an —SO₂— containing group.

(Structural Unit (a0))

The structural unit (a0) is a structural unit represented by the aforementioned general formula (a0).

In formula (a0), R represents a hydrogen atom, an alkyl group of 1 to 5 carbon atoms or a halogenated alkyl group of 1 to 5 carbon atoms.

The alkyl group for R is preferably a linear or branched alkyl group of 1 to 5 carbon atoms, and specific examples include a methyl group, an ethyl group, a propyl group, an isopropyl group, an n-butyl group, an isobutyl group, a tert-butyl group, a pentyl group, an isopentyl group, and a neopentyl group.

The halogenated alkyl group of 1 to 5 carbon atoms represented by R is a group in which part or all of the hydrogen atoms of the aforementioned alkyl group of 1 to 5 carbon atoms have been substituted with halogen atoms. Examples of the halogen atom include a fluorine atom, a chlorine atom, a bromine atom and an iodine atom, and a fluorine atom is particularly desirable.

As R, a hydrogen atom, an alkyl group of 1 to 5 carbon atoms or a fluorinated alkyl group of 1 to 5 carbon atoms is preferable, and a hydrogen atom or a methyl group is particularly desirable in terms of industrial availability.

In formula (a0), La⁰¹ represents —COO—, —CON(R′)— or a divalent aromatic group, and R′ represents a hydrogen atom or a methyl group.

The divalent aromatic group for La⁰¹ is a divalent hydrocarbon group having at least one aromatic ring, and may have a substituent.

The aromatic ring for La⁰¹ is not particularly limited, as long as it is a cyclic conjugated compound having (4n+2)π electrons, and may be either monocyclic or polycyclic. The aromatic ring preferably has 5 to 30 carbon atoms, more preferably 5 to 20, still more preferably 6 to 15, and most preferably 6 to 12. Here, the number of carbon atoms within a substituent(s) is not included in the number of carbon atoms of the aromatic hydrocarbon group. Examples of the aromatic ring include aromatic hydrocarbon rings, such as benzene, naphthalene, anthracene and phenanthrene; and aromatic hetero rings in which part of the carbon atoms constituting the aforementioned aromatic hydrocarbon rings has been substituted with a hetero atom. Examples of the hetero atom within the aromatic hetero rings include an oxygen atom, a sulfur atom and a nitrogen atom. Specific examples of the aromatic hetero ring include a pyridine ring and a thiophene ring.

Specific examples of the aromatic group for La⁰¹ include a group in which two hydrogen atoms have been removed from an aromatic hydrocarbon ring (such as benzene, naphthalene, anthracene, phenanthrene or the like) or aromatic hetero ring (arylene group or heteroarylene group); a group in which two hydrogen atoms have been removed from an aromatic compound having two or more aromatic rings (biphenyl, fluorene or the like); and a group in which one hydrogen atom of the aforementioned aromatic hydrocarbon ring or aromatic hetero ring has been substituted with an alkylene group (a group in which one hydrogen atom has been removed from the aryl group within the aforementioned arylalkyl group such as a benzyl group, a phenethyl group, a 1-naphthylmethyl group, a 2-naphthylmethyl group, a 1-naphthylethyl group, or a 2-naphthylethyl group, or a heteroarylalkyl group). The alkylene group which is bonded to the aforementioned aryl group or heteroaryl group preferably has 1 to 4 carbon atoms, more preferably 1 or 2 carbon atoms, and most preferably 1 carbon atom.

The aromatic group may or may not have a substituent. For example, the hydrogen atom bonded to the aromatic ring within the aromatic group may be substituted with a substituent. Examples of substituents include an alkyl group, an alkoxy group, a halogen atom, a halogenated alkyl group, a hydroxyl group and an oxo group (═O).

Among these, as the aromatic group for La⁰¹, a phenylene group which may have a substituent or a naphthylene group which may have a substituent is preferable.

In formula (a0), Va⁰¹ represents a linear alkylene group of 3 or more carbon atoms, provided that part or all of the hydrogen atoms constituting the alkylene group may be substituted with a halogen atom, a linear or branched alkyl group or a linear or branched halogenated alkyl group, and part of —CH₂— groups constituting the alkylene group may be replaced by a divalent cyclic group, an oxygen atom (—O—), a carbonyl group (—C(═O)—) or —NH—.

With respect to the linear alkylene group of 3 or more carbon atoms for Va⁰¹, the number of carbon atoms does not include the number of carbon atoms of the substituent(s), and refers to the number of carbon atoms of unsubstituted alkylene group. The number of carbon atoms is preferably 3 to 15, and more preferably 3 to 10. Examples of the linear alkylene group of 3 or more carbon atoms is a trimethylene group [—(CH₂)₃—], a tetramethylene group [—(CH₂)₄—], a pentamethylene group [—(CH₂)₅—], a hexamethylene group [—(CH₂)₆—] and a heptamethylene group [—(CH₂)₇—]. Examples of the halogen atom as a substituent for the alkylene group include a fluorine atom, a chlorine atom, a bromine atom and an iodine atom.

Further, examples of the linear or branched alkyl group as a substituent for the alkylene group include

an alkyl group of 1 to 15 carbon atoms, preferably an alkyl group of 1 to 5 carbon atoms. Specific examples of the alkyl group include a methyl group, an ethyl group, a propyl group, an isopropyl group, an n-butyl group, an isobutyl group, a tert-butyl group, a pentyl group, an isopentyl group and a neopentyl group. Among these, an ethyl group or an isopropyl group is more preferable.

Examples of the halogenated alkyl group as a substituent for the alkylene group include groups in which part or all of the hydrogen atoms within the aforementioned alkyl groups has been substituted with the aforementioned halogen atoms.

Part of —CH₂— group constituting the alkylene group may be replaced by a divalent cyclic group, an oxygen atom (—O—), a carbonyl group (—(═O)—) or —NH—.

As the divalent cyclic group, an aliphatic cyclic group or an aromatic cyclic group may be used, and a divalent aliphatic cyclic group is preferable.

As the divalent aliphatic cyclic group, a monocyclic group of 3 to 6 carbon atoms or a polycyclic group of 7 to 20 carbon atoms is preferable. Specific examples thereof include a group in which 2 hydrogen atoms have been removed from a monocycloalkane such as cyclopentane or cyclohexane, and a group in which 2 hydrogen atoms have been removed from a polycycloalkane such as adamantane, norbornane, isobornane, tricyclodecane or tetracyclododecane.

As the divalent aromatic cyclic group, a group having 5 to 20 carbon atoms is preferable, and examples thereof include a group in which 2 hydrogen atoms have been removed from an aromatic hydrocarbon ring such as benzene, naphthalene, anthracene or phenanthrene.

The divalent cyclic group may have a substituent. Examples of the substituent include an alkyl group, an alkoxy group, a halogen atom, a halogenated alkyl group, a hydroxy group, an oxygen atom (═O), —COOR″, —OC(═O)R″, a hydroxyalkyl group and a cyano group (wherein R″ represents a hydrogen atom or an alkyl group).

The alkyl group for the substituent is preferably an alkyl group of 1 to 6 carbon atoms. Further, the alkyl group is preferably a linear alkyl group or a branched alkyl group. Specific examples include a methyl group, an ethyl group, a propyl group, an isopropyl group, an n-butyl group, an isobutyl group, a tert-butyl group, a pentyl group, an isopentyl group, a neopentyl group and a hexyl group. Among these, a methyl group or ethyl group is preferable, and a methyl group is particularly desirable.

As the alkoxy group for the substituent, an alkoxy group of 1 to 6 carbon atoms is preferable. Further, the alkoxy group is preferably a linear or branched alkoxy group. Specific examples of the alkoxy group include the aforementioned alkyl groups for the substituent having an oxygen atom (—O—) bonded thereto.

Examples of the halogen atom for the substituent include a fluorine atom, a chlorine atom, a bromine atom and an iodine atom, and a fluorine atom is preferable.

Examples of the halogenated alkyl group for the substituent include groups in which part or all of the hydrogen atoms within the aforementioned alkyl groups has been substituted with the aforementioned halogen atoms.

As examples of the halogenated alkyl group for the substituent, groups in which part or all of the hydrogen atoms of the aforementioned alkyl groups for the substituent have been substituted with the aforementioned halogen atoms can be given. As the halogenated alkyl group, a fluorinated alkyl group is preferable, and a perfluoroalkyl group is particularly desirable.

In the —COOR″ group and the —OC(═O)R″ group, R″ represents a hydrogen atom or a linear, branched or cyclic alkyl group of 1 to 15 carbon atoms.

When R″ represents a linear or branched alkyl group, it is preferably an alkyl group of 1 to 10 carbon atoms, more preferably an alkyl group of 1 to 5 carbon atoms, and most preferably a methyl group or an ethyl group.

When R″ is a cyclic alkyl group (cycloalkyl group), it preferably has 3 to 15 carbon atoms, more preferably 4 to 12 carbon atoms, and most preferably 5 to 10 carbon atoms. As examples of the cycloalkyl group, groups in which one or more hydrogen atoms have been removed from a monocycloalkane or a polycycloalkane such as a bicycloalkane, tricycloalkane or tetracycloalkane, which may or may not be substituted with a fluorine atom or a fluorinated alkyl group, may be used. Specific examples include groups in which one or more hydrogen atoms have been removed from a monocycloalkane such as cyclopentane and cyclohexane; and groups in which one or more hydrogen atoms have been removed from a polycycloalkane such as adamantane, norbornane, isobornane, tricyclodecane or tetracyclododecane.

The hydroxyalkyl group for the substituent preferably has 1 to 6 carbon atoms, and specific examples thereof include the aforementioned alkyl groups for the substituent in which at least one hydrogen atom has been substituted with a hydroxy group.

In formula (a0), the linear alkylene group of 3 or more carbon atoms for Va⁰¹ is preferably a linear alkylene group of 5 to 7 carbon atoms, and preferably has part of —CH₂— groups constituting the alkylene group substituted with a divalent cyclic group, an oxygen atom (—O—), a carbonyl group (—C(═O)—) or —NH—.

In formula (a0), A represents an anion-containing group.

A⁻ is not particularly limited as long as it contains a portion which generates an acid anion upon exposure, and a group which is capable of generating a sulfonate anion, a carbo anion, a carboxylate anion, an imide anion or a sulfonylmethide anion is preferable.

Among these, as A⁻, a group represented by any one of formulae (a6a-r-1) to (a6a-r-3) is preferable.

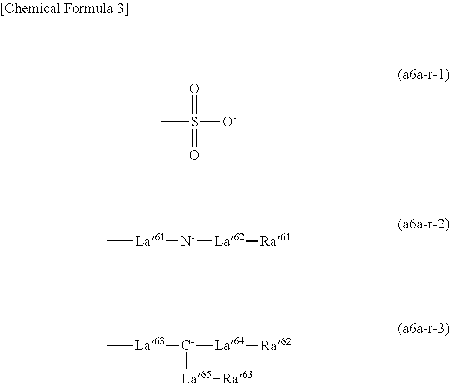

In the formulae, La′⁶¹ and La′⁶² each independently represents —SO₂—; La′⁶³ to La′⁶⁵ each independently represents —SO₂— or a single bond; and Ra′⁶¹ to Ra′⁶³ each independently represents a hydrocarbon group.

The hydrocarbon group for Ra′⁶¹ to Ra′⁶³ is the same as defined for the divalent hydrocarbon group which may have a substituent described later. The hydrocarbon group preferably has part or all of the hydrogen atoms within the hydrocarbon group substituted with fluorine, and the hydrocarbon group more preferably has 30 to 100% of the hydrogen atoms substituted with fluorine. Among these, a perfluoroalkyl group in which all of the hydrogen atoms within the alkyl group have been substituted with fluorine atoms is particularly desirable.

In general formula (a0), Mm⁺ represents an organic cation, and is the same as defined for M^{m+} in the component (B) described later. M^{m+} is preferably a cation represented by formula (ca-1) or (ca-3) shown below.

Preferable examples of the structural unit (a0) include structural units represented by general formulae (a0-1) to (a0-3) shown below.

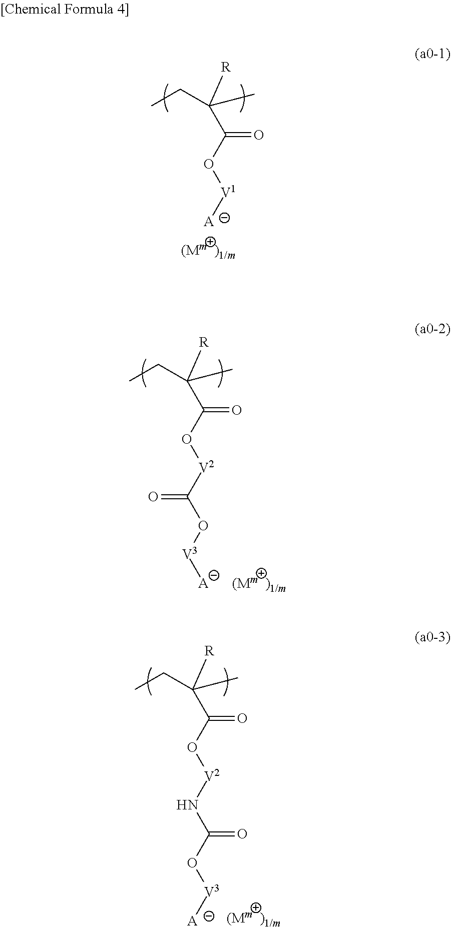

In the formulae, R represents a hydrogen atom, an alkyl group of 1 to 5 carbon atoms or a halogenated alkyl group of 1 to 5 carbon atoms; V¹ represents a linear alkylene group of at least 3 carbon atoms, provided that part or all of the hydrogen atoms constituting the alkylene group may be substituted with a halogen atom, a linear or branched alkyl group or a linear or branched halogenated alkyl group; V² and V³ each independently represents a linear alkylene group of 1 to 5 carbon atoms, a divalent cyclic group or a combination thereof, provided that part or all of the hydrogen atoms constituting the alkylene group may be substituted with a halogen atom, a linear or branched alkyl group or a linear or branched halogenated alkyl group, and part of —CH₂— groups constituting the alkylene group may be replaced by an oxygen atom (—O—); A⁻ represents an anion-containing group; M^{m+} represents an organic cation having a valency of m; and m represents an integer of 1 to 3.

The hydrogen atom, alkyl group of 1 to 5 carbon atoms and halogenated alkyl group of 1 to 5 carbon atoms for R, the anion-containing group for A⁻ and the organic cation for M^{m+} having a valency of m are the same as defined above in formula (a0).

V¹ is the same as defined for Va⁰¹ in formula (a0), and a linear fluorinated alkylene group of 3 to 7 carbon atoms is preferable. The fluorinated alkylene group may have a trifluoromethyl group, a methyl group or an ethyl group as a substituent.

Examples of the linear alkylene group of 1 to 5 carbon atoms for V² and V³ include the same groups as those defined for Va⁰¹, a methylene group and an ethylene group.

The divalent cyclic group for V² and V³ is the same as defined for the divalent cyclic group explained above for Va⁰¹.

Examples of the substituent for V² and V³ include the same substituents as those described above for Va⁰¹, and a fluorine atom, a trifluoromethyl group, a methyl group and an ethyl group is preferable.

Specific examples of the structural unit represented by general formula (a0-1) are shown below. In the following formulae, R^{α} represents a hydrogen atom, a methyl group or a trifluoromethyl group, and Mm⁺ is the same as defined above.

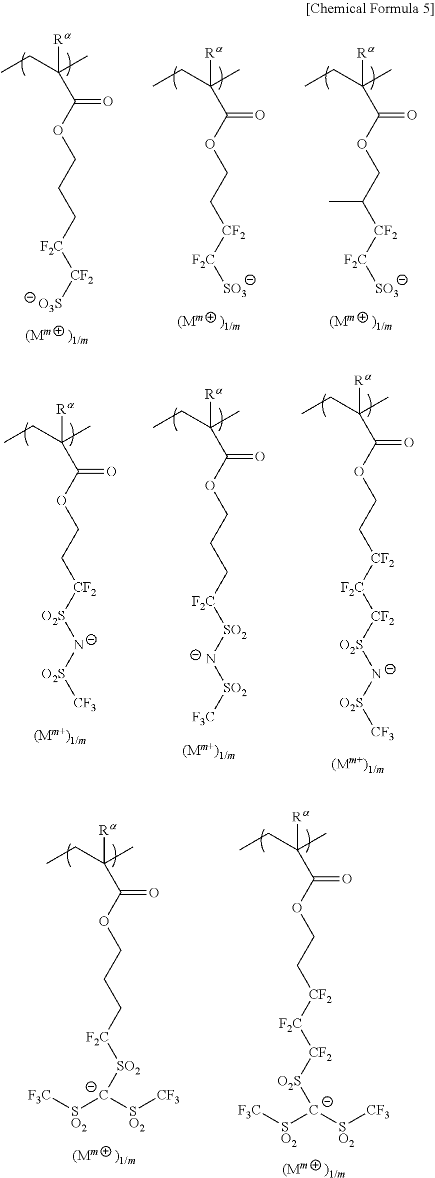

Specific examples of the structural unit represented by general formula (a0-2) are shown below. In the following formulae, R^{α} represents a hydrogen atom, a methyl group or a trifluoromethyl group, and M^{m+} is the same as defined above.

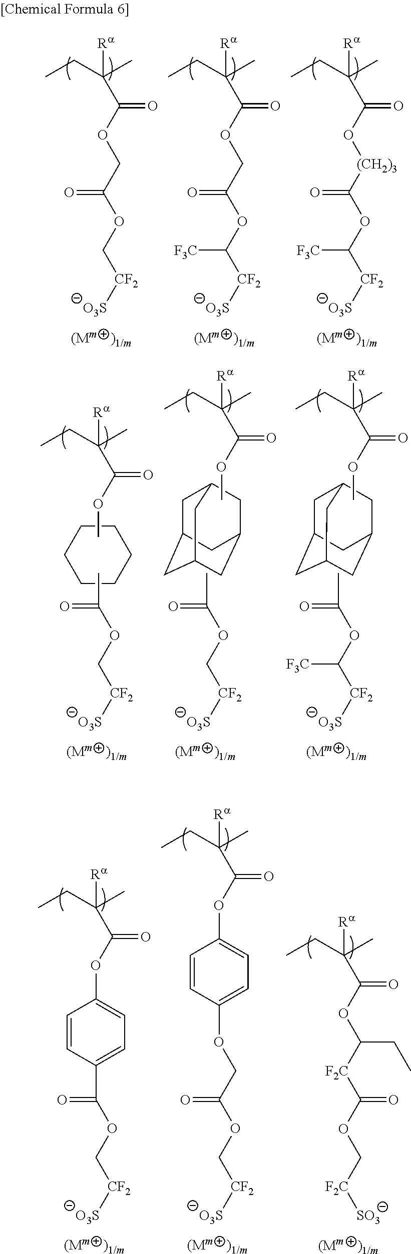

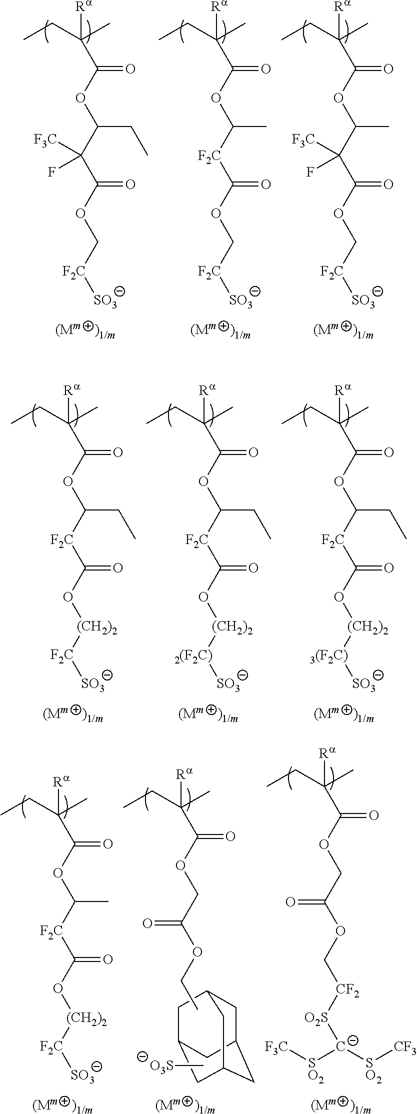

Specific examples of the structural unit represented by general formula (a0-3) are shown below. In the following formulae, R^{α} represents a hydrogen atom, a methyl group or a trifluoromethyl group, and M^{m+} is the same as defined above.

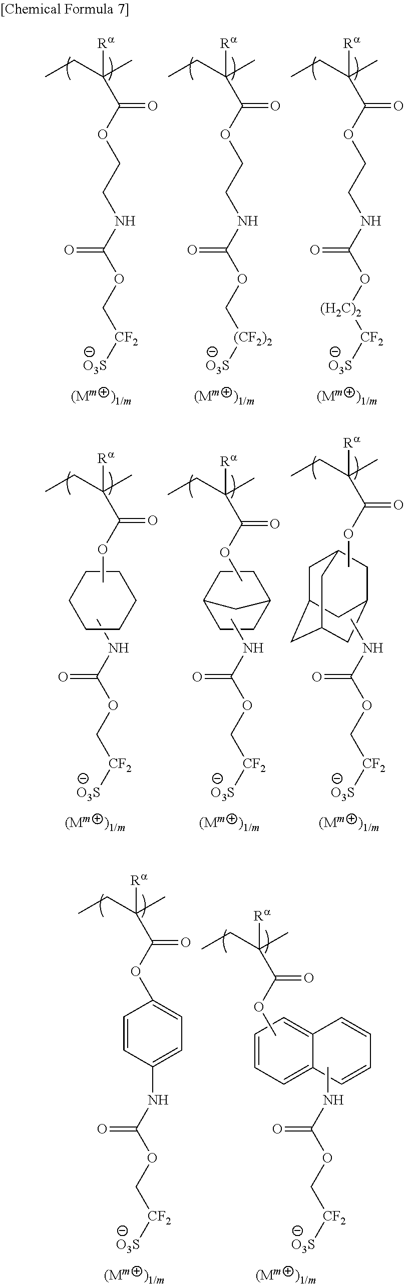

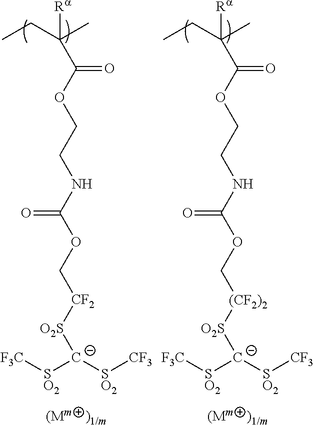

(Structural Unit (a2))

The structural unit (a2) is a structural unit represented by general formula (a2) shown below.

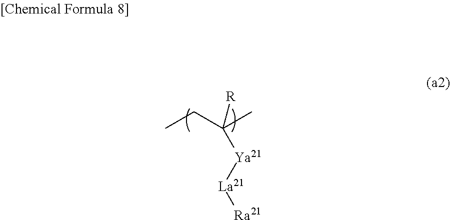

In the formula, R represents a hydrogen atom, an alkyl group of 1 to 5 carbon atoms, a halogenated alkyl group of 1 to 5 carbon atoms, a hydroxyalkyl group, an alkoxy group; Ya²¹ represents a single bond or a divalent linking group; La²¹ represents —O—, —COO—, —CON(R′)— or —OCO—; and R′ represents a hydrogen atom or a methyl group, provided that, when La²¹ represents —O—, Ya²¹ does not represents —CO—; and Ra²¹ represents a lactone-containing cyclic group, a carbonate-containing cyclic group or an —SO₂— containing cyclic group.

Ya²¹ represents a single bond or a divalent linking group. The divalent linking group for Ya²¹ is not particularly limited, and preferable examples thereof include a divalent hydrocarbon group which may have a substituent and a divalent linking group containing a hetero atom.

(Divalent Hydrocarbon Group Which May Have a Substituent)

The hydrocarbon group as a divalent linking group may be either an aliphatic hydrocarbon group or an aromatic hydrocarbon group.

An “aliphatic hydrocarbon group” refers to a hydrocarbon group that has no aromaticity. The aliphatic hydrocarbon group may be saturated or unsaturated. In general, the aliphatic hydrocarbon group is preferably saturated.

As specific examples of the aliphatic hydrocarbon group, a linear or branched aliphatic hydrocarbon group, and an aliphatic hydrocarbon group containing a ring in the structure thereof can be given.

The linear or branched aliphatic hydrocarbon group preferably has 1 to 10 carbon atoms, more preferably 1 to 8, and still more preferably 1 to 5.

As the linear aliphatic hydrocarbon group, a linear alkylene group is preferable. Specific examples thereof include a methylene group [—CH₂—], an ethylene group [—(CH₂)₂—], a trimethylene group [—(CH₂)₃—], a tetramethylene group [—(CH₂)₄—] and a pentamethylene group [—(CH₂)₅—].

As the branched aliphatic hydrocarbon group, branched alkylene groups are preferred, and specific examples include various alkylalkylene groups, including alkylmethylene groups such as —CH(CH₃)—, —CH(CH₂CH₃)—, —C(CH₃)₂—, —C(CH₃)(CH₂CH₃)—, —C(CH₃)(CH₂CH₂CH₃)—, and —C(CH₂CH₃)₂—; alkylethylene groups such as —CH(CH₃)CH₂—, —CH(CH₃)CH(CH₃)—, —C(CH₃)₂CH₂—, —CH(CH₂CH₃)CH₂—, and —C(CH₂CH₃)₂—CH₂—; alkyltrimethylene groups such as —CH(CH₃)CH₂CH₂—, and —CH₂CH(CH₃)CH₂—; and alkyltetramethylene groups such as —CH(CH₃)CH₂CH₂CH₂—, and —CH₂CH(CH₃)CH₂CH₂—. As the alkyl group within the alkylalkylene group, a linear alkyl group of 1 to 5 carbon atoms is preferable.

The linear or branched aliphatic hydrocarbon group may or may not have a substituent (a group or atom other than hydrogen) which substitutes the hydrogen atom. Examples of the substituent include a fluorine atom, a fluorinated alkyl group of 1 to 5 carbon atoms, and an oxo group (═O).

As examples of the hydrocarbon group containing a ring in the structure thereof, a cyclic aliphatic hydrocarbon group containing a hetero atom in the ring structure thereof and may have a substituent (a group in which two hydrogen atoms have been removed from an aliphatic hydrocarbon ring), a group in which the cyclic aliphatic hydrocarbon group is bonded to the terminal of the aforementioned chain-like aliphatic hydrocarbon group, and a group in which the cyclic aliphatic group is interposed within the aforementioned linear or branched aliphatic hydrocarbon group, can be given. As the linear or branched aliphatic hydrocarbon group, the same groups as those described above can be used.

The cyclic aliphatic hydrocarbon group preferably has 3 to 20 carbon atoms, and more preferably 3 to 12 carbon atoms.

The cyclic aliphatic hydrocarbon group may be polycyclic or monocyclic. As the monocyclic aliphatic hydrocarbon group, a group in which 2 hydrogen atoms have been removed from a monocycloalkane is preferable. The monocycloalkane preferably has 3 to 6 carbon atoms, and specific examples thereof include cyclopentane and cyclohexane. As the polycyclic aliphatic hydrocarbon group, a group in which two hydrogen atoms have been removed from a polycycloalkane is preferable, and the polycyclic group preferably has 7 to 12 carbon atoms. Examples of the polycycloalkane include adamantane, norbornane, isobornane, tricyclodecane and tetracyclododecane.

The cyclic aliphatic hydrocarbon group may or may not have a substituent (a group or atom other than hydrogen) which substitutes the hydrogen atom. Examples of substituents include an alkyl group, an alkoxy group, a halogen atom, a halogenated alkyl group, a hydroxyl group and an oxo group (═O).

The alkyl group as the substituent is preferably an alkyl group of 1 to 5 carbon atoms, and a methyl group, an ethyl group, a propyl group, an n-butyl group or a tert-butyl group is particularly desirable.

The alkoxy group as the substituent is preferably an alkoxy group having 1 to 5 carbon atoms, more preferably a methoxy group, ethoxy group, n-propoxy group, iso-propoxy group, n-butoxy group or tert-butoxy group, and most preferably a methoxy group or an ethoxy group.

Examples of the halogen atom for the substituent include a fluorine atom, a chlorine atom, a bromine atom and an iodine atom, and a fluorine atom is preferable.

Examples of the halogenated alkyl group for the substituent include groups in which part or all of the hydrogen atoms within the aforementioned alkyl groups has been substituted with the aforementioned halogen atoms.

The cyclic aliphatic hydrocarbon group may have part of the carbon atoms constituting the ring structure thereof substituted with a substituent containing a hetero atom. As the substituent containing a hetero atom, —O—, —C(═O)—O—, —S—, —S(═O)₂— or —S(═O)₂—O— is preferable.

The aromatic hydrocarbon group as the divalent hydrocarbon group is a divalent hydrocarbon group having at least one aromatic ring, and may have a substituent. The aromatic ring is not particularly limited, as long as it is a cyclic conjugated compound having (4n+2)π electrons (wherein n represents 0 or a natural number), and may be either monocyclic or polycyclic. The aromatic ring preferably has 5 to 30 carbon atoms, more preferably 5 to 20, still more preferably 6 to 15, and most preferably 6 to 12. Here, the number of carbon atoms within a substituent(s) is not included in the number of carbon atoms of the aromatic hydrocarbon group. Examples of the aromatic ring include aromatic hydrocarbon rings, such as benzene, naphthalene, anthracene and phenanthrene; and aromatic hetero rings in which part of the carbon atoms constituting the aforementioned aromatic hydrocarbon rings has been substituted with a hetero atom. Examples of the hetero atom within the aromatic hetero rings include an oxygen atom, a sulfur atom and a nitrogen atom. Specific examples of the aromatic hetero ring include a pyridine ring and a thiophene ring.

Specific examples of the aromatic hydrocarbon group as the divalent hydrocarbon group include a group in which two hydrogen atoms have been removed from the aforementioned aromatic hydrocarbon ring or aromatic hetero ring (arylene group or heteroarylene group); a group in which two hydrogen atoms have been removed from an aromatic compound having two or more aromatic rings (biphenyl, fluorene or the like); and a group in which one hydrogen atom of the aforementioned aromatic hydrocarbon ring or aromatic hetero ring has been substituted with an alkylene group (a group in which one hydrogen atom has been removed from the aryl group within the aforementioned arylalkyl group such as a benzyl group, a phenethyl group, a 1-naphthylmethyl group, a 2-naphthylmethyl group, a 1-naphthylethyl group, or a 2-naphthylethyl group, or a heteroarylalkyl group).

The alkylene group which is bonded to the aforementioned aryl group or heteroaryl group preferably has 1 to 4 carbon atoms, more preferably 1 or 2 carbon atoms, and most preferably 1 carbon atom.

With respect to the aromatic hydrocarbon group, the hydrogen atom within the aromatic hydrocarbon group may be substituted with a substituent. For example, the hydrogen atom bonded to the aromatic ring within the aromatic hydrocarbon group may be substituted with a substituent. Examples of substituents include an alkyl group, an alkoxy group, a halogen atom, a halogenated alkyl group, a hydroxyl group and an oxo group (═O). The alkyl group as the substituent is preferably an alkyl group of 1 to 5 carbon atoms, and a methyl group, an ethyl group, a propyl group, an n-butyl group or a tert-butyl group is particularly desirable.

The alkoxy group as the substituent is preferably an alkoxy group having 1 to 5 carbon atoms, more preferably a methoxy group, ethoxy group, n-propoxy group, iso-propoxy group, n-butoxy group or tert-butoxy group, and most preferably a methoxy group or an ethoxy group.

Examples of the halogen atom for the substituent include a fluorine atom, a chlorine atom, a bromine atom and an iodine atom, and a fluorine atom is preferable.

Examples of the halogenated alkyl group for the substituent include groups in which part or all of the hydrogen atoms within the aforementioned alkyl groups has been substituted with the aforementioned halogen atoms.

(Divalent Linking Group Containing a Hetero Atom)

With respect to a divalent linking group containing a hetero atom, a hetero atom is an atom other than carbon and hydrogen, and examples thereof include an oxygen atom, a nitrogen atom, a sulfur atom and a halogen atom.

In the case where Ya²¹ represents a divalent linking group containing a hetero atom, preferable examples of the linking group include —O—, —C(═O)—O—, —C(═O)—, —C(═O)—NH—, —NH—, —NH—C(═NH)— (wherein H may be substituted with a substituent such as an alkyl group or an acyl group), —S—, —S(═O)₂—, —S(═O)₂—O—, and a group represented by general formula —Y²¹—O—Y²²—, —Y²¹—O—, —Y²¹—C(═O)—O—, —[Y²¹—C(═O)—O]ₘ, —Y²²— or —Y²¹—O—C(═O)—Y²²— [in the formulae, Y²¹ and Y²² each independently represents a divalent hydrocarbon group which may have a substituent, O represents an oxygen atom, and m′ represents an integer of 0 to 3].

When Q¹ represents —C(═O)—NH—, —NH—, or —NH—C(═NH)—, H may be substituted with a substituent such as an alkyl group, an acyl group or the like. The substituent (an alkyl group, an acyl group or the like) preferably has 1 to 10 carbon atoms, more preferably 1 to 8, and most preferably 1 to 5.

In formulae —Y²¹—O—Y²²—, —Y²¹—O—, —Y²¹—C(═O)—O—, —[Y²¹—C(═O)ₘ, —Y²²— and —Y²¹—O—C(═O)—Y²²—, Y²¹ and Y²² each independently represents a divalent hydrocarbon group which may have a substituent. Examples of the divalent hydrocarbon group include the same groups as those described above as the “divalent hydrocarbon group which may have a substituent” in the explanation of the aforementioned divalent linking group.

As Y²¹, a linear aliphatic hydrocarbon group is preferable, more preferably a linear alkylene group, still more preferably a linear alkylene group of 1 to 5 carbon atoms, and a methylene group or an ethylene group is particularly desirable.

As Y²², a linear or branched aliphatic hydrocarbon group is preferable, and a methylene group, an ethylene group or an alkylmethylene group is more preferable. The alkyl group within the alkylmethylene group is preferably a linear alkyl group of 1 to 5 carbon atoms, more preferably a linear alkyl group of 1 to 3 carbon atoms, and most preferably a methyl group.

In the group represented by the formula —[Y²¹—C(═O)—O]_{m′}—Y²²—, m′ represents an integer of 0 to 3, preferably an integer of 0 to 2, more preferably 0 or 1, and most preferably 1. Namely, it is particularly desirable that the group represented by the formula —[Y²²—C(═O)—O]_{m′}—Y²²— is a group represented by the formula —Y²¹—C(═O)—O]_{m′}—Y²²—. Among these, a group represented by the formula —(CH₂)_{a′}—C(═O)—O—(CH₂)_{b′}— is preferable. In the formula, a′ is an integer of 1 to 10, preferably an integer of 1 to 8, more preferably an integer of 1 to 5, still more preferably 1 or 2, and most preferably 1. b′ is an integer of 1 to 10, preferably an integer of 1 to 8, more preferably an integer of 1 to 5, still more preferably 1 or 2, and most preferably 1.

In the present invention, Ya²¹ preferably represents an ester bond [—C(═O)—O—], an ether bond (—O—), a linear or branched alkylene group, a combination of these, or a single bond.

La²¹ represents —O—, —COO—, —CON(R′)— or —OCO—, and R′ represents a hydrogen atom or a methyl group, provided that, when La²¹ represents —O—, Ya²¹ does not represent —CO—.

Ra²¹ represents a lactone-containing cyclic group, a carbonate-containing cyclic group or an —SO₂— containing cyclic group.

The term “lactone-containing cyclic group” refers to a cyclic group including a ring containing a —O—C(═O)— structure (lactone ring). The term “lactone ring” refers to a single ring containing a —O—C(O)— structure, and this ring is counted as the first ring. A lactone-containing cyclic group in which the only ring structure is the lactone ring is referred to as a monocyclic group, and groups containing other ring structures are described as polycyclic groups regardless of the structure of the other rings. The lactone-containing cyclic group may be either a monocyclic group or a polycyclic group.

The lactone-containing cyclic group for Ra²¹ is not particularly limited, and an arbitrary group may be used. Specific examples include groups represented by general formulas (a2-r-1) to (a2-r-7) shown below.

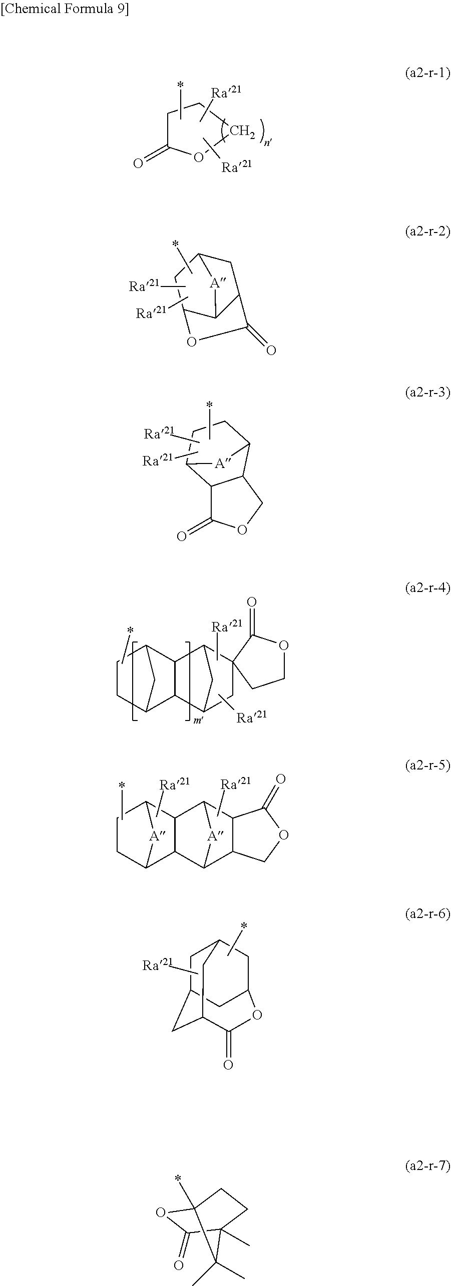

In the formulae, each Ra′²¹ independently represents a hydrogen atom, an alkyl group, an alkoxy group, a halogen atom, a halogenated alkyl group, a hydroxy group, —COOR″, —OC(═O)R″, a hydroxyalkyl group or a cyano group; R″ represents a hydrogen atom or an alkyl group; A″ represents an oxygen atom, a sulfur atom or an alkylene group of 1 to 5 carbon atoms which may contain an oxygen atom or a sulfur atom; n′ represents an integer of 0 to 2; and m′ represents 0 or 1.

In general formulae (a2-r-1) to (a2-r-7) above, A″ represents an oxygen atom (—O—), a sulfur atom (—S—) or an alkylene group of 1 to 5 carbon atoms which may contain an oxygen atom or a sulfur atom. As the alkylene group of 1 to 5 carbon atoms for A″, a linear or branched alkylene group is preferable, and examples thereof include a methylene group, an ethylene group, an n-propylene group and an isopropylene group. Examples of alkylene groups that contain an oxygen atom or a sulfur atom include the aforementioned alkylene groups in which —O—or —S— is bonded to the terminal of the alkylene group or present between the carbon atoms of the alkylene group. Specific examples of such alkylene groups include —O—CH₂—, —CH₂—O—CH₂—, —S—CH₂— and —CH₂—S—CH₂—. As A″, an alkylene group of 1 to 5 carbon atoms or —O— is preferable, more preferably an alkylene group of 1 to 5 carbon atoms, and most preferably a methylene group. As the alkyl group, alkoxy group, halogenated alkyl group, —COOR″, —OC(═O)R″ and hydroxyalkyl group for Ra′²¹, the same alkyl groups, alkoxy groups, halogenated alkyl groups, —COOR″, —OC(═O)R″ and hydroxyalkyl groups as those described above as the substituent for the divalent cyclic group (which may have a substituent) for V₀^{a1} can be mentioned.

Specific examples of the groups represented by the aforementioned general formulae (a2-r-1) to (a2-r-7) are shown below.

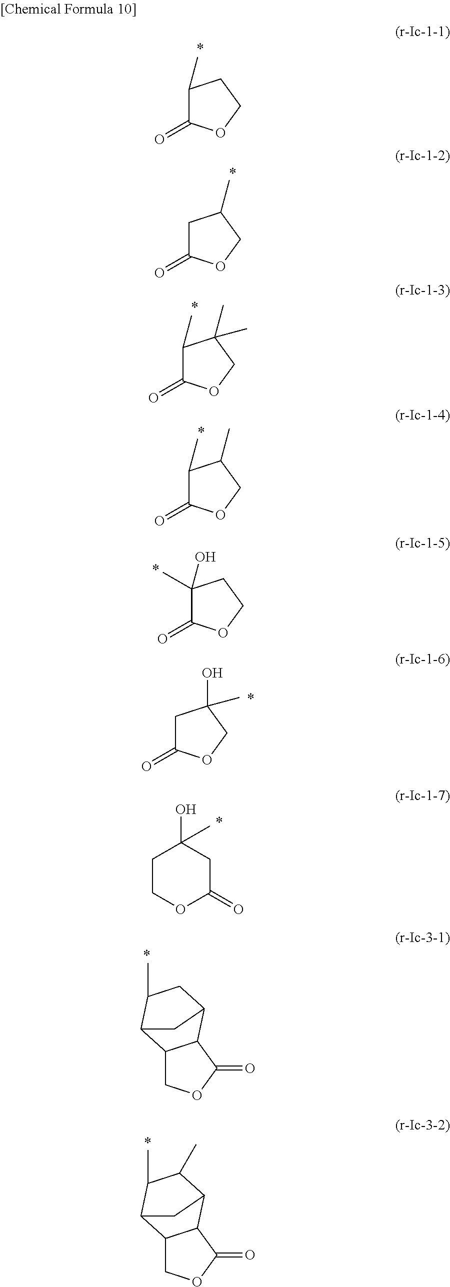

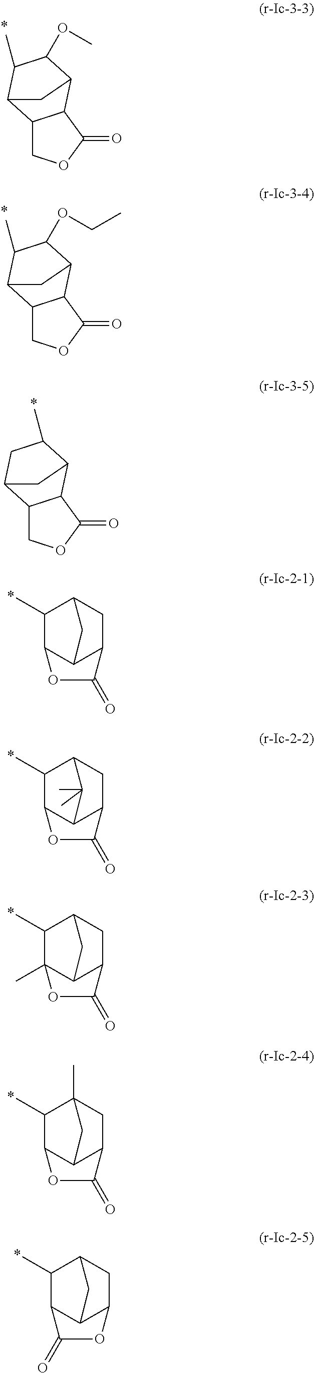

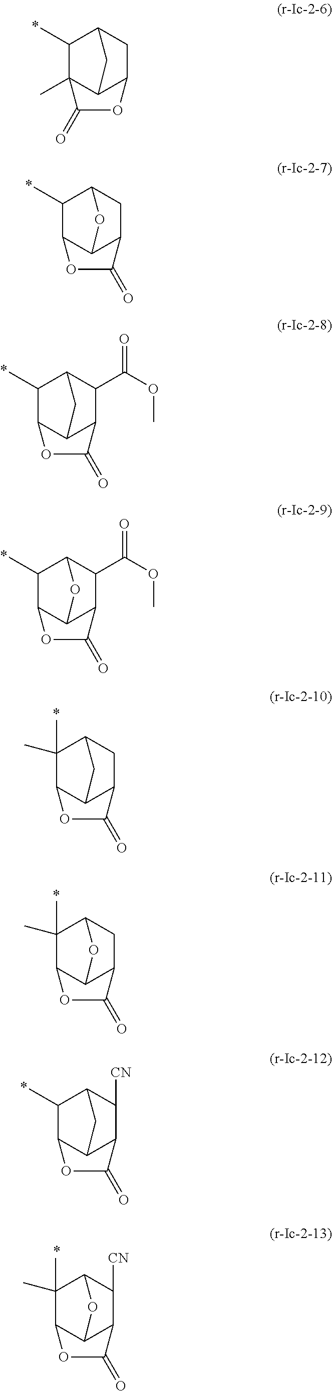

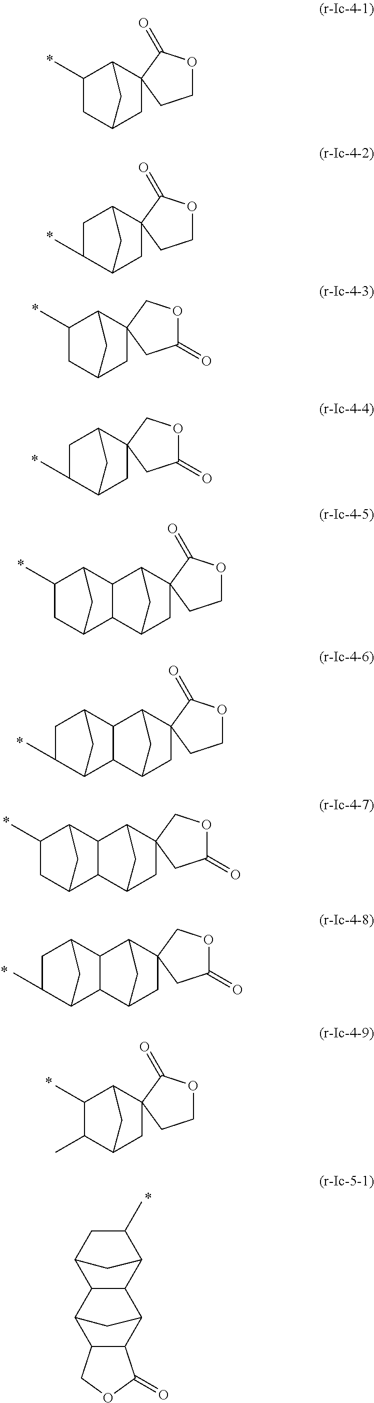

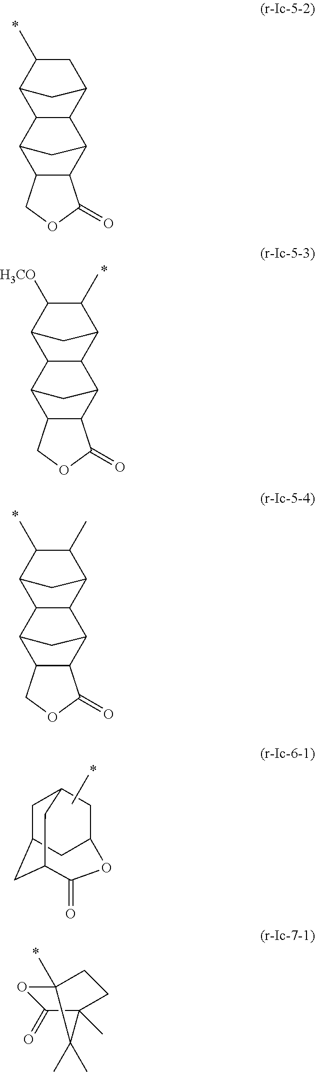

By virtue of the structural unit (a2) having a lactone ring-containing cyclic group, it is considered that the Tf temperature of the component (A1) described later is lowered. By virtue of the Tf of the base component (A) being lowered, baking can be conducted at a low temperature, and a resist composition having excellent lithography properties and resolution can be provided. In the present invention, the structural unit (a2) preferably has, as a lactone ring-containing group, a group represented by the aforementioned chemical formula (r-1c-1-1) or (r-1c-7-1).

The term “carbonate-containing cyclic group” refers to a cyclic group including a ring containing a —O—C(═O)—O— structure (carbonate ring). The term “carbonate ring” refers to a single ring containing a —O—C(═O)—O— structure, and this ring is counted as the first ring. A carbonate-containing cyclic group in which the only ring structure is the carbonate ring is referred to as a monocyclic group, and groups containing other ring structures are described as polycyclic groups regardless of the structure of the other rings. The carbonate-containing cyclic group may be either a monocyclic group or a polycyclic group.

The carbonate-containing cyclic group for Ra²¹ is not particularly limited, and an arbitrary group may be used. Specific examples include groups represented by general formulas (ax3-r-1) to (ax3-r-3) shown below.

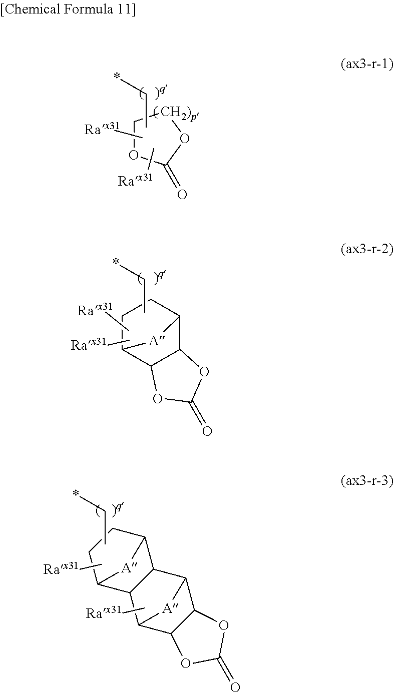

In the formulae, each Ra′³¹ independently represents a hydrogen atom, an alkyl group, an alkoxy group, a halogen atom, a halogenated alkyl group, a hydroxy group, —COOR″, —OC(═O)R″, a hydroxyalkyl group or a cyano group; R″ represents a hydrogen atom or an alkyl group; A″ represents an oxygen atom, a sulfur atom or an alkylene group of 1 to 5 carbon atoms which may contain an oxygen atom or a sulfur atom; p′ represents an integer of 1 to 3; q′ represents 0 or 1; and * represents a valence bond.

In general formulae (ax3-r-1) to (ax3-r-3), A″ is the same as defined for A″ in general formulae (a2-r-1) to (a2-r-7). The alkyl group, alkoxy group, halogen atom, halogenated alkyl group, —COOR″, —OC(═O)R″ and hydroxyalkyl group for Ra′^{x31} in the aforementioned formulae (ax3-r-1) to (ax3-r-3) are the same as defined for Ra′²¹ in the aforementioned general formulae (a2-r-1) to (a2-r-7).

Specific examples of the groups represented by the aforementioned general formulae (ax3-r-1) to (ax3-r-3) are shown below.

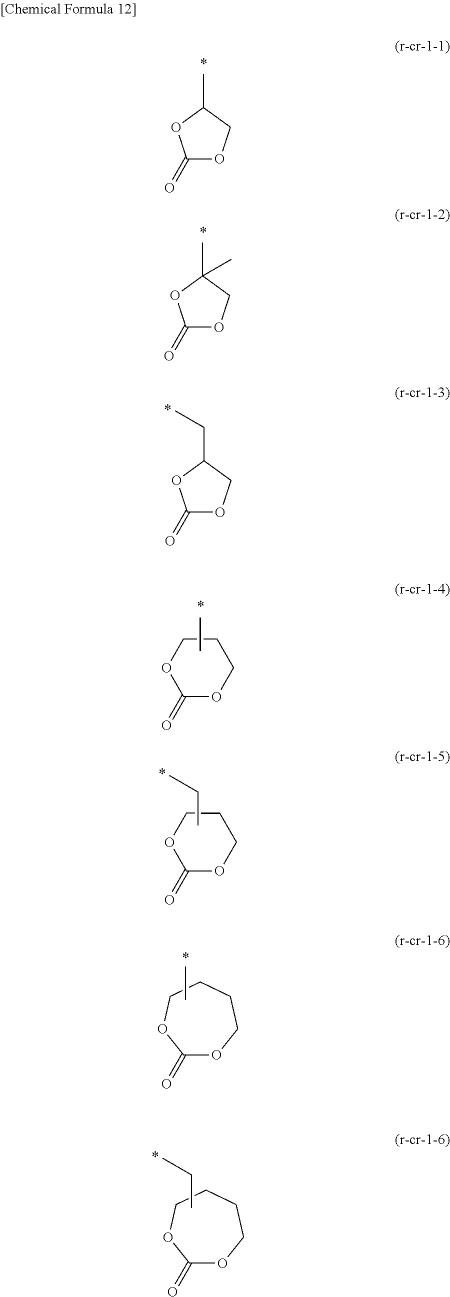

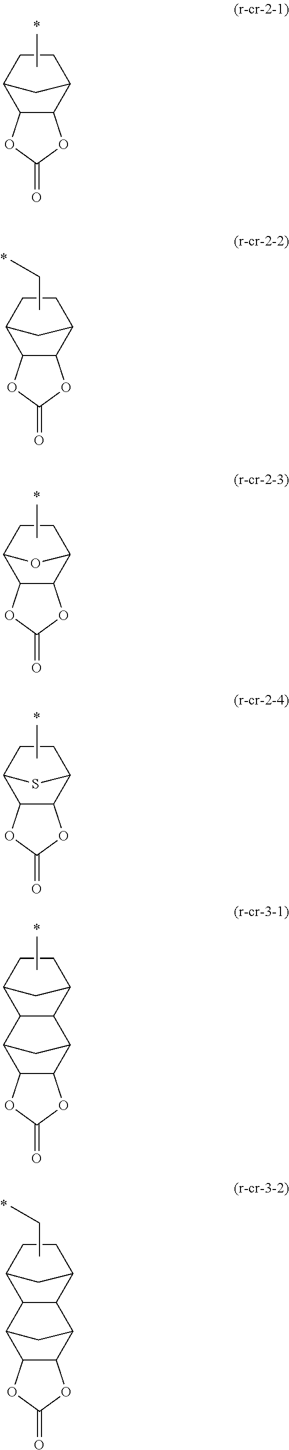

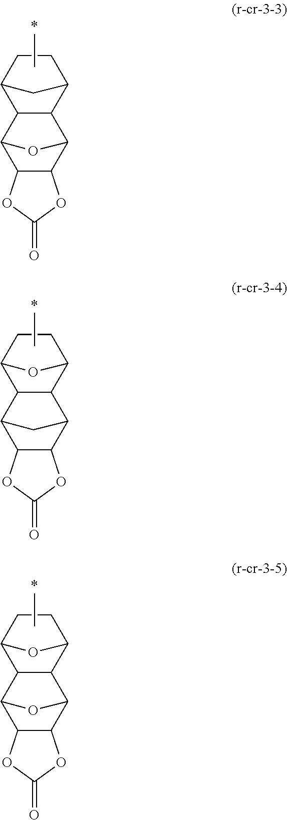

Here, an “—SO₂— containing cyclic group” for Ra²¹ refers to a cyclic group having a ring containing —SO₂— within the ring structure thereof, i.e., a cyclic group in which the sulfur atom (S) within —SO₂— forms part of the ring skeleton of the cyclic group. The ring containing —SO₂— within the ring skeleton thereof is counted as the first ring. A cyclic group in which the only ring structure is the ring that contains —SO₂— in the ring skeleton thereof is referred to as a monocyclic group, and a group containing other ring structures is described as a polycyclic group regardless of the structure of the other rings. The —SO₂— containing cyclic group may be either a monocyclic group or a polycyclic group.

As the —SO₂— containing cyclic group, a cyclic group containing —O—SO₂— within the ring skeleton thereof, i.e., a cyclic group containing a sultone ring in which —O—S— within the —O—SO₂— group forms part of the ring skeleton thereof is particularly desirable. More specific examples of the —SO₂— containing cyclic group include groups represented by general formulas (a5-r-1) to (a5-r-4) shown below.

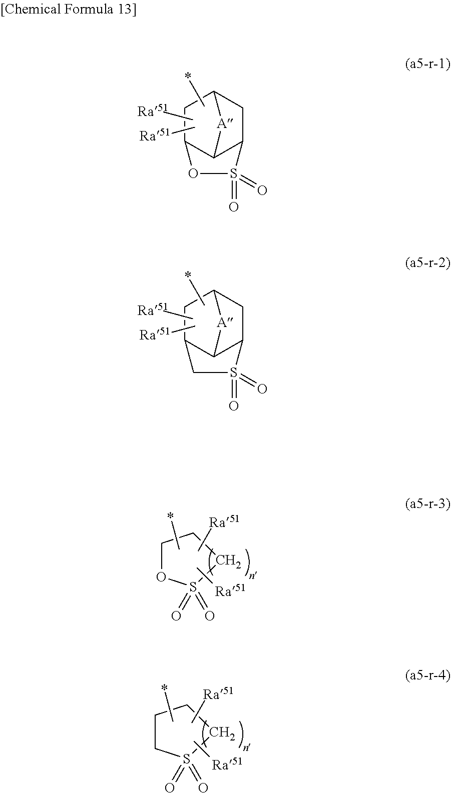

In the formulae, each Ra′⁵¹ independently represents a hydrogen atom, an alkyl group, an alkoxy group, a halogen atom, a halogenated alkyl group, a hydroxy group, —COOR″, —OC(═O)R″, a hydroxyalkyl group or a cyano group; R″ represents a hydrogen atom or an alkyl group; A″ represents an oxygen atom, a sulfur atom or an alkylene group of 1 to 5 carbon atoms which may contain an oxygen atom or a sulfur atom; and n′ represents an integer of 0 to 2.

In general formulae (a5-r-1) to (a5-r-4), A″ is the same as defined for A″ in general formulae (a2-r-1) to (a2-r-7). The alkyl group, alkoxy group, halogen atom, halogenated alkyl group, —COOR″, —OC(═O)R″ and hydroxyalkyl group for Ra′⁵¹ are the same as defined for Ra′²¹ in the aforementioned general formulae (a2-r-1) to (a2-r-7).

Specific examples of the groups represented by the aforementioned general formulas (a5-r-1) to (a5-r-4) are shown below. In the formulae shown below, “Ac” represents an acetyl group.

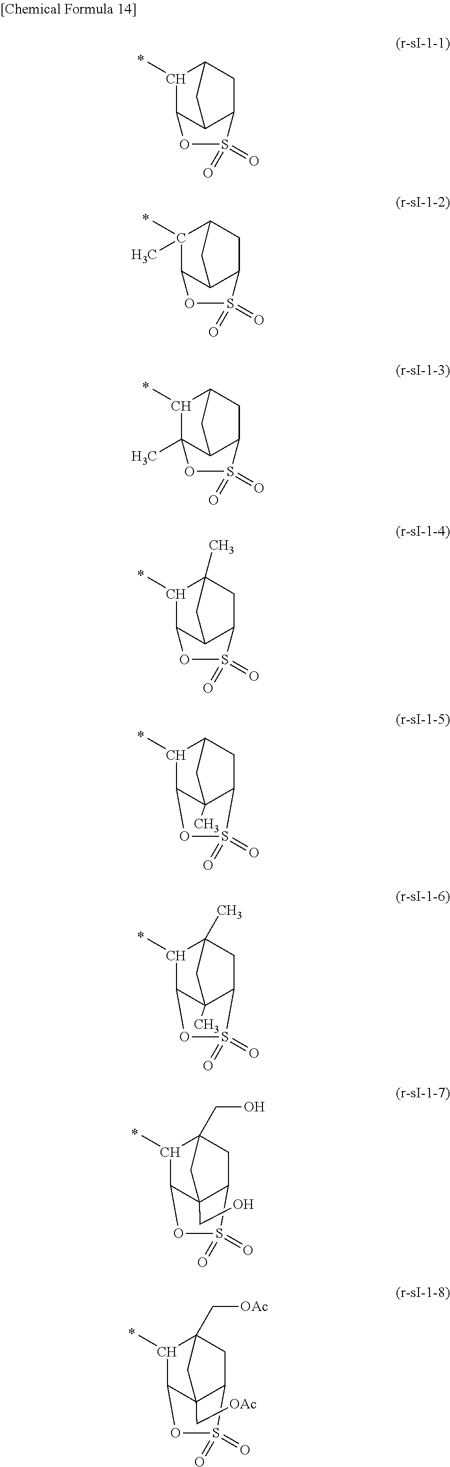

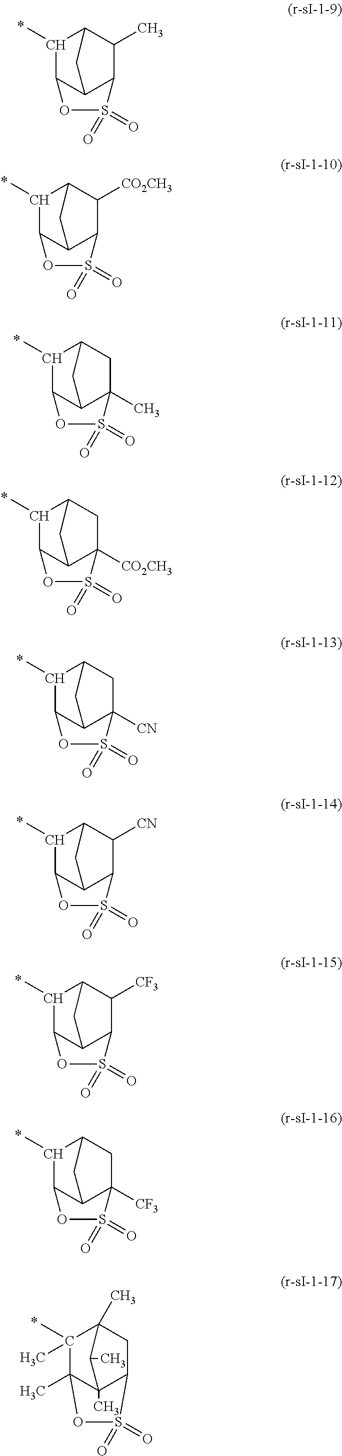

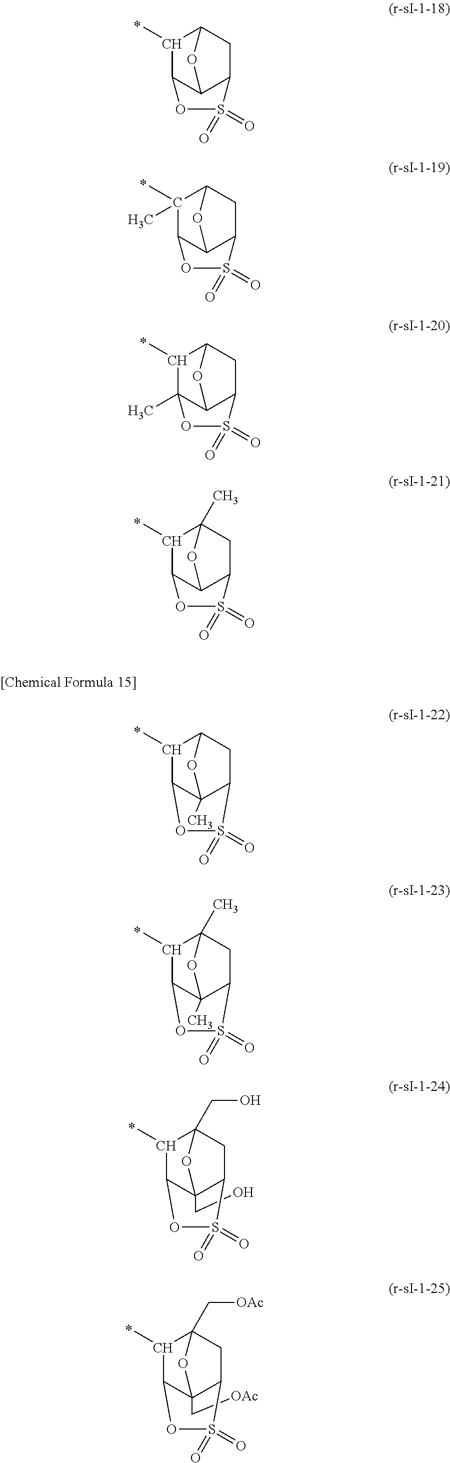

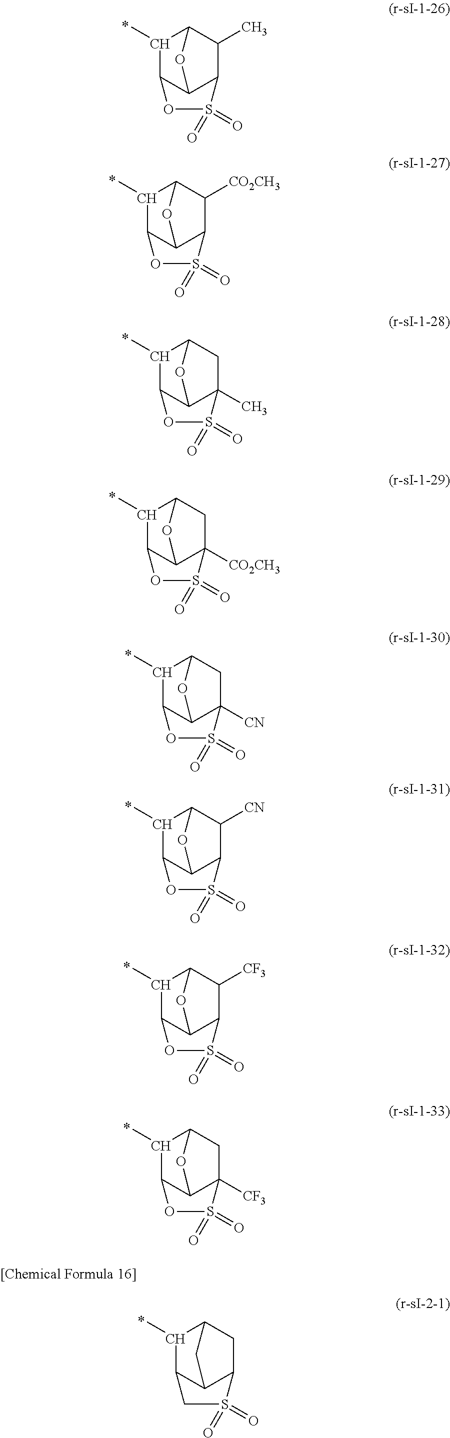

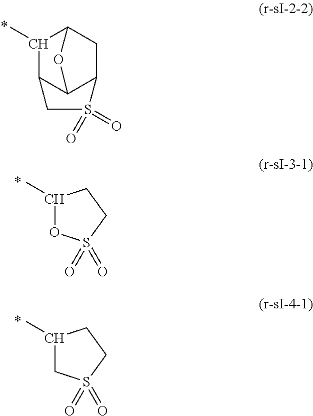

As the —SO₂— containing cyclic group, a group represented by the aforementioned general formula (a5-r-1) is preferable, at least one member selected from the group consisting of groups represented by the aforementioned chemical formulas (r-s1-1-1), (r-s1-1-18), (r-s1-3-1) and (r-s1-4-1) is more preferable, and a group represented by chemical formula (r-s1-1-1) is most preferable.

Specific examples of structural units represented by general formula (a2) are shown below. In the formulae shown below, R^{a} represents a hydrogen atom, a methyl group or a trifluoromethyl group.

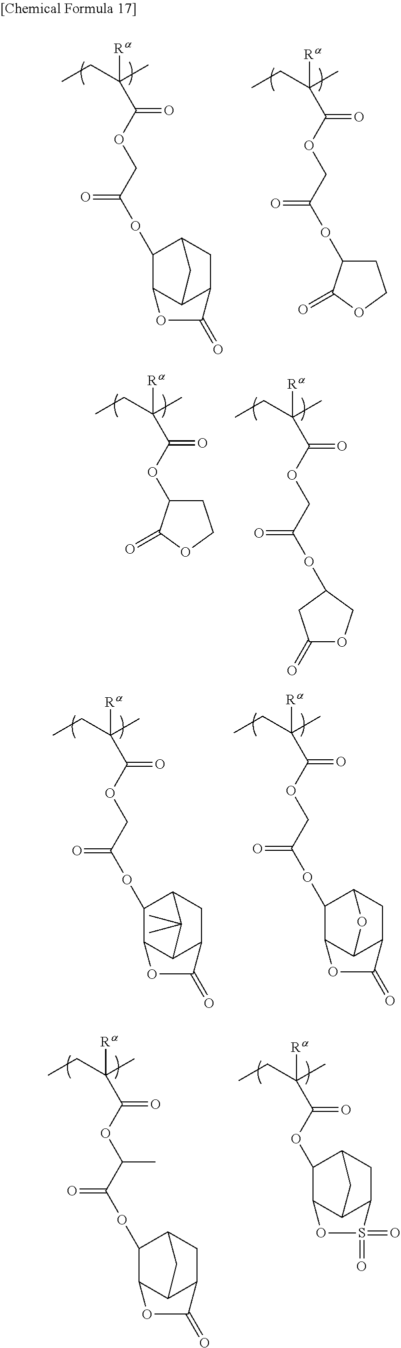

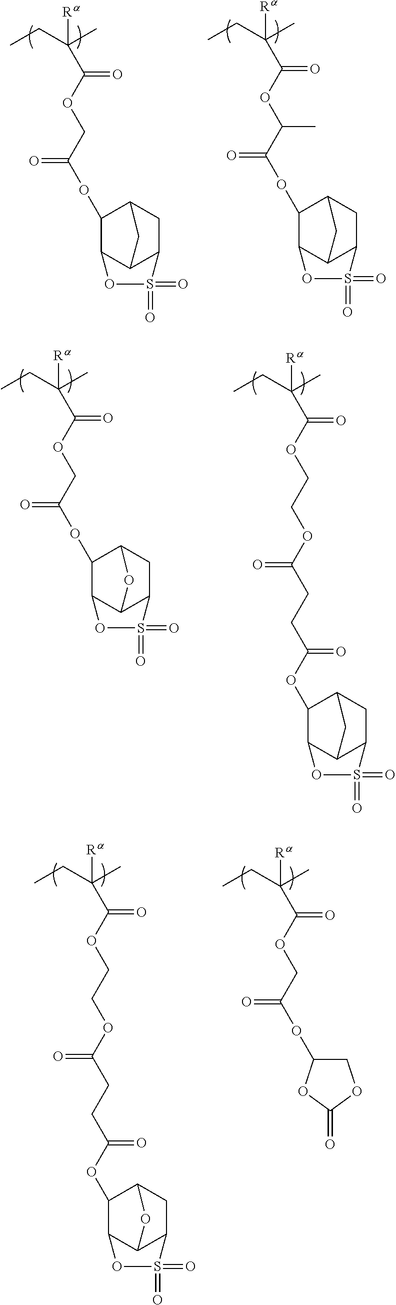

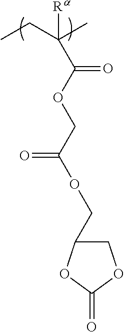

(Structural Unit (a1))

The base component (A) preferably contains a structural unit (a1). The structural unit (a1) is a structural unit containing an acid decomposable group that exhibits increased polarity by the action of acid.

The term “acid decomposable group” refers to a group in which at least a part of the bond within the structure thereof is cleaved by the action of an acid.

Examples of acid decomposable groups which exhibit increased polarity by the action of an acid include groups which are decomposed by the action of an acid to form a polar group.

Examples of the polar group include a carboxy group, a hydroxy group, an amino group and a sulfo group (—SO₃H). Among these, a polar group containing —OH in the structure thereof (hereafter, referred to as “OH-containing polar group”) is preferable, a carboxy group or a hydroxy group is more preferable, and a carboxy group is particularly desirable.

More specifically, as an example of an acid decomposable group, a group in which the aforementioned polar group has been protected with an acid dissociable group (such as a group in which the hydrogen atom of the OH-containing polar group has been protected with an acid dissociable group) can be given.

Here, the “acid dissociable group” includes:

(i) a group in which the bond between the acid dissociable group and the adjacent atom is cleaved by the action of acid; and

(ii) a group in which one of the bonds is cleaved by the action of acid, and then a decarboxylation reaction occurs, thereby cleaving the bond between the acid dissociable group and the adjacent atom.

It is necessary that the acid dissociable group that constitutes the acid decomposable group is a group which exhibits a lower polarity than the polar group generated by the dissociation of the acid dissociable group. Thus, when the acid dissociable group is dissociated by the action of acid, a polar group exhibiting a higher polarity than that of the acid dissociable group is generated, thereby increasing the polarity. As a result, the polarity of the entire component (A1) is increased. By the increase in the polarity, the solubility in an alkali developing solution changes and, the solubility in an organic developing solution is relatively decreased.

The acid dissociable group is not particularly limited, and any of the groups that have been conventionally proposed as acid dissociable groups for the base resins of chemically amplified resists can be used.

Examples of the acid dissociable group for protecting the carboxy group or hydroxy group as a polar group include the acid dissociable group represented by general formula (a1-r-1) shown below (hereafter, for the sake of convenience, sometimes referred to as “acetal-type acid dissociable group”).

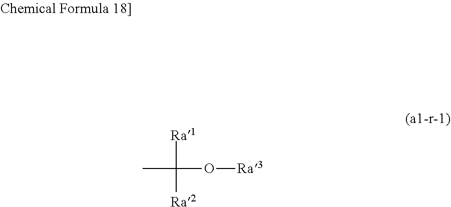

In the formula, Ra′¹ and Ra′² represents a hydrogen atom or an alkyl group; and Ra′³ represents a hydrocarbon group, provided that Ra′³ may be bonded to Ra′¹ or Ra′².

In formula (a1-r-1), as the lower alkyl group for Ra′¹ and Ra′², the same lower alkyl groups as those described above the alkyl groups as the substituent which may be bonded to the carbon atom on the α-position of the aforementioned α-substituted alkylester can be used, although a methyl group or ethyl group is preferable, and a methyl group is particularly desirable.

The hydrocarbon group for Ra′³ is preferably an alkyl group of 1 to 20 carbon atoms, more preferably an alkyl group of 1 to 10 carbon atoms, and still more preferably a linear or branched alkyl group. Specific examples thereof include a methyl group, an ethyl group, a propyl group, an isopropyl group, an n-butyl group, an isobutyl group, a tert-butyl group, a pentyl group, an isopentyl group, a neopentyl group, a 1,1-dimethylethyl group, a 1,1-diethylpropyl group, a 2,2-dimethylpropyl group and a 2,2-dimethylbutyl group.

In the case where Ra′³ is bonded to Ra′¹ or Ra′² to form a ring, the cyclic group is preferably a 4 to 7-membered ring, and more preferably a 4 to 6-membered ring. Specific examples of the cyclic group include tetrahydropyranyl group and tetrahydrofuranyl group.

Examples of the acid dissociable group for protecting the carboxy group as a polar group include the acid dissociable group represented by general formula (a1-r-2) shown below (hereafter, with respect to the acid dissociable group represented by the following formula (a1-r-2), the acid dissociable group constituted of alkyl groups is referred to as “tertiary ester-type acid dissociable group”).

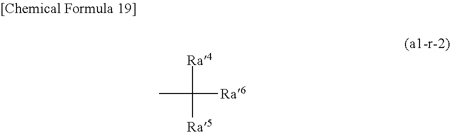

In the formula, Ra′⁴ to Ra′⁶ each independently represents a hydrocarbon group, provided that Ra′⁵ and Ra′⁶ may be mutually bonded to form a ring.

As the hydrocarbon group for Ra′⁴ to Ra′⁶, the same groups as those described above for Ra′³ can be mentioned. Ra′⁴ is preferably an alkyl group having from 1 to 5 carbon atoms. In the case where Ra′⁵ and Ra′⁶ are mutually bonded to form a ring, a group represented by general formula (a1-r2-1) shown below can be mentioned.

Examples of the acid dissociable group for protecting a hydroxy group as a polar group include the acid dissociable group represented by general formula (a1-r-3) shown below (hereafter, referred to as “tertiary alkyloxycarbonyl-type acid dissociable group”).

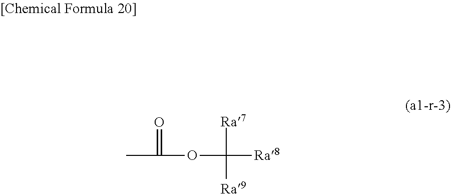

In the formula, Ra′⁷ to Ra′⁹ each independently represents an alkyl group.

In the formula (a1-r-3), Ra′⁷ to Ra′⁹ is preferably an alkyl group of 1 to 5 carbon atoms, and more preferably an alkyl group of 1 to 3 carbon atoms.

Further, the total number of carbon atoms within the alkyl group is preferably 3 to 7, more preferably 3 to 5, and most preferably 3 or 4.

Examples of the structural unit (a1) include a structural unit derived from an acrylate ester which may have the hydrogen atom bonded to the carbon atom on the α-position substituted with a substituent and contains an acid decomposable group which exhibits increased polarity by the action of acid; a structural unit derived from hydroxystyrene or a hydroxystyrene derivative in which at least a part of the hydrogen atom of the hydroxy group is protected with a substituent containing an acid decomposable group; and a structural unit derived from vinylbenzoic acid or a vinylbenzoic acid derivative in which at least a part of the hydrogen atom within —C(═O)—OH is protected with a substituent containing an acid decomposable group.

As the structural unit (a1), a structural unit derived from an acrylate ester which may have the hydrogen atom bonded to the carbon atom on the α-position substituted with a substituent is preferable.

As the structural unit (a1), a structural unit represented by general formula (a1-1) shown below is preferable.

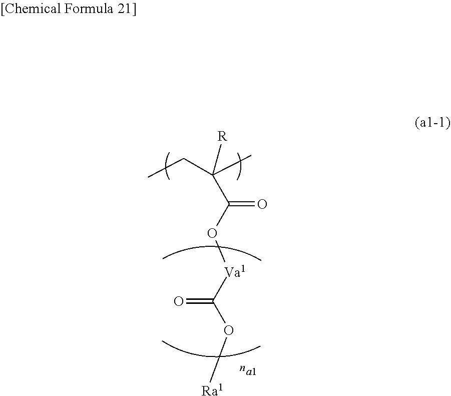

In the formulae, R represents a hydrogen atom, an alkyl group of 1 to 5 carbon atoms or a halogenated alkyl group of 1 to 5 carbon atoms; Va¹ represents a divalent hydrocarbon group; nₐₗ each independently represents an integer of 0 to 2; Ra¹ represents an acid dissociable group represented by the aforementioned formula (a1-r-1) or (a1-r-2);

In formula (a1-1), as the alkyl group of 1 to 5 carbon atoms for R, a linear or branched alkyl group of 1 to 5 carbon atoms is preferable, and specific examples thereof include a methyl group, an ethyl group, a propyl group, an isopropyl group, an n-butyl group, an isobutyl group, a tert-butyl group, a pentyl group, an isopentyl group and a neopentyl group. The halogenated alkyl group of 1 to 5 carbon atoms represented by R is a group in which part or all of the hydrogen atoms of the aforementioned alkyl group of 1 to 5 carbon atoms have been substituted with halogen atoms. Examples of the halogen atom include a fluorine atom, a chlorine atom, a bromine atom and an iodine atom, and a fluorine atom is particularly desirable.

As R, a hydrogen atom, an alkyl group of 1 to 5 carbon atoms or a fluorinated alkyl group of 1 to 5 carbon atoms is preferable, and a hydrogen atom or a methyl group is particularly desirable in terms of industrial availability.

The hydrocarbon group for Va¹ may be either an aliphatic hydrocarbon group or an aromatic hydrocarbon group. An “aliphatic hydrocarbon group” refers to a hydrocarbon group that has no aromaticity. The aliphatic hydrocarbon group as the divalent hydrocarbon group for Va¹ may be either saturated or unsaturated. In general, the aliphatic hydrocarbon group is preferably saturated.

As specific examples of the aliphatic hydrocarbon group, a linear or branched aliphatic hydrocarbon group, and an aliphatic hydrocarbon group containing a ring in the structure thereof can be given.

The linear or branched aliphatic hydrocarbon group preferably has 1 to 10 carbon atoms, more preferably 1 to 6, still more preferably 1 to 4, and most preferably 1 to 3.

As the linear aliphatic hydrocarbon group, a linear alkylene group is preferable. Specific examples thereof include a methylene group [—CH₂—], an ethylene group [—(CH₂)₂—], a trimethylene group [—(CH₂)₃—], a tetramethylene group [—(CH₂)₄—] and a pentamethylene group [—(CH₂)₅]—.

As the branched aliphatic hydrocarbon group, branched alkylene groups are preferred, and specific examples include various alkylalkylene groups, including alkylmethylene groups such as —CH(CH₃)—, —CH(CH₂CH₃)—, —C(CH₃)₂—, —C(CH₃)(CH₂CH₃)—, —C(CH₃)(CH₂CH₂CH₃)—, and —C(CH₂CH₃)₂—; alkylethylene groups such as —CH(CH₃)CH₂—, —CH(CH₃)CH(CH₃)—, —C(CH₃)₂CH₂—, —CH(CH₂CH₃)CH₂—, and —C(CH₂CH₃)₂—CH₂—; alkyltrimethylene groups such as —CH(CH₃)CH₂CH₂—, and —CH₂CH(CH₃)CH₂—; and alkyltetramethylene groups such as —CH(CH₃)CH₂CH₂CH₂—, and —CH₂CH(CH₃)CH₂CH₂—. As the alkyl group within the alkylalkylene group, a linear alkyl group of 1 to 5 carbon atoms is preferable.

As examples of the hydrocarbon group containing a ring in the structure thereof, an alicyclic hydrocarbon group (a group in which two hydrogen atoms have been removed from an aliphatic hydrocarbon ring), a group in which the alicyclic hydrocarbon group is bonded to the terminal of the aforementioned chain-like aliphatic hydrocarbon group, and a group in which the alicyclic group is interposed within the aforementioned linear or branched aliphatic hydrocarbon group, can be given. As the linear or branched aliphatic hydrocarbon group, the same groups as those described above can be used.

The alicyclic hydrocarbon group preferably has 3 to 20 carbon atoms, and more preferably 3 to 12 carbon atoms.

The alicyclic hydrocarbon group may be either a monocyclic group or a polycyclic group. As the monocyclic aliphatic hydrocarbon group, a group in which 2 hydrogen atoms have been removed from a monocycloalkane is preferable. The monocycloalkane preferably has 3 to 6 carbon atoms, and specific examples thereof include cyclopentane and cyclohexane. As the polycyclic group, a group in which two hydrogen atoms have been removed from a polycycloalkane is preferable, and the polycyclic group preferably has 7 to 12 carbon atoms. Examples of the polycycloalkane include adamantane, norbornane, isobornane, tricyclodecane and tetracyclododecane.

The aromatic hydrocarbon group is a hydrocarbon group having an aromatic ring.

The aromatic hydrocarbon group as the divalent hydrocarbon group for Va¹ preferably has 3 to 30 carbon atoms, more preferably 5 to 30, still more preferably 5 to 20, still more preferably 6 to 15, and most preferably 6 to 10. Here, the number of carbon atoms within a substituent(s) is not included in the number of carbon atoms of the aromatic hydrocarbon group.

Examples of the aromatic ring contained in the aromatic hydrocarbon group include aromatic hydrocarbon rings, such as benzene, biphenyl, fluorene, naphthalene, anthracene and phenanthrene; and aromatic hetero rings in which part of the carbon atoms constituting the aforementioned aromatic hydrocarbon rings has been substituted with a hetero atom. Examples of the hetero atom within the aromatic hetero rings include an oxygen atom, a sulfur atom and a nitrogen atom.

Specific examples of the aromatic hydrocarbon group include a group in which two hydrogen atoms have been removed from the aforementioned aromatic hydrocarbon ring (arylene group); and a group in which one hydrogen atom has been removed from the aforementioned aromatic hydrocarbon ring (aryl group) and one hydrogen atom has been substituted with an alkylene group (such as a benzyl group, a phenethyl group, a 1-naphthylmethyl group, a 2-naphthylmethyl group, a 1-naphthylethyl group, or a 2-naphthylethyl group). The alkylene group (alkyl chain within the arylalkyl group) preferably has 1 to 4 carbon atom, more preferably 1 or 2, and most preferably 1.

Specific examples of the structural unit (a1-1) is shown below. In the formulae shown below, R^{α} represents a hydrogen atom, a methyl group or a trifluoromethyl group.

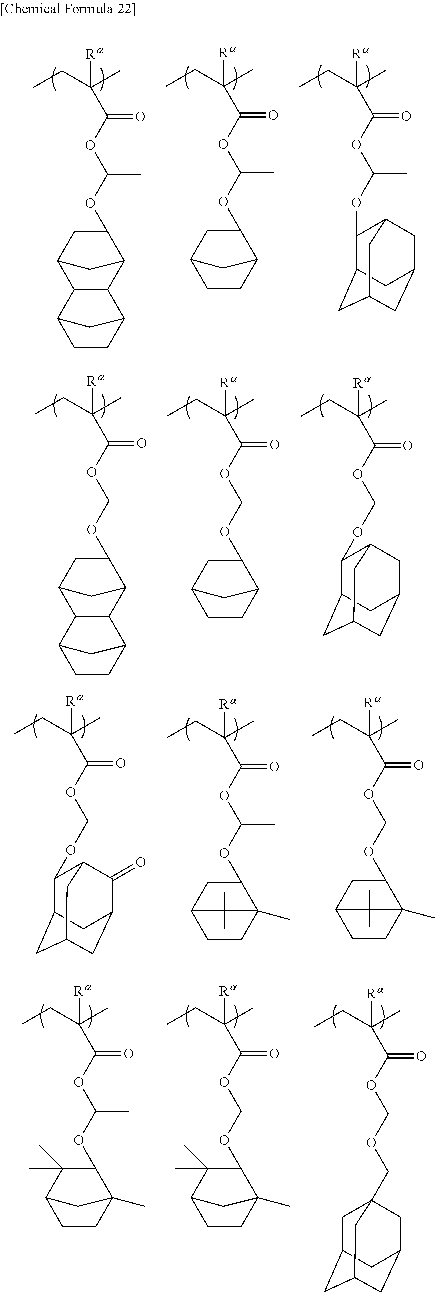

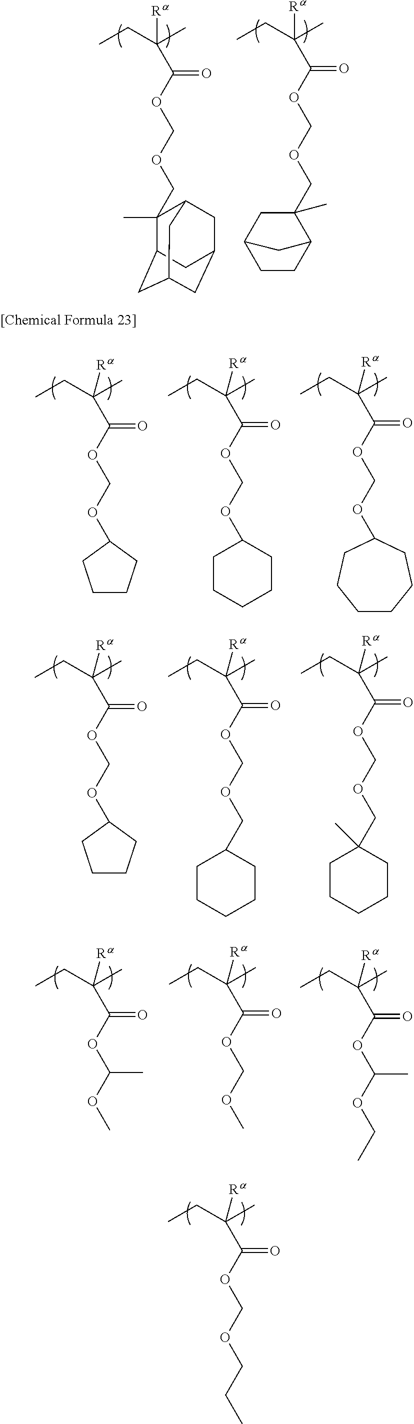

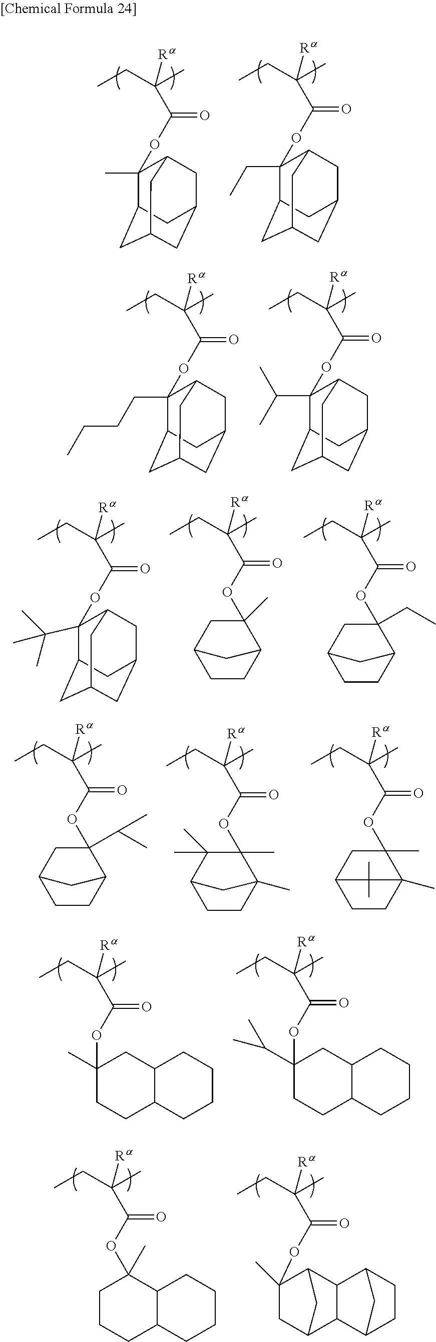

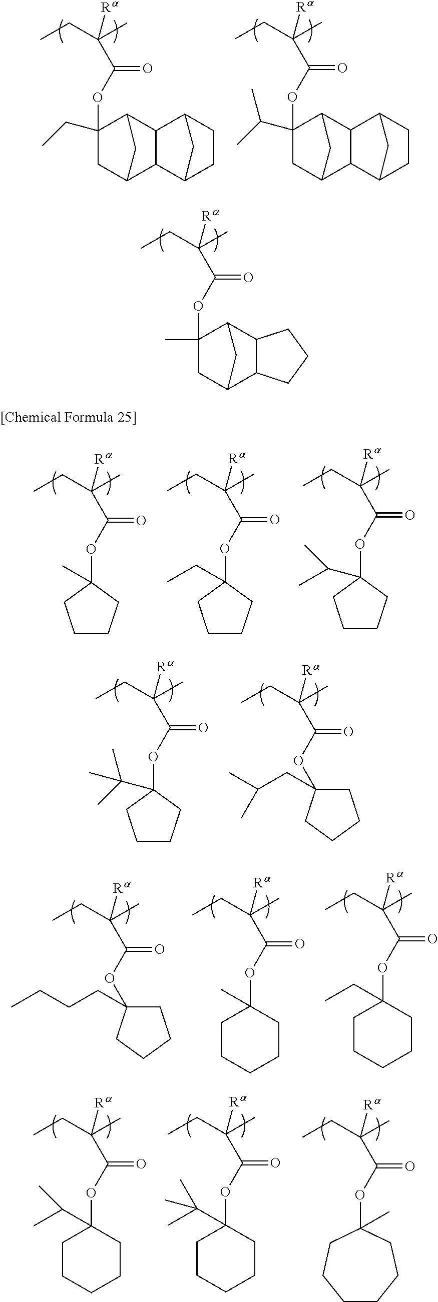

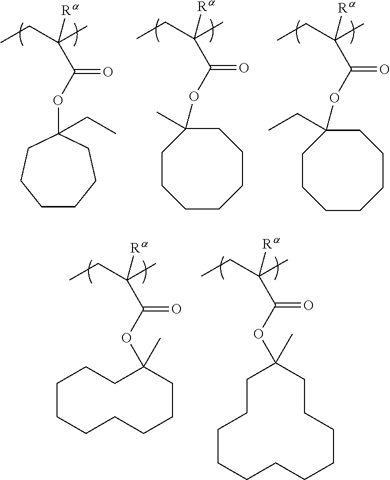

In the component (A), the amount of the structural unit (a1) based on the combined total of all structural units constituting the component (A) is preferably 20 to 80 mol %, more preferably 20 to 75 mol %, and still more preferably 25 to 70 mol %. By ensuring the lower limit, various lithography properties such as sensitivity, resolution and LWR are improved. On the other hand, when the amount of the structural unit (a1) is no more than the upper limit of the above-mentioned range, a good balance can be achieved with the other structural units.

(Structural Unit (a9))

The resist composition of the present invention preferably includes a structural unit (a9) containing a fluoroalkylsulfonylamino group, an aminosulfonyl group, a C(═O)—NH—C(═O)— group or a phenolic hydroxy group. The structural unit (a9) is a structural unit which generates proton upon exposure. By virtue of introducing the structural unit (a9), it is considered that the acid generation efficiency is improved, and deprotection more reliably proceeds, thereby contributing to reduction of LER.

The structural unit (a9) preferably has a group represented by general formula (a9-r-1) or (a9-r-2) shown below.

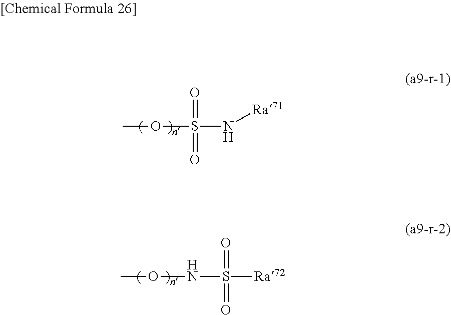

In the formulae, Ra′⁷¹ and Ra′⁷² each independently represents a hydrogen atom, an alkyl group or a fluorinated alkyl group; and n′ represents 0 or 1.

In general formula (a9-r-1) or (a9-r-2), as the alkyl group, an linear or branched alkyl group of 1 to 5 carbon atoms is preferable, and as the fluorinated alkyl group, a group in which part or all of the hydrogen atoms within a linear or branched alkyl group of 1 to 5 carbon atoms is preferable.

Examples of the structural unit having a group represented by general formula (a9-r-1) or (a9-r-2) include a structural unit represented by general formula (a9-1) or (a9-2) shown below.

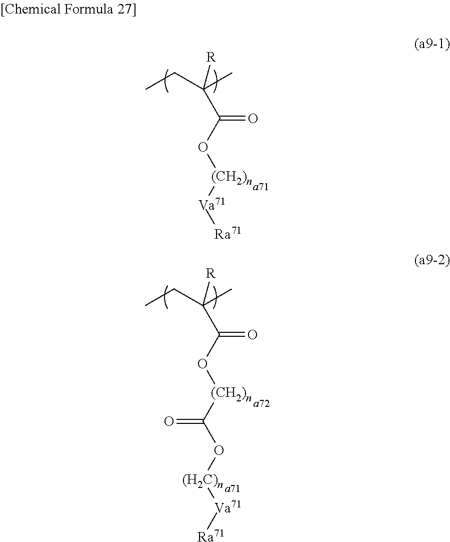

In the formulae, R is the same as defined above; each Va⁷¹ independently represents a divalent aliphatic cyclic group; each na⁷¹ independently represents an integer of 0 to 3; na⁷² represents an integer of 1 to 5; and each Ra⁷¹ independently represents a group represented by the aforementioned formula (a9-r-1) or (a9-r-2).

The divalent aliphatic cyclic group for Va⁷¹ in the formula (a9-1) or (a9-2) is the same as defined for the aliphatic hydrocarbon group containing a ring described above in the explanation of the divalent hydrocarbon group (which may have a substituent) for the divalent linking group represented by Ya²¹ in the aforementioned general formula (a2).

Further, as the structural unit (a9), a structural unit represented by general formula (a9-3) shown below may be included.

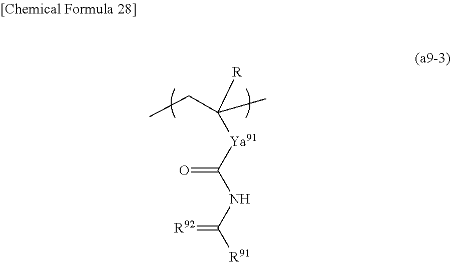

In the formula, R is the same as defined above; Ya⁹¹ represents a single bond or a divalent linking group; R⁹¹ represents a cyclic group which may have a substituent, a chain-like alkyl group which may have a substituent or a chain-like alkenyl group which may have a substituent; and R⁹² represents an oxygen atom or a sulfur atom.

In the formula (a9-3), the divalent linking group for Ya⁹¹ is the same as defined above for the divalent linking group represented by Ya²¹ in general formula (a2). The hydrocarbon group (which may have a substituent) for R⁹¹ may be an aromatic hydrocarbon group or an aliphatic hydrocarbon group.

The cyclic group (which may have a substituent), the chain-like alkyl group (which may have a substituent) and the chain-like alkenyl group (which may have a substituent) for R⁹¹ is the same as defined for R¹⁰¹ described later, and is preferably a cyclic group (which may have a substituent) or a chain-like alkyl group (which may have a substituent).

Preferable examples of the cyclic group (which may have a substituent) include a moncycloalkyl group such as a cyclopentyl group or a cyclohexyl group; a polycylcloalkyl group such as an adamantyl group, a norbornyl group or a tricyclodecyl group; an aryl group such as a phenyl group or a naphthyl group, or a fluorinated aryl group; a lactone-containing cyclic group represented by any one of the aforementioned general formulae (a2-r-1) to (a2-r-7); and an —SO₂— containing cyclic group represented by any one of the aforementioned general formulae (a5-r-1) to (a5-r-4).

As the chain-like alkyl group (which may have a substituent), an alkyl group of 1 to 10 carbon atoms or an alkyl group having the aforementioned cyclic group as a substituent is preferable.

Specific examples of the structural units represented by general formulae (a9-1) to (a9-3) are shown below. In the formulae shown below, R^{α} represents a hydrogen atom, a methyl group or a trifluoromethyl group.

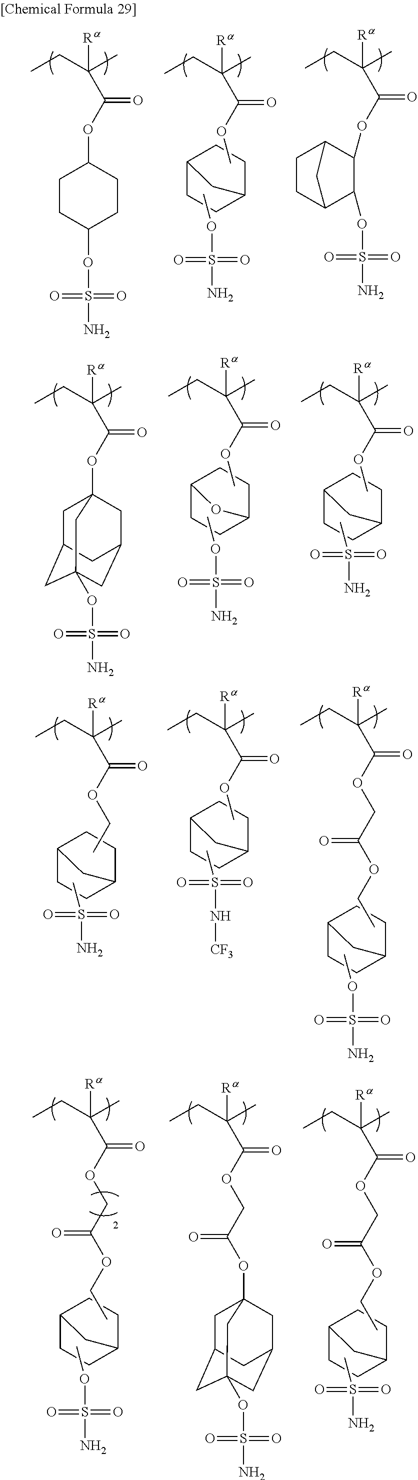

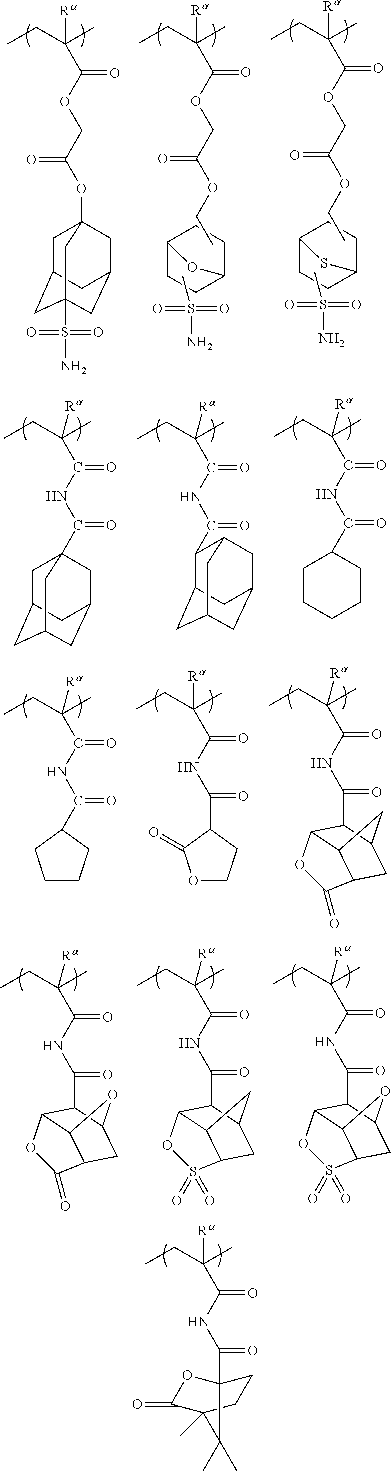

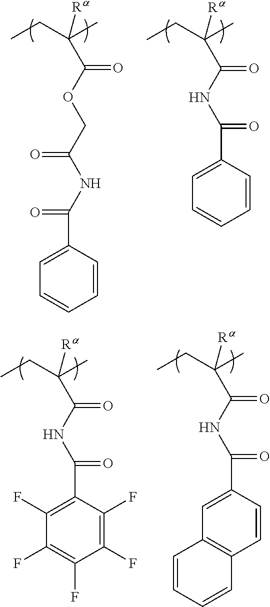

Further, as the structural unit (a9), a structural unit represented by general formula (a9-4) shown below may be included.

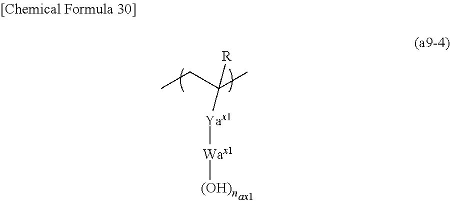

In the formula, R is the same as defined above; Ya^{x1} represents a single bond or a divalent linking group; Wa^{x1} represents an aromatic hydrocarbon group having a valency of (naₓ₁+1); and nₐₓ₁ represents an integer of 1 to 3.

In the formula (a9-4), the divalent linking group for Ya^{x1} is the same as defined for the divalent linking group represented by Ya⁰¹ and Ya⁰² in the aforementioned formula (a0-1). The aromatic hydrocarbon group for Wa^{x1} is the same as defined for the aromatic hydrocarbon group described above in the explanation of the divalent linking group represented by Ya⁰¹ and Ya⁰² in the aforementioned formula (a0-1).

Specific examples of the structural unit represented by general formula (a9-4) are shown below. In the formulae shown below, Ra represents a hydrogen atom, a methyl group or a trifluoromethyl group.

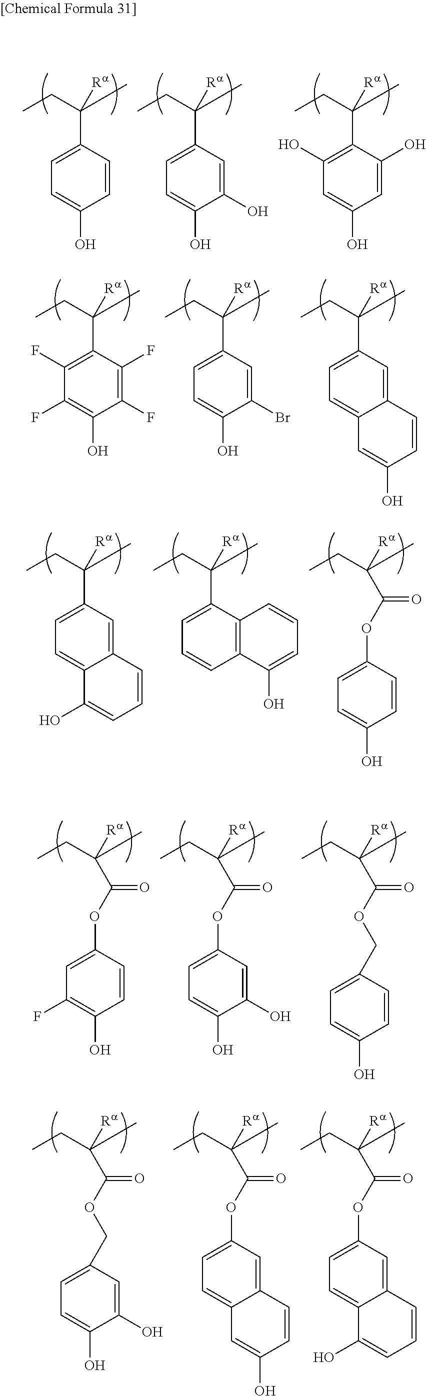

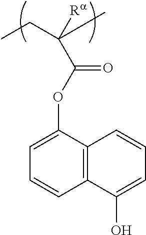

(Structural Unit (a3))

The component (A1) may contain a structural unit (a3). The structural unit (a3) is a structural unit containing a polar group-containing aliphatic hydrocarbon group (provided that the structural units that fall under the definition of structural units (a1), (a0), (a2) and (a9) are excluded).

When the component (A1) includes the structural unit (a3), it is presumed that the hydrophilicity of the component (A1) is enhanced, thereby contributing to improvement in resolution.

Examples of the polar group include a hydroxyl group, cyano group, carboxyl group, or hydroxyalkyl group in which part of the hydrogen atoms of the alkyl group have been substituted with fluorine atoms, although a hydroxyl group is particularly desirable.

Examples of the aliphatic hydrocarbon group include linear or branched hydrocarbon groups (preferably alkylene groups) of 1 to 10 carbon atoms, and cyclic aliphatic hydrocarbon groups (cyclic groups). These cyclic groups can be selected appropriately from the multitude of groups that have been proposed for the resins of resist compositions designed for use with ArF excimer lasers. The cyclic group is preferably a polycyclic group, more preferably a polycyclic group of 7 to 30 carbon atoms.

Of the various possibilities, structural units derived from an acrylate ester that include an aliphatic polycyclic group that contains a hydroxyl group, cyano group, carboxyl group or a hydroxyalkyl group in which part of the hydrogen atoms of the alkyl group have been substituted with fluorine atoms are particularly desirable. Examples of the polycyclic group include groups in which two or more hydrogen atoms have been removed from a bicycloalkane, tricycloalkane, tetracycloalkane or the like. Specific examples include groups in which two or more hydrogen atoms have been removed from a polycycloalkane such as adamantane, norbornane, isobornane, tricyclodecane or tetracyclododecane. Of these polycyclic groups, groups in which two or more hydrogen atoms have been removed from adamantane, norbornane or tetracyclododecane are preferred industrially.

As the structural unit (a3), there is no particular limitation as long as it is a structural unit containing a polar group-containing aliphatic hydrocarbon group, and an arbitrary structural unit may be used.

The structural unit (a3) is preferably a structural unit derived from an acrylate ester which may have the hydrogen atom bonded to the carbon atom on the α-position substituted with a substituent and contains a polar group-containing aliphatic hydrocarbon group.

When the aliphatic hydrocarbon group within the polar group-containing aliphatic hydrocarbon group is a linear or branched hydrocarbon group of 1 to 10 carbon atoms, the structural unit (a3) is preferably a structural unit derived from a hydroxyethyl ester of acrylic acid. On the other hand, when the hydrocarbon group is a polycyclic group, structural units represented by formulas (a3-1), (a3-2) and (a3-3) shown below are preferable.

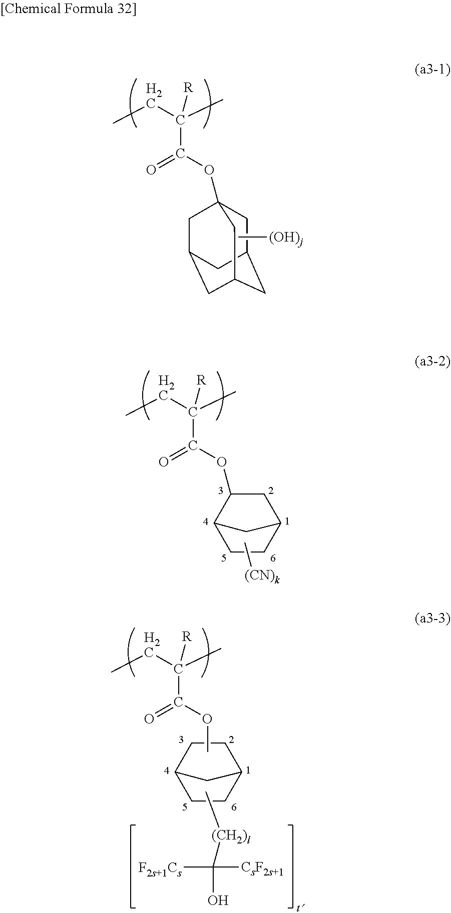

In the formulas, R is the same as defined above; j is an integer of 1 to 3; k is an integer of 1 to 3; t′ is an integer of 1 to 3;1 is an integer of 1 to 5; and s is an integer of 1 to 3.

In formula (a3-1), j is preferably 1 or 2, and more preferably 1. When j is 2, it is preferable that the hydroxyl groups be bonded to the 3rd and 5th positions of the adamantyl group. When j is 1, it is preferable that the hydroxyl group be bonded to the 3rd position of the adamantyl group.

j is preferably 1, and it is particularly desirable that the hydroxyl group be bonded to the 3rd position of the adamantyl group.

In formula (a3-2), k is preferably 1. The cyano group is preferably bonded to the 5th or 6th position of the norbornyl group.

In formula (a3-3), t′ is preferably 1. l is preferably 1. s is preferably 1. Further, it is preferable that a 2-norbornyl group or 3-norbornyl group be bonded to the terminal of the carboxy group of the acrylic acid. The fluorinated alkyl alcohol is preferably bonded to the 5th or 6th position of the norbornyl group.

As the structural unit (a3) contained in the component (A1), 1 type of structural unit may be used, or 2 or more types may be used.

In the component (A1), the amount of the structural unit (a3) based on the combined total of all structural units constituting the component (A1) is preferably 5 to 50 mol %, more preferably 5 to 40 mol %, and still more preferably 5 to 25 mol %.

When the amount of the structural unit (a3) is at least as large as the lower limit of the above-mentioned range, the effect of using the structural unit (a3) can be satisfactorily achieved. On the other hand, when the amount of the structural unit (a3) is no more than the upper limit of the above-mentioned range, a good balance can be achieved with the other structural units.

If desired, the component (A1) may further include a structural unit (a4) containing an acid non-dissociable cyclic group. When the component (A1) includes the structural unit (a4), dry etching resistance of the resist pattern to be formed is improved.

Further, the hydrophobicity of the component (A1) is further improved. Increase in the hydrophobicity contributes to improvement in terms of resolution, shape of the resist pattern and the like, particularly in an organic solvent developing process.

An “acid non-dissociable, aliphatic cyclic group” in the structural unit (a4) refers to a cyclic group which is not dissociated by the action of acid generated from the component (B) described later upon exposure, and remains in the structural unit.

As the structural unit (a4), a structural unit derived from an acrylate ester which contains an acid non-dissociable aliphatic polycyclic group is preferable. Examples of this polycyclic group include the same groups as those described above in relation to the aforementioned structural unit (a1), and any of the multitude of conventional polycyclic groups used within the resin component of resist compositions for ArF excimer lasers or KrF excimer lasers (and particularly for ArF excimer lasers) can be used.

In consideration of industrial availability and the like, at least one polycyclic group selected from amongst a tricyclodecyl group, adamantyl group, tetracyclododecyl group, isobornyl group, and norbornyl group is particularly desirable. These polycyclic groups may be substituted with a linear or branched alkyl group of 1 to 5 carbon atoms.

Further as the structural unit (a4), a structural unit derived from an acrylate ester containing an acid non-dissociable aromatic group, a structural unit derived from styrene and a structural unit derived from hydroxystyrene are also preferable.

Specific examples of the structural unit (a4) include structural units represented by general formulae (a4-1) to (a4-6) shown below, vinyl(hydroxy)naphthalene, (hydroxy)naphthyl(meth)acrylate and (hydroxy)benzyl(meth)acrylate.

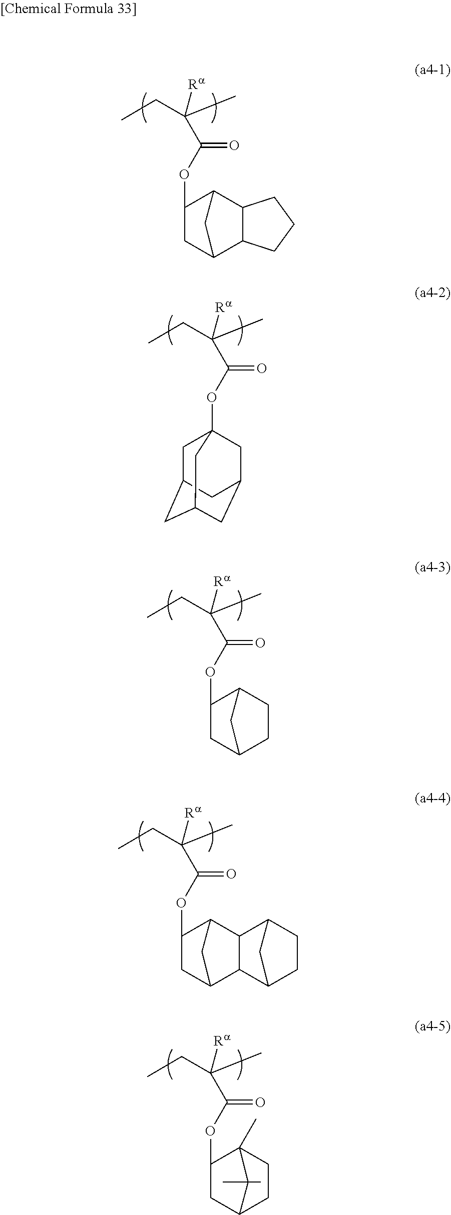

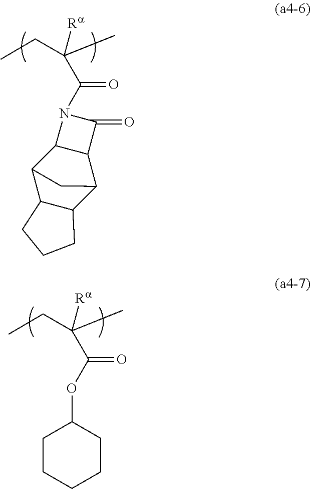

In the formulae, R^{α} represents a hydrogen atom, a methyl group or a trifluoromethyl group.

When the structural unit (a4) is included in the component (A1), the amount of the structural unit (a4) based on the combined total of all the structural units that constitute the component (A1) is preferably within the range from 1 to 30 mol %, and more preferably from 10 to 20 mol %.

The component (A1) is a copolymer including at least the structural units (a0) and (a2).

Examples of such copolymers include a copolymer consisting of the structural units (a0) and (a2); a copolymer consisting of the structural units (a0), (a2) and (a1); a copolymer consisting of the structural units (a0), (a2), (a1) and (a9); a copolymer consisting of the structural units (a0), (a2), (a1), (a9) and (a3); and a copolymer consisting of the structural units (a0), (a2), (a1), (a9), (a3) and (a4).

The component (A1) can be obtained, for example, by a conventional radical polymerization or the like of the monomers corresponding with each of the structural units, using a radical polymerization initiator such as azobisisobutyronitrile (AIBN) or dimethyl 2,2′-azobis(isobutyrate).

Furthermore, in the component (A1), by using a chain transfer agent such as HS—CH₂—CH₂—CH₂—C(CF₃)₂—OH, a —C(CF₃)₂—OH group can be introduced at the terminals of the component (A1). Such a copolymer having introduced a hydroxyalkyl group in which some of the hydrogen atoms of the alkyl group are substituted with fluorine atoms is effective in reducing developing defects and LER (line edge roughness: unevenness of the side walls of a line pattern).

The weight average molecular weight (Mw) (the polystyrene equivalent value determined by gel permeation chromatography) of the component (A1) is not particularly limited, but is preferably 1,000 to 50,000, more preferably 1,500 to 30,000, and most preferably 2,000 to 20,000. When the weight average molecular weight is no more than the upper limit of the above-mentioned range, the resist composition exhibits a satisfactory solubility in a resist solvent. On the other hand, when the weight average molecular weight is at least as large as the lower limit of the above-mentioned range, dry etching resistance and the cross-sectional shape of the resist pattern becomes satisfactory.

Further, the dispersity (Mw/Mn) is not particularly limited, but is preferably 1.0 to 5.0, more preferably 1.0 to 3.0, and most preferably 1.0 to 2.5. Here, Mn is the number average molecular weight.

As the component (A1), one type may be used alone, or two or more types may be used in combination.

In the component (A), the amount of the component (A1) based on the total weight of the component (A) is preferably 25% by weight or more, more preferably 50% by weight or more, still more preferably 75% by weight or more, and may be even 100% by weight. When the amount of the component (A1) is 25% by weight or more, various lithography properties are improved, such as improvement in MEF and circularity, and reduction of roughness.

Further, the amount of the resin component (A1) based on the total solid content is preferably 90% by weight or more, more preferably 95 to 99.9% by weight, and still more preferably 97 to 99.5% by weight. By virtue of the above mentioned range, it is considered that the Tf temperature of the resist composition becomes lower than 170 degrees, thereby resulting in excellent lithography properties.

The base component (A) may contain “a base component which exhibits increased polarity under action of acid” other than the resin component (A1) (hereafter, referred to as “component (A2)”), as long as the effects of the present invention are not impaired.

The component (A2) is not particularly limited, and any of the multitude of conventional base components used within chemically amplified resist compositions (e.g., base resins used within chemically amplified resist compositions for ArF excimer lasers or KrF excimer lasers, preferably ArF excimer lasers) can be used. For example, as a base resin for ArF excimer laser, a base resin having the aforementioned structural unit (a1) as an essential component, and optionally at least one structural unit selected from the aforementioned structural units (a0), (a2), (a3), (a4) and (a9) can be used.

As the component (A2), one type of resin may be used, or two or more types of resins may be used in combination.

In the resist composition of the present invention, as the component (A), one type may be used, or two or more types of compounds may be used in combination.

In the resist composition of the present invention, the amount of the component (A) can be appropriately adjusted depending on the thickness of the resist film to be formed, and the like.

In the resist composition of the present invention, the amount of the base component (A) can be appropriately adjusted depending on the thickness of the resist film to be formed, and the like.

<Acid Generator Component; Component (B)>

The component (B) is an acid generator component which generates acid upon exposure.

As the component (B), there is no particular limitation, and any of the known acid generators used in conventional chemically amplified resist compositions can be used. Examples of these acid generators are numerous, and include onium salt acid generators such as iodonium salts and sulfonium salts; oxime sulfonate acid generators; diazomethane acid generators such as bisalkyl or bisaryl sulfonyl diazomethanes and poly(bis-sulfonyl)diazomethanes; nitrobenzylsulfonate acid generators; iminosulfonate acid generators; and disulfone acid generators.

As an onium salt acid generator, a compound represented by general formula (b-1) or (b-2) shown below can be used.

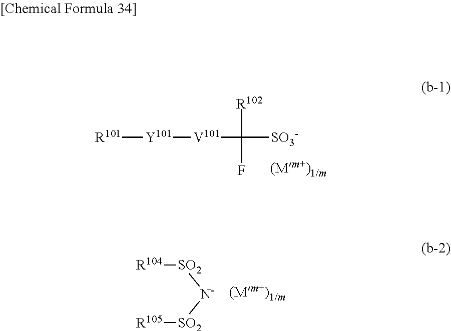

In the formulae, R¹⁰¹ represents a cyclic group which may have a substituent, a chain-like alkyl group which may have a substituent, or a chain-like alkenyl group which may have a substituent; Y¹⁰¹ represents a single bond or a divalent linking group containing an oxygen atom; V¹⁰¹ represents a single bond, an alkylene group or a fluorinated alkylene group; R¹⁰² represents a fluorine atom or a fluorinated alkyl group of 1 to 5 carbon atoms; R¹⁰⁴ and R¹⁰⁵ each independently represents an alkyl group of 1 to 10 carbon atoms or a fluorinated alkyl group of 1 to 10 carbon atoms, and may be mutually bonded to form a ring; and M′^{m+} represents an organic cation having a valency of m.

{Anion Moiety}

In the formula (b-1), R¹⁰¹ represents a cyclic group which may have a substituent, a chain-like alkyl group which may have a substituent or a chain-like alkenyl group which may have a substituent. The cyclic group is preferably a cyclic hydrocarbon group. The cyclic hydrocarbon group may be an aromatic hydrocarbon group or an aliphatic hydrocarbon group.

Examples of the aromatic hydrocarbon group for R¹⁰¹ include the aromatic hydrocarbon rings described above for the divalent aromatic hydrocarbon group, and an aryl group in which one hydrogen atom has been removed from an aromatic compound having two or more aromatic rings, and a phenyl group or a naphthyl group is preferable.

Examples of the cyclic aliphatic hydrocarbon group for R¹⁰¹ include groups in which one hydrogen atom has been removed from a monocycloalkane or a polycycloalkane described above for the divalent aliphatic hydrocarbon group, and an adamantyl group or a norbornyl group is preferable.

Further, the cyclic hydrocarbon group for R¹⁰¹ may contain a hetero atom like as a heterocycle, and specific examples thereof include lactone-containing cyclic groups represented by the aforementioned general formulas (a2-r-1) to (a2-r-7), —SO₂— containing cyclic groups represented by the aforementioned formulas (a5-r-1) to (a5-r-4) and heterocycles shown below.

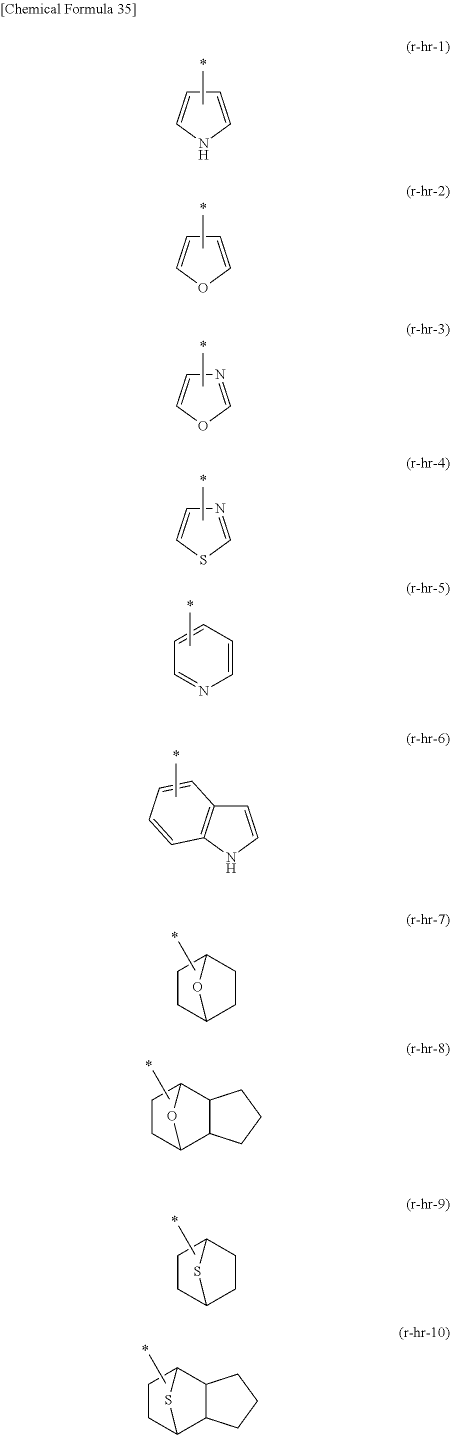

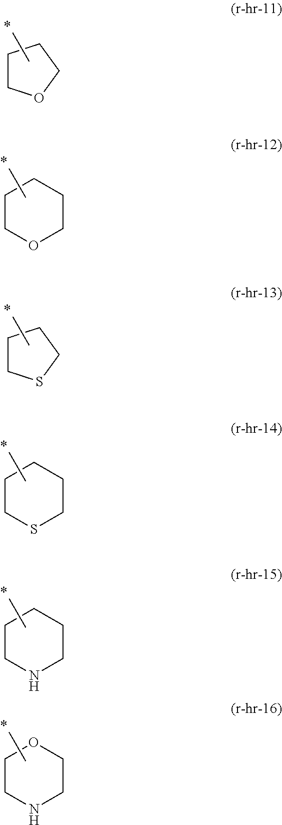

As the substituent for the cyclic hydrocarbon group for R¹⁰¹, an alkyl group, an alkoxy group, a halogen atom, a halogenated alkyl group, a hydroxyl group, an oxygen atom (═O), a nitro group or the like can be used.

The alkyl group as the substituent is preferably an alkyl group of 1 to 5 carbon atoms, and a methyl group, an ethyl group, a propyl group, an n-butyl group or a tert-butyl group is particularly desirable.

The alkoxy group as the substituent is preferably an alkoxy group having 1 to 5 carbon atoms, more preferably a methoxy group, ethoxy group, n-propoxy group, iso-propoxy group, n-butoxy group or tert-butoxy group, and most preferably a methoxy group or an ethoxy group.

Examples of the halogen atom for the substituent include a fluorine atom, a chlorine atom, a bromine atom and an iodine atom, and a fluorine atom is preferable.

Example of the halogenated alkyl group as the substituent for the aforementioned aromatic hydrocarbon group include groups in which part or all of the hydrogen atoms within an alkyl group of 1 to 5 carbon atoms (e.g., a methyl group, an ethyl group, a propyl group, an n-butyl group or a tert-butyl group) have been substituted with the aforementioned halogen atoms.

The chain-like alkyl group for R¹⁰¹ may be linear or branched. The linear alkyl group preferably has 1 to 20 carbon atoms, more preferably 1 to 15, and most preferably 1 to 10. Specific examples include a methyl group, an ethyl group, a propyl group, a butyl group, a pentyl group, a hexyl group, a heptyl group, an octyl group, a nonyl group, a decyl group, an undecyl group, a dodecyl group, a tridecyl group, an isotridecyl group, a tetradecyl group, a pentadecyl group, a hexadecyl group, an isohexadecyl group, a heptadecyl group, an octadecyl group, a nonadecyl group, an icosyl group, a henicosyl group and a docosyl group.

The branched alkyl group preferably has 3 to 20 carbon atoms, more preferably 3 to 15, and most preferably 3 to 10. Specific examples include a 1-methylethyl group, a 1-methylpropyl group, a 2-methylpropyl group, a 1-methylbutyl group, a 2-methylbutyl group, a 3-methylbutyl group, a 1-ethylbutyl group, a 2-ethylbutyl group, a 1-methylpentyl group, a 2-methylpentyl group, a 3-methylpentyl group and a 4-methylpentyl group.

The chain-like alkenyl group for R¹⁰¹ preferably has 2 to 10 carbon atoms, more preferably 2 to 5, still more preferably 2 to 4, and most preferably 3. Examples thereof include a vinyl group, a propenyl group (an allyl group) and a butynyl group. Examples of branched monovalent unsaturated hydrocarbon groups include a 1-methylpropenyl group and a 2-methylpropenyl group.

Among the above-mentioned examples, as the unsaturated hydrocarbon group, a propenyl group is particularly desirable.

As the substituent for the chain-like alkyl group or alkenyl group for R¹⁰¹, an alkoxy group, a halogen atom, a halogenated alkyl group, a hydroxyl group, an oxygen atom (═O), a nitro group, an amino group, a cyclic group for R¹⁰¹ or the like can be used.

In the present invention, R¹⁰¹ is preferably a cyclic hydrocarbon group which may have a substituent, and a phenyl group, a naphthyl group, a group in which one or more hydrogen atoms have been removed from a polycycloalkane, lactone-containing cyclic groups represented by the formulas (a2-r-1) to (a2-r-7), —SO₂— containing cyclic groups represented by the formulas (a5-r-1) to (a5-r-4) or the like are preferable.

In the case where Y¹⁰¹ is a divalent linking group containing an oxygen atom, Y¹⁰¹ may contain an atom other than an oxygen atom. Examples of atoms other than an oxygen atom include a carbon atom, a hydrogen atom, a sulfur atom and a nitrogen atom.

Examples of divalent linking groups containing an oxygen atom include non-hydrocarbon, oxygen atom-containing linking groups such as an oxygen atom (an ether bond; —O—), an ester bond (—C(═O)—O—), an amido bond (—C(═O)—NH—), a carbonyl group (—C(═O)—) and a carbonate bond (—O—C(═O)—O—); and combinations of the aforementioned non-hydrocarbon, hetero atom-containing linking groups with an alkylene group. Furthermore, the combinations may have a sulfonyl group (—SO₂—) bonded thereto. As the combination, the linking group represented by formulas (y-a1-1) to (y-a1-7) shown below can be mentioned.

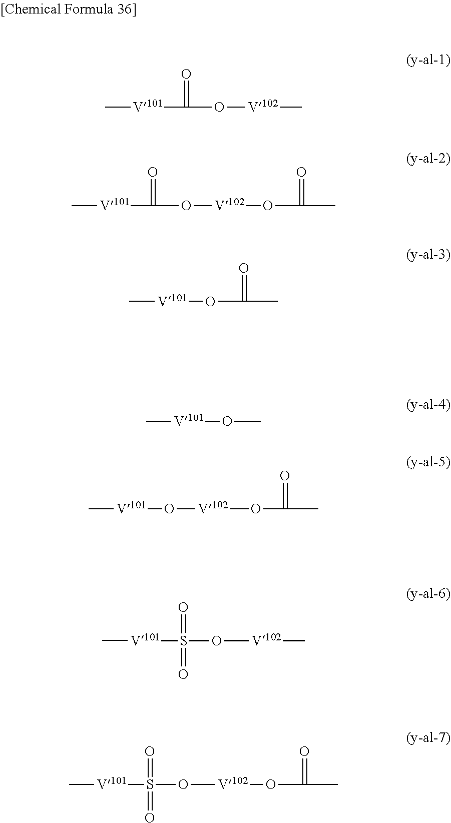

In the formulae, V′¹⁰¹ represents a single bond or an alkylene group of 1 to 5 carbon atoms; V′¹⁰² represents a divalent saturated hydrocarbon group of 1 to 30 carbon atoms.

The divalent saturated hydrocarbon group for V′¹⁰² is preferably an alkylene group of 1 to 30 carbon atoms.

Specific examples of the alkylene group for V′¹⁰¹ and V′¹⁰² include a methylene group [—CH₂—]; alkylmethylene groups such as —CH(CH₃)—, —CH(CH₂CH₃)—, —C(CH₃)₂—, —C(CH₃)(CH₂CH₃)—, —C(CH₃)(CH₂CH₂CH₃)— and —C(CH₂CH₃)₂—; an ethylene group [—CH₂CH₂—]; alkylethylene groups such as —CH(CH₃)CH₂—, —CH(CH₃)CH(CH₃)—, —C(CH₃)₂CH₂— and —CH(CH₂CH₃)CH₂—; a trimethylene group (n-propylene group) [—CH₂CH₂CH₂—]; alkyltrimethylene groups such as —CH(CH₃)CH₂CH₂— and —CH₂CH(CH₃)CH₂—; a tetramethylene group [—CH₂CH₂CH₂CH₂—]; alkyltetramethylene groups such as —CH(CH₃)CH₂CH₂CH₂— and —CH₂CH(CH₃)CH₂CH₂—; and a pentamethylene group [—CH₂CH₂CH₂CH₂CH₂—]. Among these, a linear alkylene group is preferable.

Further, part of methylene group within the alkylene group for V′¹⁰¹ and V′¹⁰² may be substituted with a divalent aliphatic cyclic group of 5 to 10 carbon atoms. The aliphatic cyclic group is preferably a divalent group in which one hydrogen atom has been removed from the cyclic alkyl group for Ra′³, and a cyclohexylene group, 1,5-adamantylene group or 2,6-adamantylene group is preferable.

Y¹⁰¹ is preferably a divalent linking group containing an ether bond or an ester bond, and groups represented by the aforementioned formulas (y-a1-1) to (y-a1-5) are preferable.

In the formula (b-1), V¹⁰¹ is preferably a single bond or a fluorinated alkylene group of 1 to 4 carbon atoms.

In the formula (b-1), R¹⁰² is preferably a fluorine atom or a perfluoroalkyl group of 1 to 5 carbon atoms, and is more preferably a fluorine atom.

As specific examples of anion moieties of the formula (b-1),

fluorinated alkylsulfonate anions such as a trifluoromethanesulfonate anion or a perfluorobutanesulfonate anion when Y¹⁰¹ is a single bond, and

anions represented by formula (an-1) to (an-3) shown below when Y¹⁰¹ is a divalent linking group containing an oxygen atom can be mentioned.

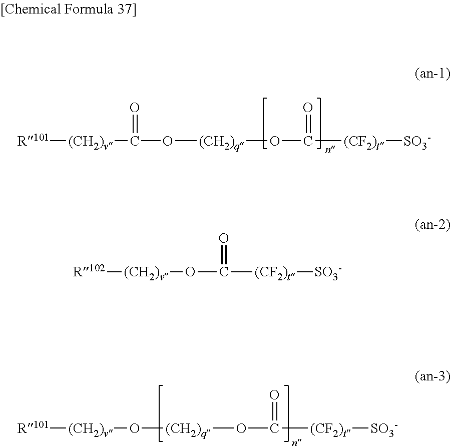

In the formulae, R″¹⁰¹ represents an aliphatic cyclic group which may have a substituent, a group represented by any one of the aforementioned formulas (r-hr-1) to (r-hr-6) or a chain-like alkyl group which may have a substituent; R″¹⁰² represents an aliphatic cyclic group which may have a substituent, a lactone-containing cyclic group represented by any one of the aforementioned formulas (a2-r-1) to (a2-r-7) or an —SO₂— containing cyclic group represented by any one of the aforementioned formulas (a5-r-1) to (a5-r-4); R″¹⁰³ represents an aromatic cyclic group which may have a substituent or a chain-like alkenyl group which may have a substituent; v″ represents an integer of 0 to 3; q″ represents an integer of 1 to 20; t″ represents an integer of 1 to 3; and n″ represents 0 or 1.

As the aliphatic cyclic group for R″¹⁰¹, R″¹⁰² and R″¹⁰³ which may have a substituent, the same groups as the cyclic aliphatic hydrocarbon group for R¹⁰¹ described above are preferable. As the substituent, the same groups as those described above for substituting the cyclic aliphatic hydrocarbon group for R¹⁰¹ can be mentioned.

As the aromatic cyclic group for R″¹⁰³ which may have a substituent, the same groups as the cyclic aromatic hydrocarbon group for R¹⁰¹ described above are preferable. As the substituent, the same groups as those described above for substituting the cyclic aromatic hydrocarbon group for R¹⁰¹ can be mentioned.

As the chain-like alkyl group for R″¹⁰¹ which may have a substituent, the same groups as those described above for R¹⁰¹ are preferable. As the chain-like alkenyl group for R″¹⁰³ which may have a substituent, the same groups as those described above for R¹⁰¹ are preferable.

In the formula (b-2), R¹⁰⁴ and R¹⁰⁵ each independently represents an alkyl group of 1 to 10 carbon atoms or a fluorinated alkyl group of 1 to 10 carbon atoms, and may be mutually bonded to form a ring.

Each of R¹⁰⁴ and R¹⁰⁵ is preferably a linear or branched (fluorinated) alkyl group. The (fluorinated) alkyl group preferably has 1 to 10 carbon atoms, preferably 1 to 7, and more preferably 1 to 3. The smaller the number of carbon atoms of the (fluorinated) alkyl group for R¹⁰⁴ and R¹⁰⁵, the more the solubility in a resist solvent is improved.

Further, in the (fluorinated) alkyl group for R¹⁰⁴ and R¹⁰⁵, it is preferable that the number of hydrogen atoms substituted with fluorine atoms is as large as possible because the acid strength increases and the transparency to high energy radiation of 200 nm or less or electron beam is improved.

The fluorination ratio of the (fluorinated) alkyl group is preferably from 70 to 100%, more preferably from 90 to 100%, and it is particularly desirable that the alkylene group or alkyl group be a perfluoroalkylene group or perfluoroalkyl group in which all hydrogen atoms are substituted with fluorine atoms.

{Cation Moiety}

In formulae (b-1) and (b-2), M′^{m+} represents an organic cation having a valency of m, preferably a sulfonium cation or a iodonium cation, and most preferably a cation represented by any one of general formulae (ca-1) to (ca-4) shown below.

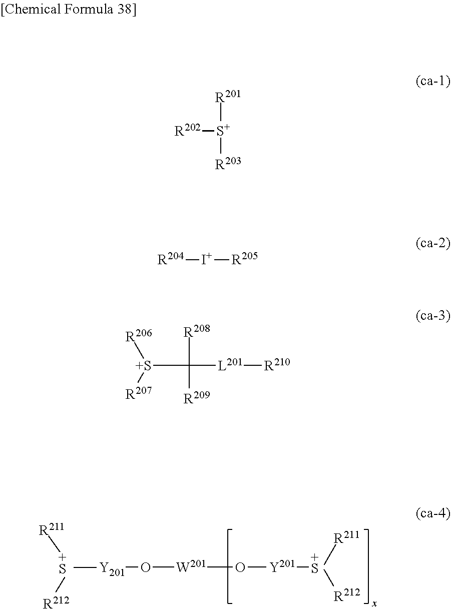

In the formulae, R²⁰¹ to R²⁰⁷ R²¹¹ and R²¹² independently represents an aryl group, an alkyl group or an alkenyl group, provided that two of R²⁰¹ to R²⁰³, R²⁰⁶ and R²⁰⁷, or R²¹¹ and R₂₁₂ may be mutually bonded to form a ring with the sulfur atom;

R²⁰⁸ and R²⁰⁹ each independently represents a hydrogen atom or an alkyl group of 1 to 5 carbon atoms; R²¹⁰ represents an aryl group which may have a substituent, an alkyl group which may have a substituent, an alkenyl group which may have a substituent or an —SO₂— containing cyclic group which may have a substituent; L²⁰¹ represents —C(═O)— or —C(═O)O—; Y²⁰¹ each independently represents an arylene group, an alkylene group or an alkenylene group; x represents 1 or 2; and W²⁰¹ represents a linking group having a valency of (x+1).

As the aryl group for R²⁰¹ to R²⁰⁷ and R²¹⁰ to R²¹² an unsubstituted aryl group of 6 to 20 carbon atoms can be mentioned, and a phenyl group or a naphthyl group is preferable.

As the alkyl group for R²⁰¹ to R²⁰⁷ and R²¹⁰ to R²¹², a chain-like or cyclic alkyl group having 1 to 30 carbon atoms is preferable.

The alkenyl group for R²⁰¹ to R²⁰⁷ and R²¹⁰ to R²¹² preferably has 2 to 10 carbon atoms.

R²⁰⁸ and R²⁰⁹ is preferably a hydrogen atom or an alkyl group of 1 to 3 carbon atoms, and when R²⁰⁸ and R²⁰⁹ each represents an alkyl group, R²⁰⁸ and R²⁰⁹ may be mutually bonded to form a ring.

As the —SO₂— containing cyclic group for R²¹⁰ which may have a substituent, the same “—SO₂— containing cyclic groups” as those described above for Ra²¹ can be mentioned, and the group represented by the aforementioned general formula (a5-r-1) is preferable.

Examples of the substituent for R²⁰¹ to R²⁰⁷ and R²¹⁰ to R²¹² include an alkyl group, a halogen atom, a halogenated alkyl group, an oxo group (═O), a cyano group, an amino group, an aryl group and groups represented by general formulae (ca-r-1) to (ca-r-7) shown below.

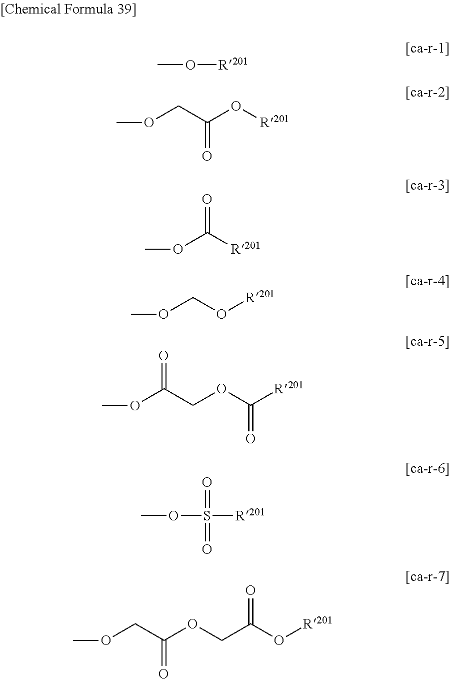

In the formulae, R′²⁰¹ each independently represents a hydrogen atom, a cyclic group which may have a substituent, a chain-like alkyl group which may have a substituent or a chain-like alkenyl group which may have a substituent.

As the cyclic group which may have a substituent, the chain-like alkyl group which may have a substituent and the chain-like alkenyl group which may have a substituent for R′²⁰¹, the same groups as those described above for R¹⁰¹ can be mentioned. As the cyclic group which may have a substituent and chain-like alkyl group which may have a substituent, the same groups as those described above for the group represented by the aforementioned formula (a1-r-2) can be also mentioned.

When R²⁰¹ to R²⁰³, R²⁰⁶, R²⁰⁷, R²¹¹ and R²¹² are mutually bonded to form a ring with the sulfur atom, these groups may be mutually bonded via a hetero atom such as a sulfur atom, an oxygen atom or a nitrogen atom, or a functional group such as a carbonyl group, —SO—, —SO₂—, —SO₃—, —COO—, —CONH— or —N(R_{N})— (wherein R_{N} represents an alkyl group of 1 to 5 carbon atoms).

The ring containing the sulfur atom in the skeleton thereof is preferably a 3 to 10-membered ring, and most preferably a 5 to 7-membered ring. Specific examples of the ring formed include a thiophene ring, a thiazole ring, a benzothiophene ring, a thianthrene ring, a benzothiophene ring, a dibenzothiophene ring, a 9H-thioxanthene ring, a thioxanthone ring, a phenoxathiin ring, a tetrahydrothiophenium ring, and a tetrahydrothiopyranium ring.

In the formula (ca-4), x represents 1 or 2.

W²⁰¹ represents a linking group having a valency of (x+1), i.e., a divalent or trivalent linking group.

As the divalent linking group for W²⁰¹, a divalent hydrocarbon group which may have a substituent is preferable, and as examples thereof, the same hydrocarbon groups as those described above for Ya²¹ in the general formula (a2) can be mentioned. The divalent linking group for W²⁰¹ may be linear, branched or cyclic, and cyclic is more preferable. Among these, an arylene group having two carbonyl groups, each bonded to the terminal thereof is preferable. Examples of the arylene group include a phenylene group and a naphthylene group, and a phenylene group is particularly desirable.

As the trivalent linking group for W²⁰¹, a group in which one hydrogen atom has been removed from the aforementioned divalent linking group and a group in which the divalent linking group has been bonded to another divalent linking group can be mentioned. The trivalent linking group for W²⁰¹ is preferably an arylene group combined with three carbonyl groups.

Specific examples of preferable cations represented by formula (ca-1) include cations represented by formulas (ca-1-1) to (ca-1-58) shown below.

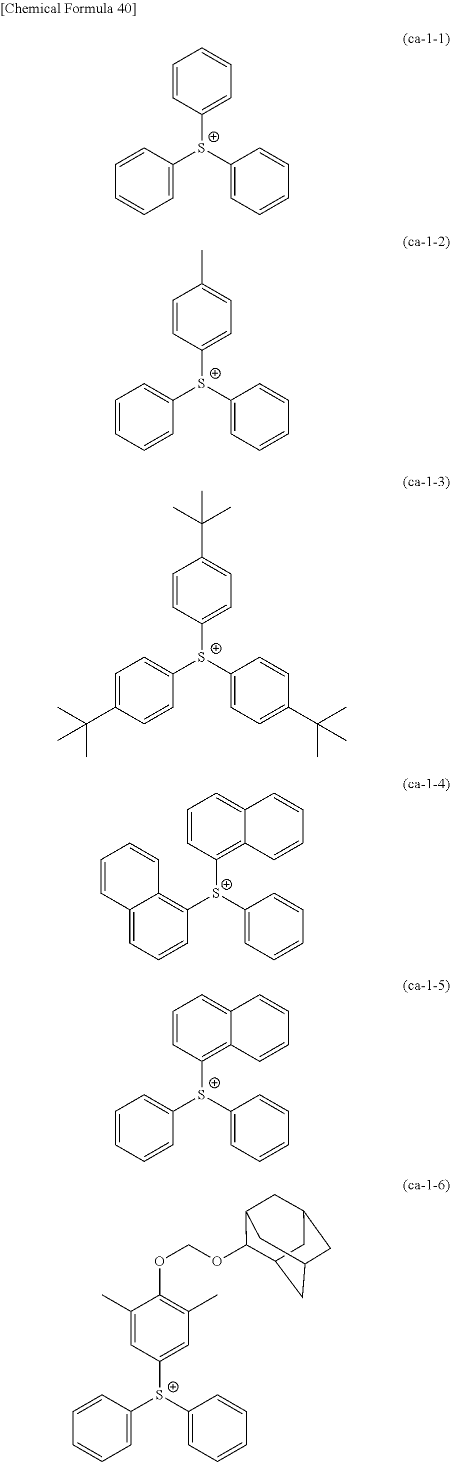

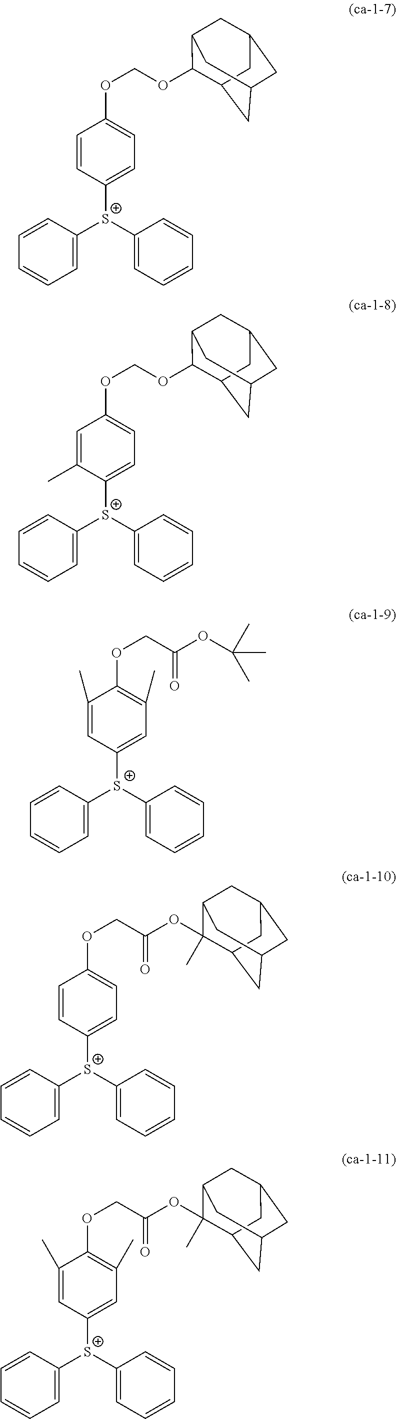

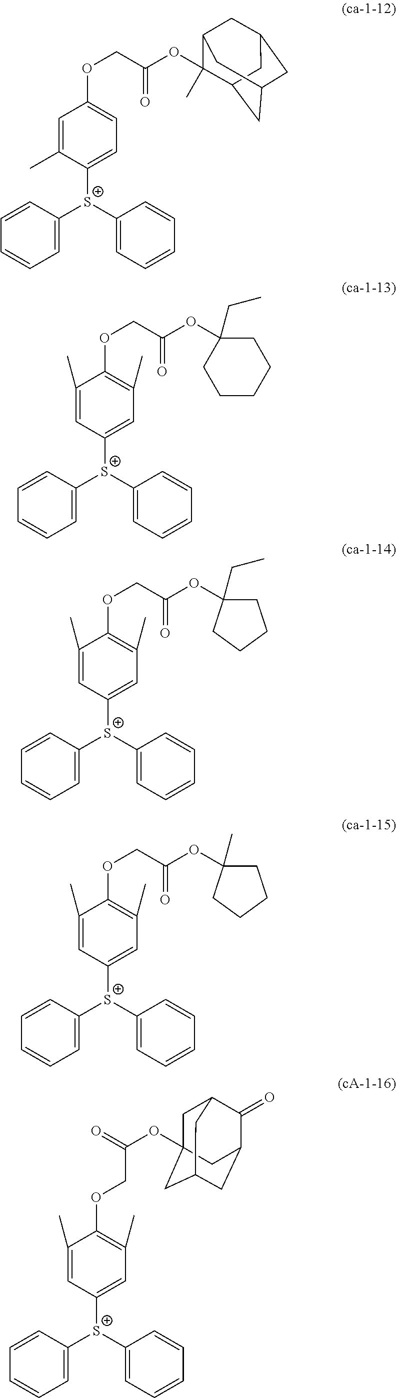

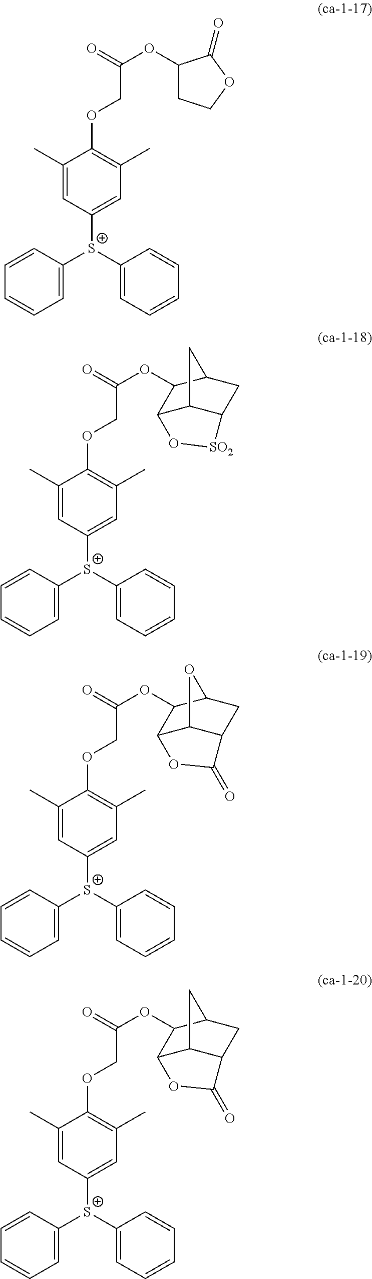

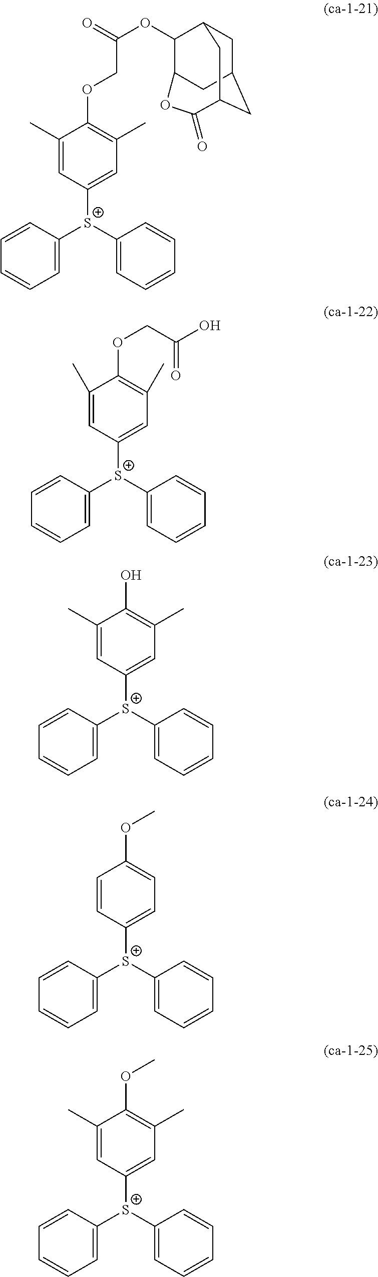

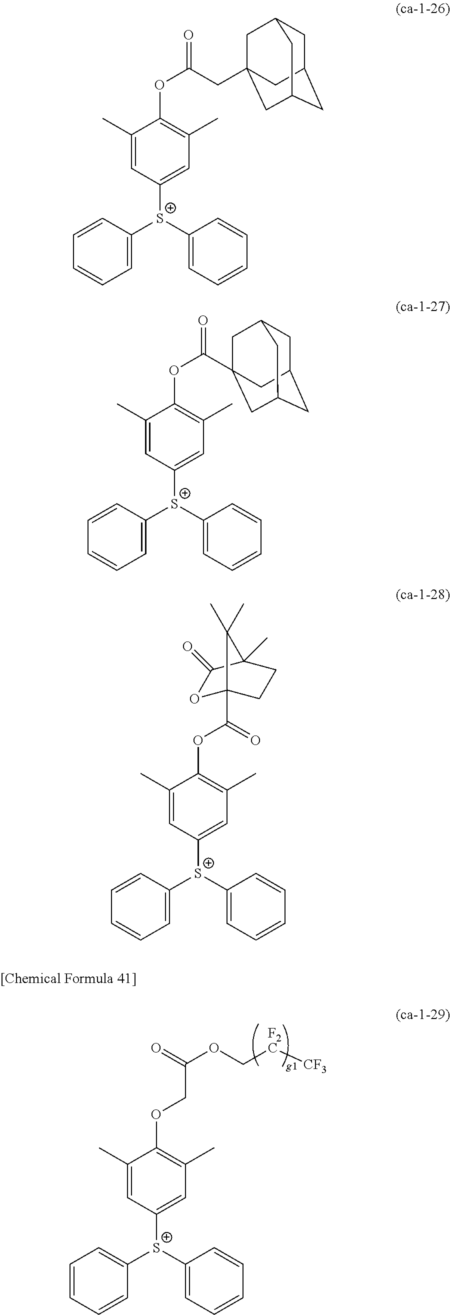

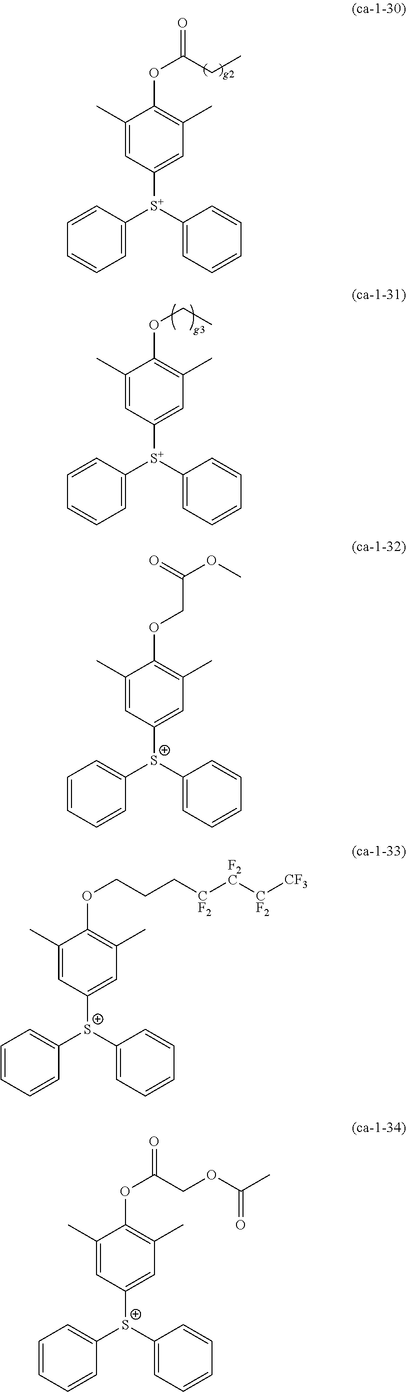

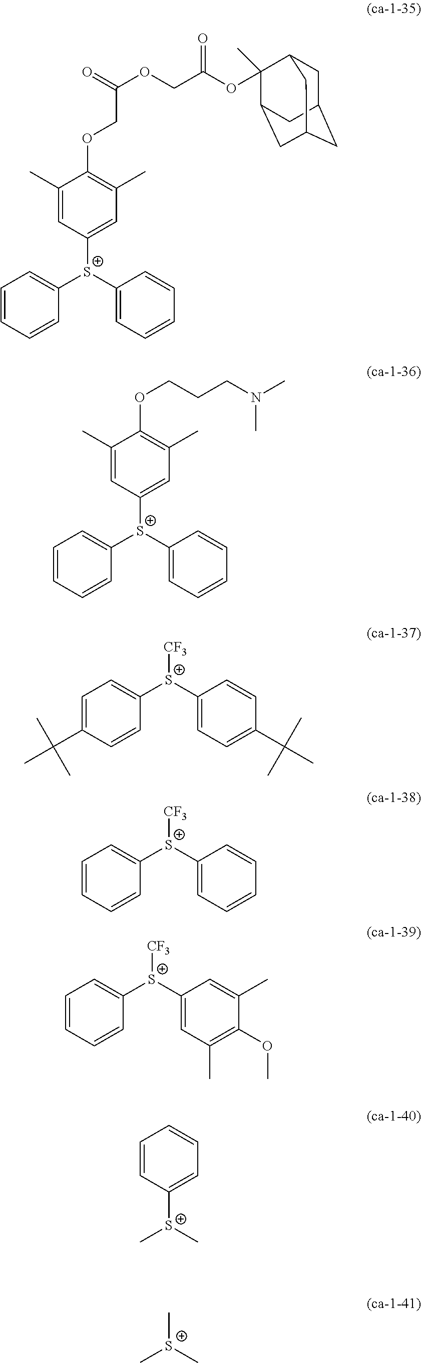

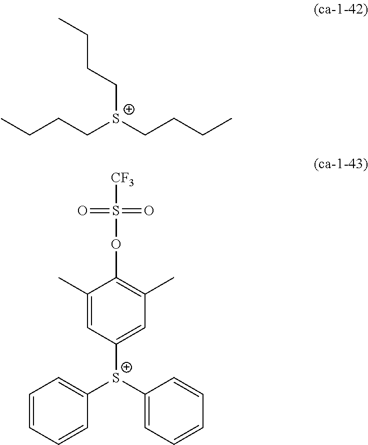

In the formulae, g1, g2 and g3 represent recurring numbers, wherein g1 is an integer of 1 to 5, g2 is an integer of 0 to 20, and g3 is an integer of 0 to 20.

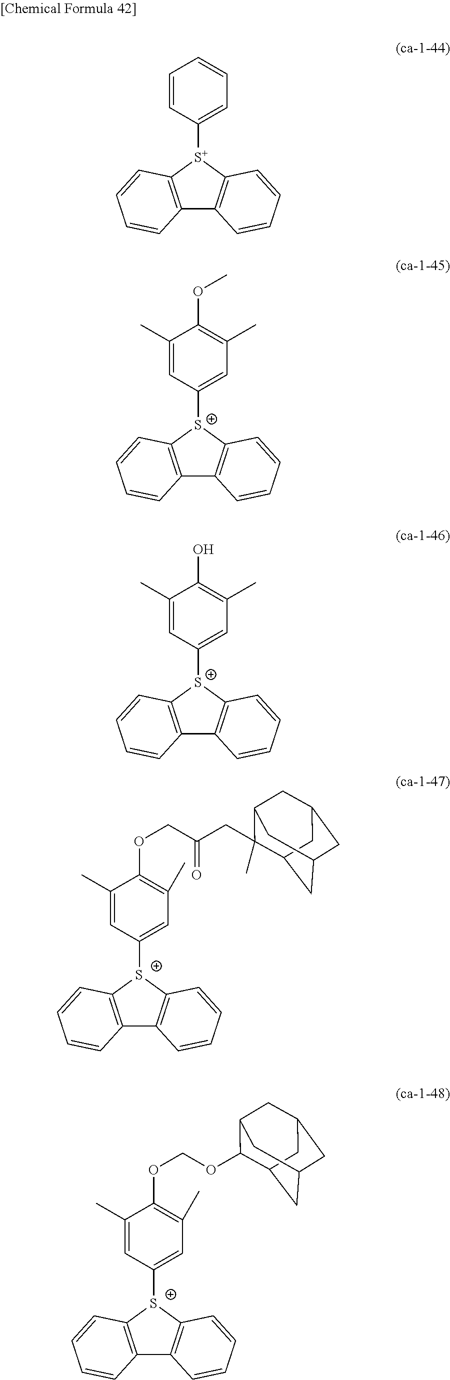

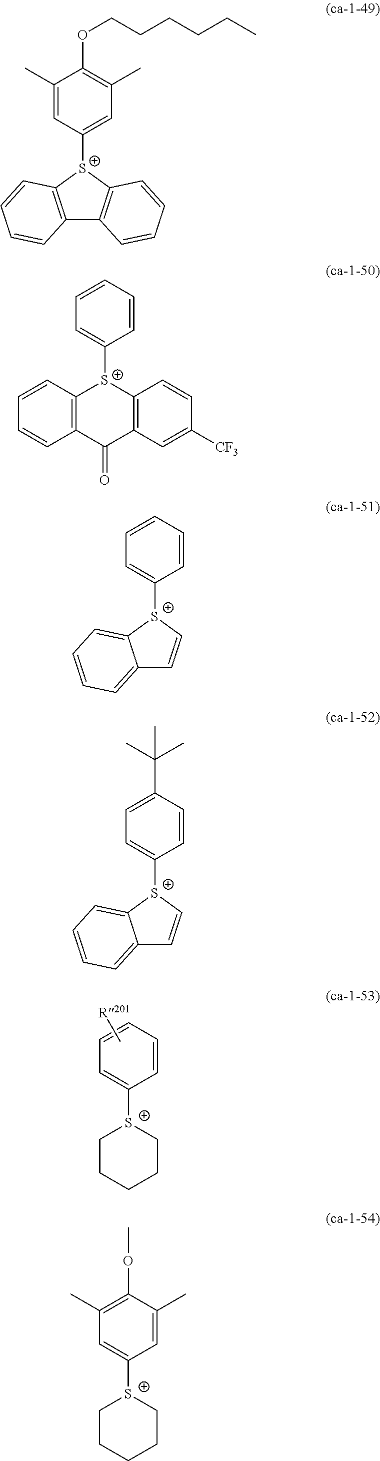

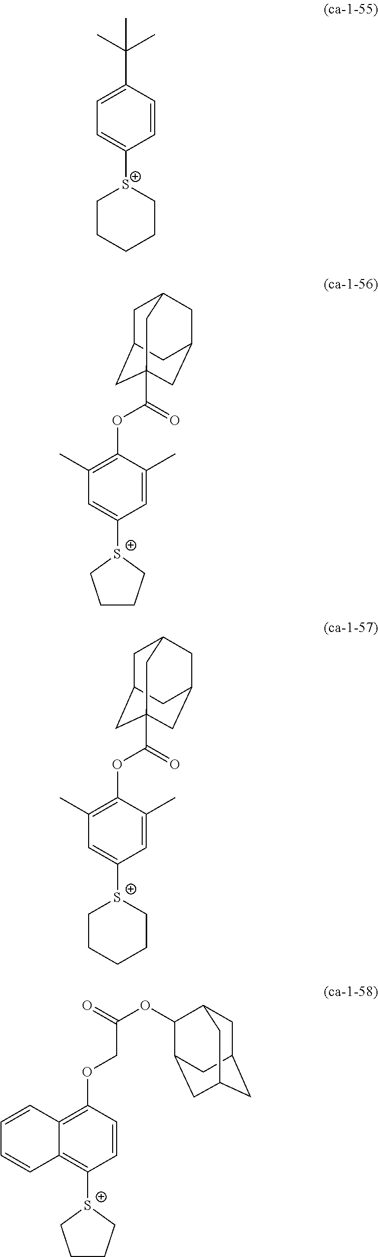

In the formulae, R″²⁰¹ represents a hydrogen atom or a substituent, and as the substituent, the same groups as those described above for substituting R²⁰¹ to R²⁰⁷ and R²¹⁰ to R²¹² can be mentioned.

Specific examples of preferable cations represented by formula (ca-3) include cations represented by formulas (ca-3-1) to (ca-3-6) shown below.

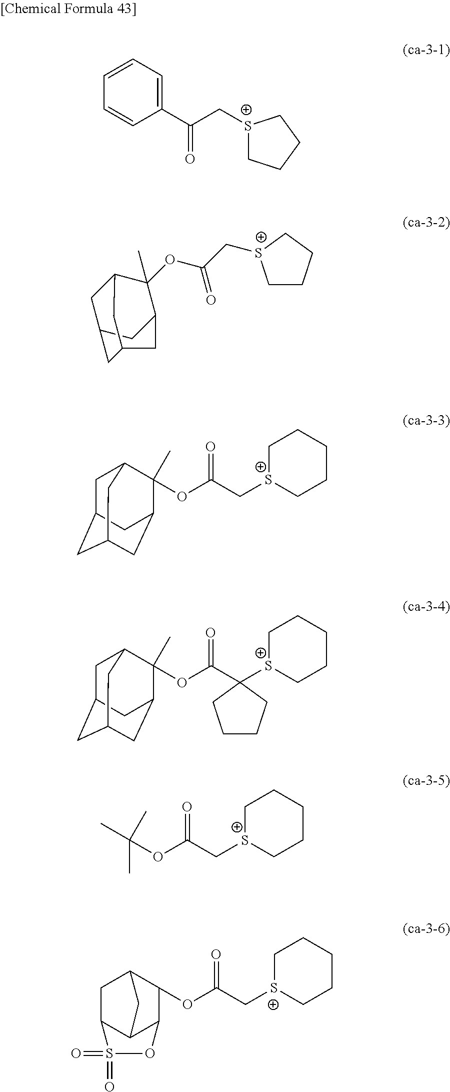 [SMILES: O=C(C[S+]1CCCC1)c1ccccc1 ; CC1(OC(=O)C[S+]2CCCC2)C2CC3CC(C2)CC1C3 ; CC1(OC(=O)C[S+]2CCCCC2)C2CC3CC(C2)CC1C3 ; CC1(OC(=O)C2([S+]3CCCCC3)CCCC2)C2CC3CC(C2)CC1C3 ; CC(C)(C)OC(=O)C[S+]1CCCCC1 ; O=C(C[S+]1CCCCC1)OC1C2CC3C1OS(=O)(=O)C3C2]

Specific examples of preferable cations represented by formula (ca-4) include cations represented by formulas (ca-4-1) and (ca-4-2) shown below.

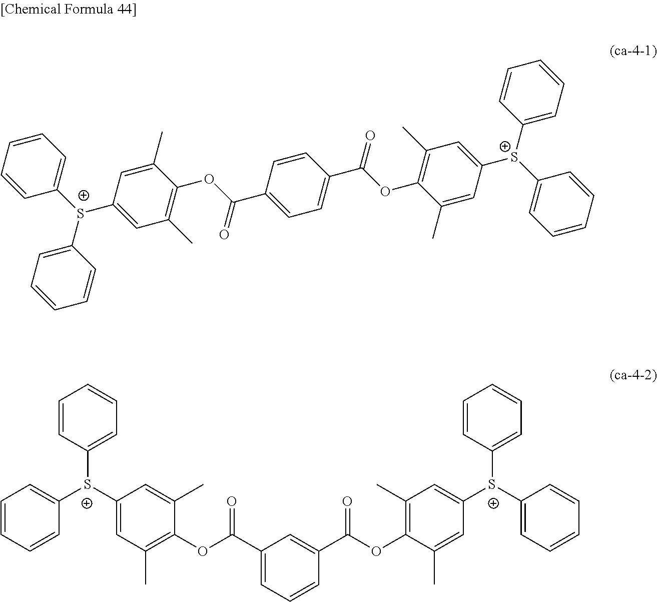 [SMILES: Cc1cc([S+](c2ccccc2)c2ccccc2)cc(C)c1OC(=O)c1ccc(C(=O)Oc2c(C)cc([S+](c3ccccc3)c3ccccc3)cc2C)cc1 ; Cc1cc([S+](c2ccccc2)c2ccccc2)cc(C)c1OC(=O)c1cccc(C(=O)Oc2c(C)cc([S+](c3ccccc3)c3ccccc3)cc2C)c1]

As the component (B), one type of these acid generators may be used alone, or two or more types may be used in combination.

When the resist composition of the present invention contains the component (B), the amount of the component (B) relative to 100 parts by weight of the component (A) is preferably within a range from 0.5 to 60 parts by weight, more preferably from 1 to 50 parts by weight, and still more preferably from 1 to 40 parts by weight. When the amount of the component (B) is within the above-mentioned range, formation of a resist pattern can be satisfactorily performed. Further, by virtue of the above-mentioned range, when each of the components are dissolved in an organic solvent, a uniform solution can be obtained and the storage stability becomes satisfactory.

<Basic Compound Component; Component (D)>

The component (D) is a basic compound component, and functions as an acid diffusion control agent, i.e., a quencher which traps the acid generated from the component (B) upon exposure. In the present invention, a “basic compound” refers to a compound which is basic relative to the component (B).

The component (D) is not particularly limited, as long as it is a compound which is basic relative to the component (B), so as to functions as an acid diffusion inhibitor. As the component (D), any of the conventionally known compounds may be selected for use. Among these, an aliphatic amine, particularly a secondary aliphatic amine or tertiary aliphatic amine is preferable.

An aliphatic amine is an amine having one or more aliphatic groups, and the aliphatic groups preferably have 1 to 12 carbon atoms.

Examples of these aliphatic amines include amines in which at least one hydrogen atom of ammonia (NH₃) has been substituted with an alkyl group or hydroxyalkyl group of no more than 12 carbon atoms (i.e., alkylamines or alkylalcoholamines), and cyclic amines.

Specific examples of alkylamines and alkylalcoholamines include monoalkylamines such as n-hexylamine, n-heptylamine, n-octylamine, n-nonylamine, and n-decylamine; dialkylamines such as diethylamine, di-n-propylamine, di-n-heptylamine, di-n-octylamine, and dicyclohexylamine; trialkylamines such as trimethylamine, triethylamine, tri-n-propylamine, tri-n-butylamine, tri-n-hexylamine, tri-n-pentylamine, tri-n-heptylamine, tri-n-octylamine, tri-n-nonylamine, tri-n-decylamine, and tri-n-dodecylamine; and alkyl alcohol amines such as diethanolamine, triethanolamine, diisopropanolamine, triisopropanolamine, di-n-octanolamine, and tri-n-octanolamine. Among these, trialkylamines of 5 to 10 carbon atoms are preferable, and tri-n-pentylamine and tri-n-octylamine are particularly desirable.

As the component (D), one type of compound may be used, or two or more types of compounds may be used in combination.

When the resist composition of the present invention contains the component (D), the amount of the component (D) relative to 100 parts by weight of the base component (A) is preferably within a range from 0.1 to 15 parts by weight, more preferably from 0.3 to 12 parts by weight, and still more preferably from 0.5 to 12 parts by weight. When the amount of the component (D) is at least as large as the lower limit of the above-mentioned range, various lithography properties (such as roughness) of the resist composition are improved. Further, a resist pattern having an excellent shape can be obtained. On the other hand, when the amount of the component (D) is no more than the upper limit of the above-mentioned range, sensitivity can be maintained at a satisfactory level, and through-put becomes excellent.

<Optional Components>

[Component (E)]

Furthermore, in the resist composition of the present invention, for preventing any deterioration in sensitivity, and improving the resist pattern shape and the post exposure stability of the latent image formed by the pattern-wise exposure of the resist layer, at least one compound (E) (hereafter referred to as the component (E)) selected from the group consisting of an organic carboxylic acid, or a phosphorus oxo acid or derivative thereof can be added.

Examples of suitable organic carboxylic acids include acetic acid, malonic acid, citric acid, malic acid, succinic acid, benzoic acid, and salicylic acid. Examples of phosphorus oxo acids include phosphoric acid, phosphonic acid and phosphinic acid. Among these, phosphonic acid is particularly desirable.

Examples of oxo acid derivatives include esters in which a hydrogen atom within the above-mentioned oxo acids is substituted with a hydrocarbon group. Examples of the hydrocarbon group include an alkyl group of 1 to 5 carbon atoms and an aryl group of 6 to 15 carbon atoms.

Examples of phosphoric acid derivatives include phosphoric acid esters such as di-n-butyl phosphate and diphenyl phosphate.

Examples of phosphonic acid derivatives include phosphonic acid esters such as dimethyl phosphonate, di-n-butyl phosphonate, phenyl phosphonate, diphenyl phosphonate and dibenzyl phosphonate.

Examples of phosphinic acid derivatives include phosphinic acid esters and phenylphosphinic acid.

As the component (E), one type may be used alone, or two or more types may be used in combination.

The component (E) is typically used in an amount within a range from 0.01 to 5.0 parts by weight, relative to 100 parts by weight of the component (A).

[Component (S)]

The resist composition for immersion exposure according to the present invention can be prepared by dissolving the materials for the resist composition in an organic solvent (hereafter, frequently referred to as “component (S)”).

The component (S) may be any organic solvent which can dissolve the respective components to give a uniform solution, and one or more kinds of any organic solvent can be appropriately selected from those which have been conventionally known as solvents for a chemically amplified resist.

Examples thereof include lactones such as y-butyrolactone;

ketones such as acetone, methyl ethyl ketone, cyclohexanone, methyl-n-pentyl ketone, methyl isopentyl ketone, and 2-heptanone;

polyhydric alcohols, such as ethylene glycol, diethylene glycol, propylene glycol and dipropylene glycol;

compounds having an ester bond, such as ethylene glycol monoacetate, diethylene glycol monoacetate, propylene glycol monoacetate, and dipropylene glycol monoacetate; polyhydric alcohol derivatives including compounds having an ether bond, such as a monoalkylether (e.g., monomethylether, monoethylether, monopropylether or monobutylether) or monophenylether of any of these polyhydric alcohols or compounds having an ester bond (among these, propylene glycol monomethyl ether acetate (PGMEA) and propylene glycol monomethyl ether (PGME) are preferable); cyclic ethers such as dioxane; esters such as methyl lactate, ethyl lactate (EL), methyl acetate, ethyl acetate, butyl acetate, methyl pyruvate, ethyl pyruvate, methyl methoxypropionate, and ethyl ethoxypropionate;

and aromatic organic solvents such as anisole, ethylbenzylether, cresylmethylether, diphenylether, dibenzylether, phenetole, butylphenylether, ethylbenzene, diethylbenzene, pentylbenzene, isopropylbenzene, toluene, xylene, cymene and mesitylene.

These solvents can be used individually, or in combination as a mixed solvent.

Among these, propylene glycol monomethyl ether acetate (PGMEA), propylene glycol monomethyl ether (PGME) and ethyl lactate (EL) are preferable.

Further, among the mixed solvents, a mixed solvent obtained by mixing PGMEA with a polar solvent is preferable. The mixing ratio (weight ratio) of the mixed solvent can be appropriately determined, taking into consideration the compatibility of the PGMEA with the polar solvent, but is preferably in the range of 1:9 to 9:1, more preferably from 2:8 to 8:2. For example, when EL is mixed as the polar solvent, the PGMEA:EL weight ratio is preferably from 1:9 to 9:1, and more preferably from 2:8 to 8:2. Alternatively, when PGME is mixed as the polar solvent, the PGMEA:PGME weight ratio is preferably from 1:9 to 9:1, more preferably from 2:8 to 8:2, and still more preferably 3:7 to 7:3. Alternatively, when PGME and cyclohexanone is mixed as the polar solvent, the PGMEA:(PGME+cyclohexanone) weight ratio is preferably from 1:9 to 9:1, more preferably from 2:8 to 8:2, and still more preferably 3:7 to 7:3.

Further, as the component (S), a mixed solvent of γ-butyrolactone with PGMEA, EL or the aforementioned mixed solvent of PGMEA with a polar solvent, is also preferable. The mixing ratio (former:latter) of such a mixed solvent is preferably from 70:30 to 95:5.

The amount of the organic solvent is not particularly limited, and is appropriately adjusted to a concentration which enables coating of a coating solution to a substrate, depending on the thickness of the coating film. In general, the organic solvent is used in an amount such that the solid content of the resist composition becomes within the range from 1 to 20% by weight, preferably from 1.5 to 15% by weight, and more preferably from 1.8 to 5% by weight.

If desired, other miscible additives can also be added to the resist composition of the present invention. Examples of such miscible additives include additive resins for improving the performance of the resist film (such as a fluorine-containing resin), surfactants for improving the applicability, dissolution inhibitors, plasticizers, stabilizers, colorants, halation prevention agents, and dyes.

<<Method of Forming a Resist Pattern>>

The method of forming a resist pattern according to the present invention includes: forming a resist film on a substrate using a resist composition of the present invention; conducting exposure of the resist film; and developing the resist film to form a resist pattern.

The method for forming a resist pattern according to the present invention can be performed, for example, as follows.

Firstly, a resist composition of the present invention is applied to a substrate using a spinner or the like, and a bake treatment (post applied bake (PAB)) is conducted at a temperature of 80 to 150° C. for 40 to 120 seconds, preferably 60 to 90 seconds, to form a resist film.

Following selective exposure of the thus formed resist film, either by exposure through a mask having a predetermined pattern formed thereon (mask pattern) using an exposure apparatus such as an ArF exposure apparatus, an electron beam lithography apparatus or an EUV exposure apparatus, or by patterning via direct irradiation with an electron beam without using a mask pattern, baking treatment (post exposure baking (PEB)) is conducted under temperature conditions of 80 to 150° C. for 40 to 120 seconds, and preferably 60 to 90 seconds.

Next, the resist film is subjected to a developing treatment.

The developing treatment is conducted using an alkali developing solution in the case of an alkali developing process, and a developing solution containing an organic solvent (organic developing solution) in the case of a solvent developing process.

After the developing treatment, it is preferable to conduct a rinse treatment. The rinse treatment is preferably conducted using pure water in the case of an alkali developing process, and a rinse solution containing an organic solvent in the case of a solvent developing process.

In the case of a solvent developing process, after the developing treatment or the rinsing, the developing solution or the rinse liquid remaining on the pattern can be removed by a treatment using a supercritical fluid.

After the developing treatment or the rinse treatment, drying is conducted. If desired, bake treatment (post bake) can be conducted following the developing. In this manner, a resist pattern can be obtained.

The substrate is not specifically limited and a conventionally known substrate can be used. For example, substrates for electronic components, and such substrates having wiring patterns formed thereon can be used. Specific examples of the material of the substrate include metals such as silicon wafer, copper, chromium, iron and aluminum; and glass. Suitable materials for the wiring pattern include copper, aluminum, nickel, and gold.

Further, as the substrate, any one of the above-mentioned substrates provided with an inorganic and/or organic film on the surface thereof may be used. As the inorganic film, an inorganic antireflection film (inorganic BARC) can be used. As the organic film, an organic antireflection film (organic BARC) and an organic film such as a lower-layer organic film used in a multilayer resist method can be used.

Here, a “multilayer resist method” is method in which at least one layer of an organic film (lower-layer organic film) and at least one layer of a resist film (upper resist film) are provided on a substrate, and a resist pattern formed on the upper resist film is used as a mask to conduct patterning of the lower-layer organic film. This method is considered as being capable of forming a pattern with a high aspect ratio. More specifically, in the multilayer resist method, a desired thickness can be ensured by the lower-layer organic film, and as a result, the thickness of the resist film can be reduced, and an extremely fine pattern with a high aspect ratio can be formed.

The multilayer resist method is broadly classified into a method in which a double-layer structure consisting of an upper-layer resist film and a lower-layer organic film is formed (double-layer resist method), and a method in which a multilayer structure having at least three layers consisting of an upper-layer resist film, a lower-layer organic film and at least one intermediate layer (thin metal film or the like) provided between the upper-layer resist film and the lower-layer organic film (triple-layer resist method).

The wavelength to be used for exposure is not particularly limited and the exposure can be conducted using radiation such as ArF excimer laser, KrF excimer laser, F₂ excimer laser, extreme ultraviolet rays (EUV), vacuum ultraviolet rays (VUV), electron beam (EB), X-rays, and soft X-rays. The resist composition of the present invention is effective to KrF excimer laser, ArF excimer laser, EB and EUV.

The exposure of the resist film can be either a general exposure (dry exposure) conducted in air or an inert gas such as nitrogen, or immersion exposure (immersion lithography).

In immersion lithography, the region between the resist film and the lens at the lowermost point of the exposure apparatus is pre-filled with a solvent (immersion medium) that has a larger refractive index than the refractive index of air, and the exposure (immersion exposure) is conducted in this state.

The immersion medium preferably exhibits a refractive index larger than the refractive index of air but smaller than the refractive index of the resist film to be exposed. The refractive index of the immersion medium is not particularly limited as long at it satisfies the above-mentioned requirements.

Examples of this immersion medium which exhibits a refractive index that is larger than the refractive index of air but smaller than the refractive index of the resist film include water, fluorine-based inert liquids, silicon-based solvents and hydrocarbon-based solvents.

Specific examples of the fluorine-based inert liquids include liquids containing a fluorine-based compound such as C₃HCl₂F₅, C₄F₉OCH₃, C₄F₉OC₂H₅ or C₅H₃F₇ as the main component, which have a boiling point within a range from 70 to 180° C. and preferably from 80 to 160° C. A fluorine-based inert liquid having a boiling point within the above-mentioned range is advantageous in that the removal of the immersion medium after the exposure can be conducted by a simple method.

As a fluorine-based inert liquid, a perfluoroalkyl compound in which all of the hydrogen atoms of the alkyl group are substituted with fluorine atoms is particularly desirable. Examples of these perfluoroalkyl compounds include perfluoroalkylether compounds and perfluoroalkylamine compounds.

Specifically, one example of a suitable perfluoroalkylether compound is perfluoro(2-butyl-tetrahydrofuran) (boiling point 102° C.), and an example of a suitable perfluoroalkylamine compound is perfluorotributylamine (boiling point 174° C.).

As the immersion medium, water is preferable in terms of cost, safety, environment and versatility.

As an example of the alkali developing solution used in an alkali developing process, a 0.1 to 10% by weight aqueous solution of tetramethylammonium hydroxide (TMAH) can be given.

As the organic solvent contained in the organic developing solution used in a solvent developing process, any of the conventional organic solvents can be used which are capable of dissolving the component (A) (prior to exposure). Specific examples of the organic solvent include polar solvents such as ketone solvents, ester solvents, alcohol solvents, amide solvents and ether solvents, and hydrocarbon solvents.

If desired, the organic developing solution may have a conventional additive blended. Examples of the additive include surfactants. The surfactant is not particularly limited, and for example, an ionic or non-ionic fluorine and/or silicon surfactant can be used.

When a surfactant is added, the amount thereof based on the total amount of the organic developing solution is generally 0.001 to 5% by weight, preferably 0.005 to 2% by weight, and more preferably 0.01 to 0.5% by weight.

The developing treatment can be performed by a conventional developing method. Examples thereof include a method in which the substrate is immersed in the developing solution for a predetermined time (a dip method), a method in which the developing solution is cast up on the surface of the substrate by surface tension and maintained for a predetermined period (a puddle method), a method in which the developing solution is sprayed onto the surface of the substrate (spray method), and a method in which the developing solution is continuously ejected from a developing solution ejecting nozzle while scanning at a constant rate to apply the developing solution to the substrate while rotating the substrate at a constant rate (dynamic dispense method).

As the organic solvent contained in the rinse liquid used in the rinse treatment after the developing treatment in the case of a solvent developing process, any of the aforementioned organic solvents contained in the organic developing solution can be used which hardly dissolves the resist pattern. In general, at least one solvent selected from the group consisting of hydrocarbon solvents, ketone solvents, ester solvents, alcohol solvents, amide solvents and ether solvents is used. Among these, at least one solvent selected from the group consisting of hydrocarbon solvents, ketone solvents, ester solvents, alcohol solvents and amide solvents is preferable, more preferably at least one solvent selected from the group consisting of alcohol solvents and ester solvents, and an alcohol solvent is particularly desirable.

The rinse treatment using a rinse liquid (washing treatment) can be conducted by a conventional rinse method. Examples of the rinse method include a method in which the rinse liquid is continuously applied to the substrate while rotating it at a constant rate (rotational coating method), a method in which the substrate is immersed in the rinse liquid for a predetermined time (dip method), and a method in which the rinse liquid is sprayed onto the surface of the substrate (spray method).

In the resist composition of the present invention, by virtue of including structural units having a long chain (i.e., structural unit (a0) and structural unit (a2)), it is considered that the Tf temperature of the resin component can be lowered. As a result, low PEB conditions can be selected, and it is presumed that diffusion of acid can be controlled. Further, it is considered that, by virtue of the structural unit (a2) having a lactone-containing cyclic group, a carbonate-containing cyclic group or an —SO₂— containing cyclic group, the structural unit (a2) contributes to lowering the Tf temperature of the resin component (which results in lowering the Tf temperature of the resist composition).

In the resist composition of the present invention, by virtue of including a structural unit having a long chain (structural unit (a0)), it is considered that the terminal effect of each structural unit is improved. Specifically, in a structural unit having a polar group on the terminal thereof, by virtue of elonging the chain length, the adhesiveness with a substrate is improved, and prevention of collapse, improvement in resolution and improvement in solubility can be expected.

### EXAMPLES

The present invention will be described more specifically with reference to the following examples, although the scope of the present invention is by no way limited by these examples.

### POLYMER SYNTHESIS EXAMPLE

Polymeric compounds 1 to 33 were synthesized using the following monomers (1) to (22) which derived the structural units constituting each polymeric compound by a conventional method. With respect to the obtained compounds, the compositional ratio (the molar ratio of the respective structural units indicated in the structural formula shown below) as determined by carbon 13 nuclear magnetic resonance spectroscopy (600 MHz_{—}13C-NMR; internal standard: tetramethylsilane), and the weight average molecular weight (Mw) and the molecular weight dispersity (Mw/Mn) determined by the polystyrene equivalent value as measured by GPC are shown in Tables 1 to 4.

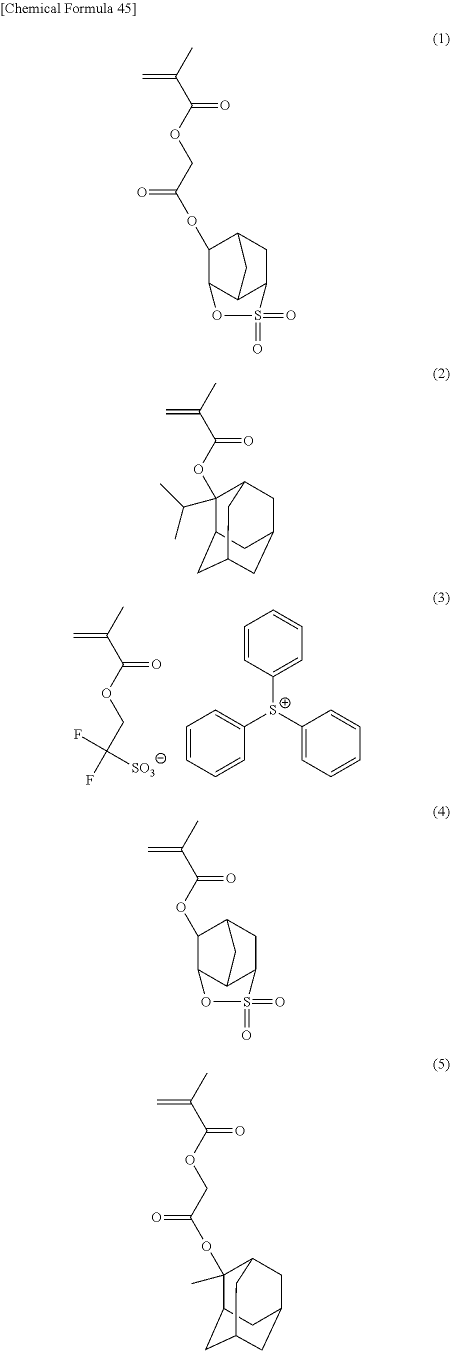

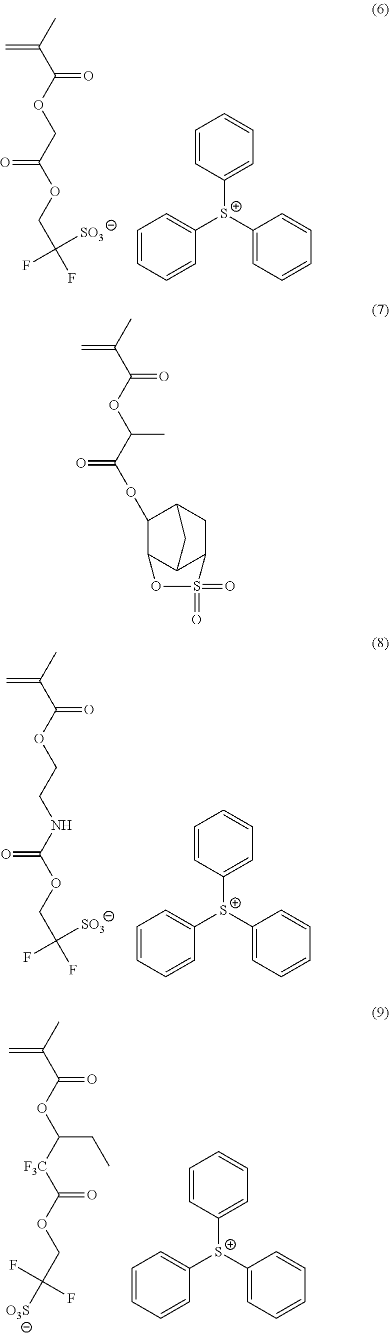

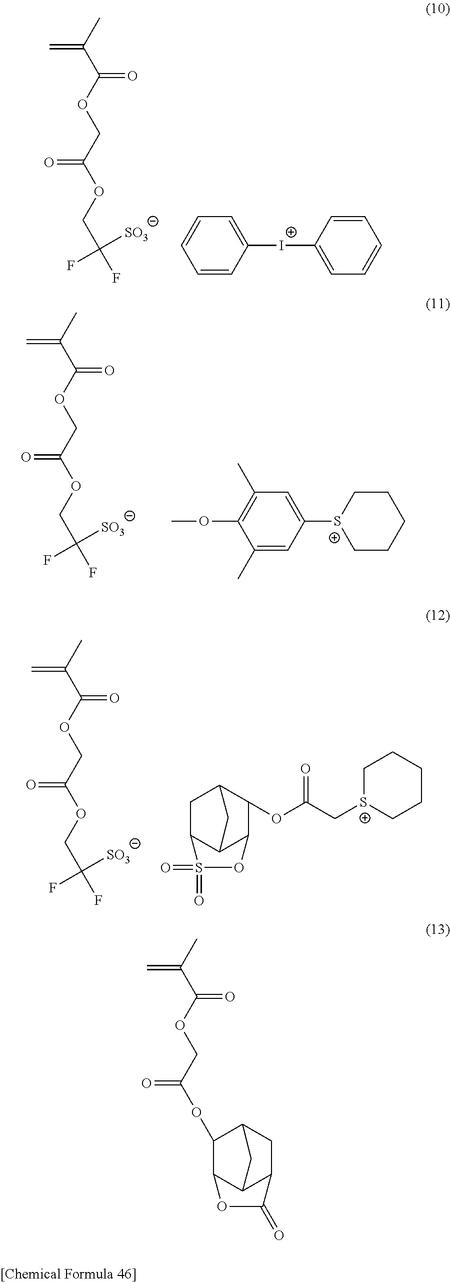

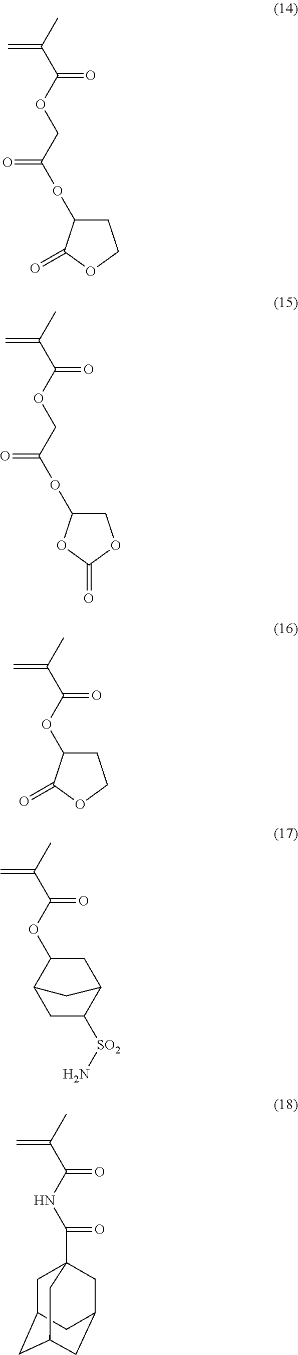

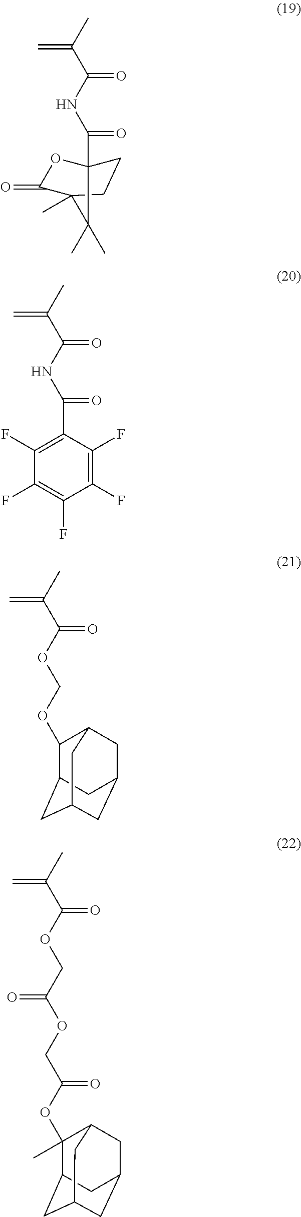

TABLE 1

| | | Polymeric compound | | | | | | | | | |
|---|---|---|---|---|---|---|---|---|---|---|---|
| | | 1 | 2 | 3 | 4 | 5 | 6 | 7 | 8 | 9 | 10 |
| Monomer | (1) | 44.2 | | 44.2 | 44.2 | 61.6 | 45.8 | | 45.8 | | 44.4 |
| | (2) | 41.5 | 42.1 | | | 24.3 | 39.4 | | 39.4 | 42.2 | 41.3 |
| | (3) | 14.3 | | 14.8 | 14.8 | | | | | | |
| | (4) | | 46.6 | | | | | | | | |
| | (5) | | | 41 | 41 | | | 37.8 | | | |
| | (6) | | 11.3 | | | 14.1 | 14.8 | 15.3 | 14.8 | 13.5 | 14.3 |
| | (7) | | | | | | | 46.9 | | | |
| | (8) | | | | | | | | | | |
| | (9) | | | | | | | | | | |
| | (10) | | | | | | | | | | |
| | (11) | | | | | | | | | | |
| | (12) | | | | | | | | | | |
| | (13) | | | | | | | | | | |
| | (14) | | | | | | | | | | |
| | (15) | | | | | | | | | | |
| | (16) | | | | | | | | | 44.3 | |
| | (17) | | | | | | | | | | |
| | (18) | | | | | | | | | | |
| | (19) | | | | | | | | | | |
| | (20) | | | | | | | | | | |
| | (21) | | | | | | | | | | |
| | (22) | | | | | | | | | | |

| | | | | | | | | | | |
|---|---|---|---|---|---|---|---|---|---|---|
| Mw | 12400 | 12400 | 14400 | 14400 | 13100 | 11800 | 12400 | 11800 | 11900 | 12300 |
| Mw/Mn | 1.56 | 1.69 | 1.73 | 1.73 | 1.74 | 1.69 | 1.54 | 1.69 | 1.78 | 1.69 |

TABLE 2

| | | Polymeric compound | | | | | | | | | |
|---|---|---|---|---|---|---|---|---|---|---|---|
| | | 11 | 12 | 13 | 14 | 15 | 16 | 17 | 18 | 19 | 20 |
| Monomer | (1) | 44.7 | 44 | 44.7 | 46.2 | 43.9 | | | | | 37.2 |
| | (2) | | | | | | | | | | |
| | (3) | | | | | | | | | | |
| | (4) | | | | | | | | | | |
| | (5) | 41.4 | 43.5 | 42.7 | 38.9 | 41 | 41.4 | 42.2 | 41.9 | 16.2 | 30.5 |
| | (6) | | | | | | 13.4 | 12.8 | 13.3 | 14 | 13.5 |
| | (7) | | | | | | | | | 34.6 | |
| | (8) | 13.9 | | | | | | | | | |
| | (9) | | 12.5 | | | | | | | | |
| | (10) | | | 12.6 | | | | | | | |
| | (11) | | | | 14.9 | | | | | | |
| | (12) | | | | | 15.1 | | | | | |
| | (13) | | | | | | 45.2 | | | | |
| | (14) | | | | | | | 45 | | | |
| | (15) | | | | | | | | 44.8 | | |
| | (16) | | | | | | | | | 35.2 | |
| | (17) | | | | | | | | | | 18.8 |
| | (18) | | | | | | | | | | |
| | (19) | | | | | | | | | | |
| | (20) | | | | | | | | | | |
| | (21) | | | | | | | | | | |
| | (22) | | | | | | | | | | |

| | | | | | | | | | | |
|---|---|---|---|---|---|---|---|---|---|---|
| Mw | 11800 | 11300 | 11900 | 12100 | 12200 | 12500 | 12100 | 12400 | 11800 | 12400 |
| Mw/Mn | 1.99 | 1.57 | 1.59 | 1.72 | 1.79 | 1.79 | 1.71 | 1.66 | 1.85 | 1.65 |

TABLE 3

| | | Polymeric compound | | | | | | | | | |
|---|---|---|---|---|---|---|---|---|---|---|---|
| | | 21 | 22 | 23 | 24 | 25 | 26 | 27 | 28 | 29 | 30 |
| Monomer | (1) | 40 | 38 | 36.2 | 19.1 | 44 | 44.9 | 45.9 | 45.4 | | |
| | (2) | | | | | | | | | | |
| | (3) | | | | | | | | | | |
| | (4) | | | | | | | | | | |
| | (5) | 29.7 | 33.3 | 33.7 | 34.6 | | | | | | |
| | (6) | 13.4 | 12.8 | 13.6 | 14 | 13.4 | 13.1 | | | 14 | 13.8 |
| | (7) | | | | | | | | | | |
| | (8) | | | | | | | | | | |
| | (9) | | | | | | | | | | |
| | (10) | | | | | | | | | | |
| | (11) | | | | | | | 14.5 | 14.7 | | |
| | (12) | | | | | | | | | | |
| | (13) | | | | | | | | | | |
| | (14) | | | | | | | | | 43.8 | 44.4 |
| | (15) | | | | | | | | | | |
| | (16) | | | | 16.2 | | | | | | |
| | (17) | | | | | | | | | | |
| | (18) | 16.9 | | | 16.1 | | | | | | |
| | (19) | | 15.9 | | | | | | | | |
| | (20) | | | 16.5 | | | | | | | |
| | (21) | | | | | 42.6 | | 39.6 | | 42.2 | |
| | (22) | | | | | | 42 | | 39.9 | | 41.8 |

| | | | | | | | | | | |
|---|---|---|---|---|---|---|---|---|---|---|
| Mw | 11800 | 12500 | 11100 | 12200 | 12800 | 12600 | 11200 | 12300 | 12500 | 12100 |
| Mw/Mn | 1.62 | 1.89 | 1.73 | 1.76 | 1.88 | 1.79 | 1.7 | 1.64 | 1.68 | 1.77 |

TABLE 4

| | | Polymeric compound | | |
|---|---|---|---|---|
| | | 31 | 32 | 33 |
| Monomer | (1) | 38.7 | 38.5 | 19.8 |
| | (2) | | | |
| | (3) | | | |
| | (4) | | | |
| | (5) | | | |
| | (6) | 12.8 | 12.9 | 13.6 |
| | (7) | | | |
| | (8) | | | |
| | (9) | | | |
| | (10) | | | |
| | (11) | | | |
| | (12) | | | |
| | (13) | | | |
| | (14) | | | |
| | (15) | | | |
| | (16) | | | 17.5 |
| | (17) | | | |
| | (18) | 15.7 | 15.6 | 16.6 |
| | (19) | | | |
| | (20) | | | |
| | (21) | 32.8 | | 32.5 |
| | (22) | | 33 | |

| | | | |
|---|---|---|---|
| Mw | 12000 | 12600 | 11700 |
| Mw/Mn | 1.72 | 1.68 | 1.84 |

TABLE 5

| | Component | Component | Component |
|---|---|---|---|
| | (A) | (D) | (S) |
| Comparative | (A)-1 | (D)-1 | (S)-1 |
| Example 1 | [100] | [1.5] | [5000] |
| Comparative | (A)-2 | (D)-1 | (S)-1 |
| Example 2 | [100] | [1.5] | [5000] |
| Comparative | (A)-3 | (D)-1 | (S)-1 |
| Example 3 | [100] | [1.5] | [5000] |
| Comparative | (A)-4 | (D)-1 | (S)-1 |
| Example 4 | [100] | [1.5] | [5000] |
| Comparative | (A)-5 | (D)-1 | (S)-1 |
| Example 5 | [100] | [1.5] | [5000] |
| Comparative | (A)-7 | (D)-1 | (S)-1 |
| Example 6 | [100] | [1.5] | [5000] |

TABLE 6

| | Component | Component | Component |
|---|---|---|---|
| | (A) | (D) | (S) |
| Example 1 | (A)-8 | (D)-1 | (S)-1 |
| | [100] | [1.5] | [5000] |
| Example 2 | (A)-9 | (D)-1 | (S)-1 |
| | [100] | [1.5] | [5000] |
| Example 3 | (A)-10 | (D)-1 | (S)-1 |
| | [100] | [1.5] | [5000] |
| Example 4 | (A)-11 | (D)-1 | (S)-1 |
| | [100] | [1.5] | [5000] |
| Example 5 | (A)-12 | (D)-1 | (S)-1 |
| | [100] | [1.5] | [5000] |
| Example 6 | (A)-13 | (D)-1 | (S)-1 |
| | [100] | [1.5] | [5000] |
| Example 7 | (A)-14 | (D)-1 | (S)-1 |
| | [100] | [1.5] | [5000] |
| Example 8 | (A)-15 | (D)-1 | (S)-1 |
| | [100] | [1.5] | [5000] |
| Example 9 | (A)-16 | (D)-1 | (S)-1 |
| | [100] | [1.5] | [5000] |
| Example 10 | (A)-17 | (D)-1 | (S)-1 |
| | [100] | [1.5] | [5000] |
| Example 11 | (A)-18 | (D)-1 | (S)-1 |
| | [100] | [1.5] | [5000] |
| Example 12 | (A)-19 | (D)-1 | (S)-1 |
| | [100] | [1.5] | [5000] |

TABLE 7

| | Component | Component | Component |
|---|---|---|---|
| | (A) | (D) | (S) |
| Example 13 | (A)-20 | (D)-1 | (S)-1 |
| | [100] | [1.5] | [5000] |
| Example 14 | (A)-21 | (D)-1 | (S)-1 |
| | [100] | [1.5] | [5000] |
| Example 15 | (A)-22 | (D)-1 | (S)-1 |
| | [100] | [1.5] | [5000] |
| Example 16 | (A)-23 | (D)-1 | (S)-1 |
| | [100] | [1.5] | [5000] |
| Example 17 | (A)-24 | (D)-1 | (S)-1 |
| | [100] | [1.5] | [5000] |
| Example 18 | (A)-25 | (D)-1 | (S)-1 |
| | [100] | [1.5] | [5000] |
| Example 19 | (A)-26 | (D)-1 | (S)-1 |
| | [100] | [1.5] | [5000] |
| Example 20 | (A)-27 | (D)-1 | (S)-1 |
| | [100] | [1.5] | [5000] |
| Example 21 | (A)-28 | (D)-1 | (S)-1 |
| | [100] | [1.5] | [5000] |
| Example 22 | (A)-29 | (D)-1 | (S)-1 |
| | [100] | [1.5] | [5000] |
| Example 23 | (A)-30 | (D)-1 | (S)-1 |
| | [100] | [1.5] | [5000] |
| Example 24 | (A)-31 | (D)-1 | (S)-1 |
| | [100] | [1.5] | [5000] |
| Example 25 | (A)-32 | (D)-1 | (S)-1 |
| | [100] | [1.5] | [5000] |
| Example 26 | (A)-33 | (D)-1 | (S)-1 |
| | [100] | [1.5] | [5000] |
| Reference | (A)-6 | (D)-1 | (S)-1 |
| Example 1 | [100] | [1.5] | [5000] |

In Tables 5 to 7, the reference characters indicate the following. The values in brackets [ ] indicate the amount (in terms of parts by weight) of the component added.

(A)-1 to (A)-33: the aforementioned polymeric compounds 1 to 33

(D)-1: tri-n-octylamine.

(S)-1: a mixed solvent of PGMEA/PGME/cyclohexanone=3/2/5 (weight ratio)

Using the obtained resist compositions, the following evaluations were conducted.

[Measurement of Thermal Flow Temperature (Tf)]

An organic anti-reflection film composition (product name: DUV-42P, manufactured by Brewer Science Ltd.) was applied to an 8-inch silicon wafer using a spinner, and the composition was then baked on a hotplate at 180° C. for 60 seconds, thereby forming an organic anti-reflection film having a film thickness of 65 nm. Then, each resist composition was applied to the anti-reflection film using a spinner, and was then prebaked (PAB) on a hotplate at 90° C. for 60 seconds and dried, thereby forming a resist film having a film thickness of 100 nm.

Subsequently, the resist film was selectively irradiated with an KrF excimer laser (248 nm) through a mask pattern, using an KrF exposure apparatus NSR-S203 (manufactured by Nikon Corporation, NA (numerical aperture)=0.68, σ=0.75). Thereafter, a PEB treatment was conducted at 90° C. for 60 seconds, followed by alkali development for 60 seconds at 23° C. in a 2.38wt % aqueous TMAH solution (product name: NMD-3; manufactured by Tokyo Ohka Kogyo Co., Ltd.).

As a result, in each of the examples, an isolated hole pattern with a diameter of 170 nm and a pitch of 1,200 nm was formed on the resist film.

With respect to each isolated hole pattern, post exposure bake was conducted at a temperature between 120 to 190° C. (at intervals of 5° C.) for 60 seconds.

The change in the dimension of the hole diameter at each temperature, based on the diameter with no post bake treatment (23° C., 170 nm) was recorded, and the temperature at which the dimension started to decrease by 10% based on the dimension with no post bake treatment (23° C.) (i.e., the temperature at which the hole diameter became 153 nm) was defined as the Tf temperature.

[Formation of Resist Pattern]

Using a spinner, each resist composition was uniformly applied to an 8-inch silicon wafer that had been treated with hexamethyldisilazane (HMDS) at 90° C. for 36 seconds, and the solution was then subjected to a bake treatment (PAB) at a temperature indicated in Tables 8 to 10, thereby forming a resist film (film thickness: 60 nm).

Subsequently, the resist film was subjected to drawing (exposure) using an electron beam lithography apparatus JBX-9300FS (manufactured by JEOL Ltd.) at an acceleration voltage of 100 kV, targeting a pattern having a space width of 50 nm and a pitch of 100 nm. Then, a post exposure bake (PEB) treatment was conducted at 100° C. for 60 seconds, followed by development for 60 seconds at 23° C. using a 2.38% by weight aqueous solution of tetramethylammonium hydroxide (TMAH). Thereafter, water rinsing was conducted for 60 seconds using pure water, followed by drying by shaking.

As a result, in each of the examples, a space and line resist pattern (hereafter, referred to as “SL pattern”) in which spaces having a space width of 50 nm were provided at a pitch of 100 nm was formed on the resist film.

[Evaluation of Line Edge Roughness (LER)]

With respect to the SL pattern formed in the above [Formation of resist pattern], 3σ was determined as a yardstick for indicating LER. “3σ” indicates a value of 3 times the standard deviation (σ) (i.e., 3(s)) (unit: nm) determined by measuring the line width at 400 points in the lengthwise direction of the line using a measuring SEM (a scanning electron microscope, product name: S-9380, manufactured by Hitachi, Ltd.; acceleration voltage: 800V). The smaller this 3 s value is, the lower the level of roughness of the line side walls, indicating that an SL pattern with a uniform width was obtained. The results are indicated under “LER (nm)” in Tables 8 to 10.

The optimum exposure dose Eop (mJ/cm²) with which the LS pattern was formed in the above [Formation of resist pattern] was determined. The results are shown in Tables 8 to 10.

[Evaluation of Exposure Latitude (5% EL)]

In the above [Formation of resist pattern 2], the exposure dose with which an SL pattern having a dimension of the target dimension (space width: 50 nm)±5% (i.e., 47.5 nm to 52.5 nm) was determined, and the EL margin (unit: %) was determined by the following formula. The larger the value of the exposure latitude, the smaller the change in the pattern dimension by the variation of the exposure dose. The results are indicated “5% EL” in Tables 8 to 10.

EL margin (%)=(|E1−E2|/Eop)×100

<f0 In the formula, E1 represents the exposure dose (mJ/cm²) for forming a LS pattern having a line width of 47.5 nm, and E2 represents the exposure dose (mJ/cm²) for forming a LS pattern having a line width of 52.5 nm.

The “resolution” was determined by using a measuring SEM (scanning electron microscope) S-9380 (manufactured by Hitachi Ltd.) to determine the critical resolution (nm) at the above Eop value. The results are shown in Tables 8 to 10.

TABLE 8

| | PAB/PEB | | | | | Resolu- |
|---|---|---|---|---|---|---|
| | (° C.) each | Tf | Eop | | LER | tion |
| | 60 sec | (° C) | (uC/cm²) | 5% EL | (nm) | (nm) |
| Comparative | 140/120 | 178.1 | 47.6 | 9.3 | 8.9 | 50 |
| Example 1 | | | | | | |
| Comparative | 140/120 | 180.6 | 53.4 | 8.2 | 8.7 | 60 |
| Example 2 | | | | | | |
| Comparative | 140/120 | 175.6 | 50.4 | 10.8 | 7.9 | 60 |
| Example 3 | | | | | | |
| Comparative | 140/100 | 175.6 | 134.2 | 13.1 | 6.8 | 50 |
| Example 4 | | | | | | |
| Comparative | 140/130 | 192.4 | 55.7 | 7.4 | 9.6 | 60 |
| Example 5 | | | | | | |
| Comparative | 140/120 | 178.9 | 48.3 | 10.1 | 9 | 50 |
| Example 6 | | | | | | |

TABLE 9

| | PAB/PEB | | | | | Resolu- |
|---|---|---|---|---|---|---|
| | (° C.) each | Tf | Eop | | LER | tion |
| | 60 sec | (° C) | (uC/cm²) | 5% EL | (nm) | (nm) |
| Example 1 | 130/100 | 161 | 48.8 | 16.2 | 6.2 | 40 |
| Example 2 | 120/90 | 152.1 | 47.7 | 17.1 | 6.3 | 40 |
| Example 3 | 120/95 | 157.1 | 49 | 17.4 | 5.8 | 40 |
| Example 4 | 120/90 | 155.4 | 52.1 | 18.7 | 6.1 | 40 |
| Example 5 | 120/90 | 150.2 | 50.3 | 20.4 | 6.2 | 40 |
| Example 6 | 130/100 | 160.6 | 55.6 | 18.2 | 5.8 | 40 |
| Example 7 | 130/100 | 161.3 | 60.3 | 17.9 | 5.5 | 40 |
| Example 8 | 130/100 | 163.7 | 57.4 | 16.2 | 5.7 | 40 |
| Example 9 | 110/85 | 146.1 | 46.6 | 16.4 | 6.4 | 40 |
| Example 10 | 110/85 | 145.3 | 48 | 17.1 | 6.1 | 40 |
| Example 11 | 110/85 | 144 | 47.5 | 17 | 5.8 | 40 |
| Example 12 | 120/95 | 159.8 | 50.1 | 16.9 | 6.3 | 40 |

TABLE 10

| | PAB/PEB | | | | | Resolu- |
|---|---|---|---|---|---|---|
| | (° C.) each | Tf | Eop | | LER | tion |
| | 60 sec | (° C) | (uC/cm²) | 5% EL | (nm) | (nm) |
| Example 13 | 130/100 | 166.6 | 53.4 | 18.1 | 5.9 | 40 |
| Example 14 | 130/100 | 165.6 | 55.2 | 17.7 | 5.7 | 30 |
| Example 15 | 130/100 | 166.9 | 51.6 | 18 | 5.5 | 30 |
| Example 16 | 130/100 | 165.1 | 54 | 18.4 | 5.9 | 30 |
| Example 17 | 120/90 | 152 | 48.5 | 21 | 5.8 | 30 |
| Example 18 | 120/95 | 155.4 | 50.2 | 19.4 | 5.4 | 40 |
| Example 19 | 110/85 | 142.3 | 49.6 | 20.7 | 5.6 | 40 |
| Example 20 | 120/95 | 156.2 | 54.7 | 19.6 | 6.2 | 40 |
| Example 21 | 110/85 | 143.5 | 53.5 | 18.2 | 6 | 40 |
| Example 22 | 110/90 | 147.3 | 45.8 | 17.6 | 6.1 | 40 |
| Example 23 | 110/90 | 138.9 | 45.2 | 17.9 | 6.4 | 40 |
| Example 24 | 130/100 | 164 | 51.1 | 18.6 | 5.2 | 30 |
| Example 25 | 120/95 | 156.3 | 50.7 | 17.5 | 5.3 | 30 |
| Example 26 | 120/90 | 149.7 | 49.9 | 20.1 | 5.1 | 30 |
| Reference | 130/120 | 161 | 38.7 | 8.8 | 9.1 | 70 |
| Example 1 | | | | | | |

As seen from the results shown above, the resist compositions of Examples 1 to 26 exhibited excellent lithography properties such as LER, as compared to the resist compositions of Comparative Examples 1 to 6.

While preferred embodiments of the invention have been described and illustrated above, it should be understood that these are exemplary of the invention and are not to be considered as limiting. Additions, omissions, substitutions, and other modifications can be made without departing from the spirit or scope of the present invention. Accordingly, the invention is not to be considered as being limited by the foregoing description, and is only limited by the scope of the appended claims.

1. A resist composition comprising a base component (A) which generates acid upon exposure and exhibits changed solubility in a developing solution by the action of acid,
the base component (A) comprising a resin component (A1) comprising a structural unit (a0) represented by general formula (a0) shown below and a structural unit (a2) represented by general formula (a2) shown below,
provided that, when the resist composition is used to form a film on a substrate, and the film is subjected to selective exposure and developing to form a hole pattern, followed by a bake treatment, a bake treatment temperature (Tf) at which a size of the hole pattern is started to be reduced 10% as compared to the size before the bake treatment is lower than 170° C.: 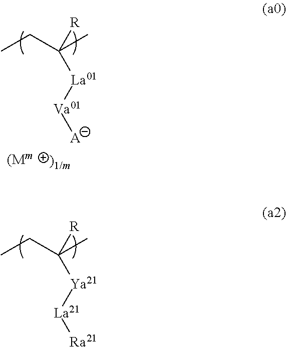
wherein R represents a hydrogen atom, an alkyl group of 1 to 5 carbon atoms or a halogenated alkyl group of 1 to 5 carbon atoms; La⁰¹ represents —COO—, —CON(R′)— or a divalent aromatic group; R′ represents a hydrogen atom or a methyl group; Va⁰¹ represents a linear alkylene group of at least 3 carbon atoms, provided that part or all of the hydrogen atoms constituting the alkylene group may be substituted with a halogen atom, a linear or branched alkyl group or a linear or branched halogenated alkyl group, and part of —CH₂— constituting the alkylene group may be replaced by a divalent cyclic group, an oxygen atom (—O—), a carbonyl group (—C(═O)—) or —NH—; A⁻ represents an anion-containing group; Mm⁺ represents an organic cation having a valency of m; m represents an integer of 1 to 3; Ya²¹ represents a single bond or divalent linking group, La²¹ represents —O—, —COO—, —CON(R′)— or —OCO—, and R′ represents a hydrogen atom or a methyl group, provided that, when La²¹ represents —O—, Ya²¹ does not represent —CO—; and Ra²¹ represents a lactone-containing group, a carbonate containing group or an —SO₂— containing group.

2. The resist composition according to claim 1, wherein the resin component (A1) further comprises a structural unit (a1) containing an acid decomposable group that exhibits increased polarity by the action of acid.

3. The resist composition according to claim 1, wherein the resin component (A1) further comprises a structural unit (a9) containing a fluoroalkylsulfonylamino group, an aminosulfonyl group, a —C(═O)—NH—C(═O)— group or a phenolic hydroxy group.

4. A method of forming a resist pattern, comprising:
using a resist composition of claim 1 to form a resist film on a substrate;
conducting exposure of the resist film; and
developing the resist film to form a resist pattern.

5. The resist composition according to claim 1, wherein the bake treatment temperature (Tf) is 140° C. to 165° C.

6. The resist composition according to claim 1, wherein the bake treatment temperature (Tf) is 150° C. to 160° C.

7. The resist composition according to claim 1, wherein Va⁰¹ represents a linear alkylene group of 5 to 7 carbon atoms in which part of —CH₂— groups constituting the alkylene group has been substituted with a divalent cyclic group, an oxygen atom (—O—), a carbonyl group (—C(═O)—) or —NH—.

8. The resist composition according to claim 1, wherein A⁻ represents a group represented by any one of formulae (a6a-r-1) to (a6a-r-3) shown below: 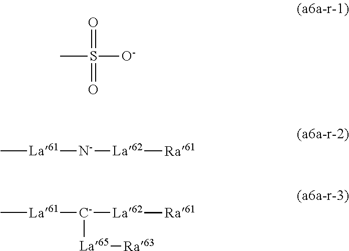
wherein La′⁶¹ and La′⁶² each independently represents —SO₂—; La′⁶³ to La′⁶⁵ each independently represents —SO₂— or a single bond; and Ra′⁶¹ to Ra′⁶³ each independently represents a hydrocarbon group.

9. The resist composition according to claim 1, wherein M^{m+} represents a cation represented by formula (ca-1) or (ca-3) shown below: 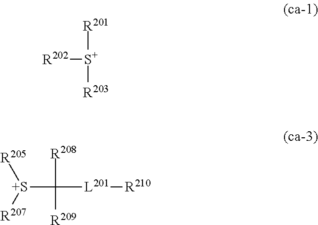
wherein R²⁰¹ to R²⁰⁷ each independently represents an aryl group, an alkyl group or an alkenyl group, provided that two of R²⁰¹ to R²⁰³, R²⁰⁶ and R²⁰⁷ may be mutually bonded to form a ring with the sulfur atom; R²⁰⁸ and R²⁰⁹ each independently represents a hydrogen atom or an alkyl group of 1 to 5 carbon atoms; and R²¹⁰ represents an aryl group which may have a substituent, an alkyl group which may have a substituent, an alkenyl group which may have a substituent or an —SO₂— containing cyclic group which may have a substituent; L²⁰¹ represents —C(═O)— or —C(═O)O—.

10. The resist composition according to claim 1, wherein the structural unit (a0) is represented by any one of formulae (a0-1) to (a0-3) shown below: 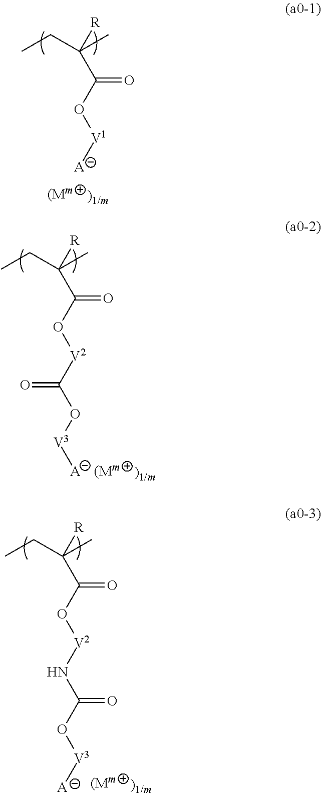
wherein R represents a hydrogen atom, an alkyl group of 1 to 5 carbon atoms or a halogenated alkyl group of 1 to 5 carbon atoms; V¹ represents a linear alkylene group of at least 3 carbon atoms, provided that part or all of the hydrogen atoms constituting the alkylene group may be substituted with a halogen atom, a linear or branched alkyl group or a linear or branched halogenated alkyl group; V² and V³ each independently represents a linear alkylene group of 1 to 5 carbon atoms, a divalent cyclic group or a combination thereof, provided that part or all of the hydrogen atoms constituting the alkylene group may be substituted with a halogen atom, a linear or branched alkyl group or a linear or branched halogenated alkyl group, and part of —CH₂— groups constituting the alkylene group may be replaced by an oxygen atom (—O—); A represents an anion-containing group; M^{m+} represents an organic cation having a valency of m; and m represents an integer of 1 to 3.

11. The resist composition according to claim 1, wherein Ya²¹ represents an ester bond [—C(═O)—O—], an ether bond (—O—), a linear or branched alkylene group, a combination thereof, or a single bond.

12. The resist composition according to claim 1, wherein Ra²¹ represents a lactone-containing group represented by any one of formulae (a2-r-1) to (a2-r-7) shown below, a carbonate containing group represented by any one of formulae (ax3-r-1) to (ax3-r-3) shown below, or an —SO₂— containing group represented by any one of general formulae (a5-r-1) to (a5-r-4) shown below: 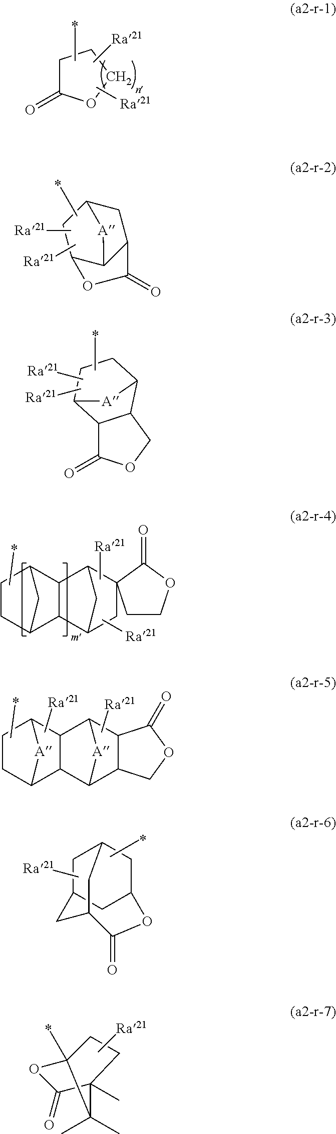
wherein each Ra′²¹ independently represents a hydrogen atom, an alkyl group, an alkoxy group, a halogen atom, a halogenated alkyl group, a hydroxy group, —COOR″, —OC(═O)R″, a hydroxyalkyl group or a cyano group; R″ represents a hydrogen atom or an alkyl group; A″ represents an oxygen atom, a sulfur atom or an alkylene group of 1 to 5 carbon atoms which may contain an oxygen atom or a sulfur atom; n′ represents an integer of 0 to 2; and m′ represents 0 or 1; 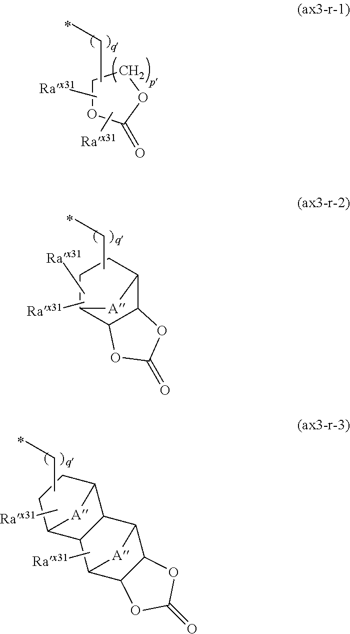
wherein each Ra′^{x31} independently represents a hydrogen atom, an alkyl group, an alkoxy group, a halogen atom, a halogenated alkyl group, a hydroxy group, —COOR″, —OC(═O)R″, a hydroxyalkyl group or a cyano group; R″ represents a hydrogen atom or an alkyl group; A″ represents an oxygen atom, a sulfur atom or an alkylene group of 1 to 5 carbon atoms which may contain an oxygen atom or a sulfur atom; p′ represents an integer of 1 to 3; q′ represents 0 or 1; and * represents a valence bond; 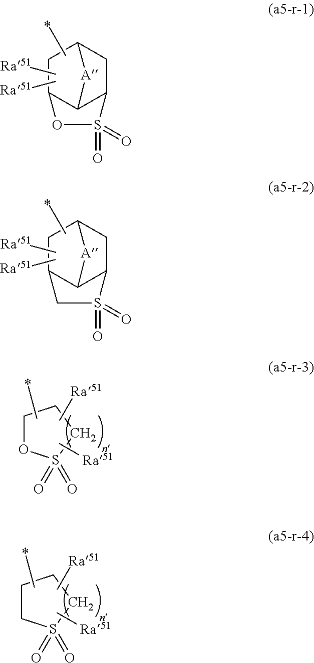
wherein each Ra′⁵¹ independently represents a hydrogen atom, an alkyl group, an alkoxy group, a halogen atom, a halogenated alkyl group, a hydroxy group, —COOR″, —OC(═O)R″, a hydroxyalkyl group or a cyano group; R″ represents a hydrogen atom or an alkyl group; A″ represents an oxygen atom, a sulfur atom or an alkylene group of 1 to 5 carbon atoms which may contain an oxygen atom or a sulfur atom; and n′ represents an integer of 0 to 2.

13. The resist composition according to claim 3, wherein the structural unit (a9) contains a group represented by general formula (a9-r-1) or (a9-r-2) shown below: 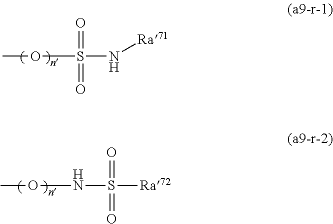
wherein Ra′⁷¹ and Ra′⁷² each independently represents a hydrogen atom, an alkyl group or a fluorinated alkyl group; and n′ represents 0 or 1.

14. The resist composition according to claim 13, wherein the structural unit (a9) is represented by general formula (a9-1), (a9-2) or (a9-3) shown below: 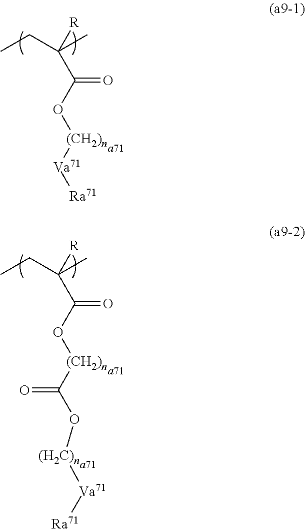
wherein R represents a hydrogen atom, an alkyl group of 1 to 5 carbon atoms or a halogenated alkyl group of 1 to 5 carbon atoms; each Va⁷¹ independently represents a divalent aliphatic cyclic group; each na⁷¹ independently represents an integer of 0 to 3; na⁷² represents an integer of 1 to 5; and each Ra⁷¹ independently represents a group represented by the aforementioned formula (a9-r-1) or (a9-r-2); 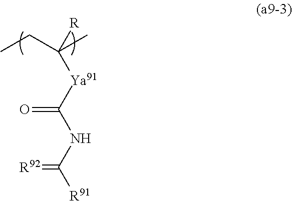
wherein R represents a hydrogen atom, an alkyl group of 1 to 5 carbon atoms or a halogenated alkyl group of 1 to 5 carbon atoms; Ya⁹¹ represents a single bond or a divalent linking group; R⁹¹ represents a cyclic group which may have a substituent, a chain-like alkyl group which may have a substituent or a chain-like alkenyl group which may have a substituent; and R⁹² represents an oxygen atom or a sulfur atom.

15. The resist composition according to claim 10, wherein Ra²¹ represents a lactone-containing group represented by any one of formulae (a2-r-1) to (a2-r-7) shown below, a carbonate containing group represented by any one of formulae (ax3-r-1) to (ax3-r-3) shown below, or an —SO₂— containing group represented by any one of general formulae (a5-r-1) to (a5-r-4) shown below: 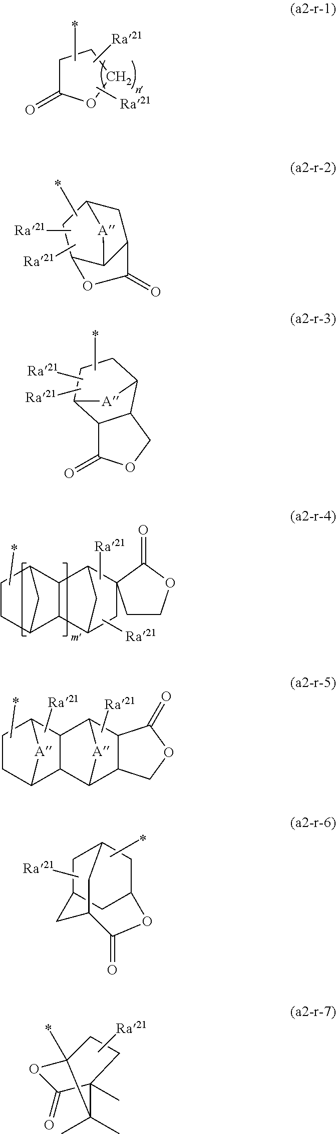
wherein each Ra′²¹ independently represents a hydrogen atom, an alkyl group, an alkoxy group, a halogen atom, a halogenated alkyl group, a hydroxy group, —COOR″, —OC(═O)R″, a hydroxyalkyl group or a cyano group; R″ represents a hydrogen atom or an alkyl group; A″ represents an oxygen atom, a sulfur atom or an alkylene group of 1 to 5 carbon atoms which may contain an oxygen atom or a sulfur atom; n′ represents an integer of 0 to 2; and m′ represents 0 or 1; 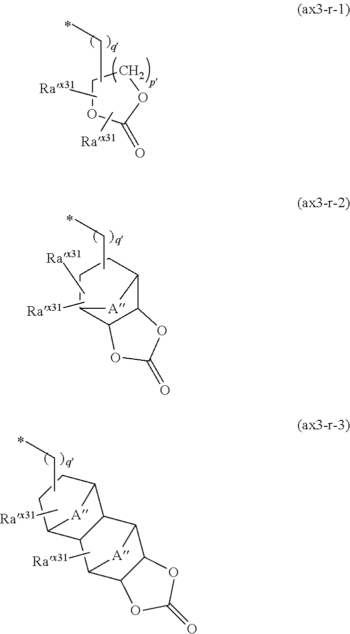
wherein each Ra″^{x31} independently represents a hydrogen atom, an alkyl group, an alkoxy group, a halogen atom, a halogenated alkyl group, a hydroxy group, —COOR″, —OC(═O)R″, a hydroxyalkyl group or a cyano group; R″ represents a hydrogen atom or an alkyl group; A″ represents an oxygen atom, a sulfur atom or an alkylene group of 1 to 5 carbon atoms which may contain an oxygen atom or a sulfur atom; p′ represents an integer of 1 to 3; q′ represents 0 or 1; and * represents a valence bond; 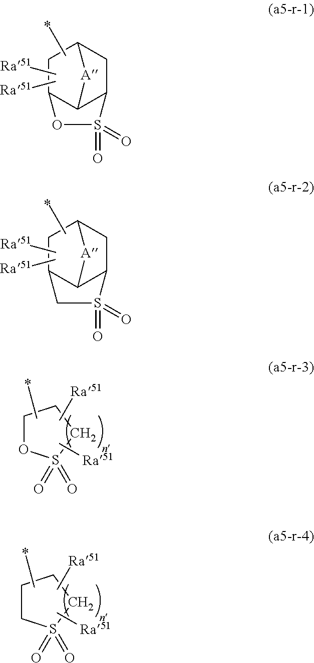
wherein each Ra′⁵¹ independently represents a hydrogen atom, an alkyl group, an alkoxy group, a halogen atom, a halogenated alkyl group, a hydroxy group, —COOR″, —OC(═O)R″, a hydroxyalkyl group or a cyano group; R″ represents a hydrogen atom or an alkyl group; A″ represents an oxygen atom, a sulfur atom or an alkylene group of 1 to 5 carbon atoms which may contain an oxygen atom or a sulfur atom; and n′ represents an integer of 0 to 2.
